(19) United States
(12) Patent Application Publication
(10) Pub. No.: US 2026/0076061 A1
(43) Pub. Date: Mar. 12, 2026

(54) ANODE FOR OLED SUB-PIXEL CIRCUIT

(71) Applicant: Applied Materials, Inc., Santa Clara, CA (US)

(72) Inventors: Yu-Hsin LIN, Zhubei City (TW); Chung-chia CHEN, Hsinchu City (TW); Ji Young CHOUNG, Hwaseong-si (KR); Sheng-Wen WANG, Tainan City (TW)

(21) Appl. No.: 19/227,050

(22) Filed: Jun. 3, 2025

Related U.S. Application Data
(63) Continuation-in-part of application No. 18/915,877, filed on Oct. 15, 2024.
(60) Provisional application No. 63/691,744, filed on Sep. 6, 2024.

(51) Int. Cl. H10K 59/80; H10K 59/12

(52) U.S. Cl. CPC H10K 59/80517; H10K 59/1201

(57) ABSTRACT

Embodiments of the present disclosure generally relate to a display. More specifically, embodiments described herein relate to pixels and methods of forming pixels that may be utilized in a display such as an organic light-emitting diode (OLED) display. In one or more embodiments, a method includes disposing a plurality of metal layers over a substrate. The plurality of metal layers include a plurality of first sub-layers, a plurality of second sub-layers, and a plurality of third sub-layers. Disposing the plurality of metal layers includes disposing the plurality of first sub-layers over the substrate, the second plurality of sub-layers over the plurality of first sub-layers, and the plurality of third sub-layers over the plurality of second sub-layers, wherein the plurality of first sub-layers comprise a first thickness, the plurality of second sub-layers comprise a second thickness, and the plurality of third sub-layers comprise a third thickness.

### CROSS-REFERENCE TO RELATED APPLICATIONS

This application is a continuation-in-part of U.S. patent application Ser. No. 18/915,877, filed Oct. 15, 2024, which claims priority to United States Provisional Patent Application Ser. No. 63/691,744, filed Sep. 6, 2024, which are herein incorporated by reference.

### BACKGROUND

### Field

Embodiments of the present disclosure generally relate to a display. More specifically, embodiments described herein relate to pixels and methods of forming pixels that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

Generally, OLED pixel patterning utilizes a fine metal mask process, which restricts panel size, pixel resolution, and substrate size. Attempts to overcome the challenges of using a fine metal mask process have involved using photolithography processes to pattern pixels. Unfortunately, conventional photolithography processes and OLED pixel patterning processes can result in oxidation of the organic material, oxidation of an overhang of an inorganic material, poor cathode coverage, residue of an encapsulation layer over an inorganic substrate, and poor deposition under an overhang of the inorganic material, each of which can disrupt OLED performance.

Accordingly, what is needed in the art are OLED pixels and methods of forming OLED pixels to improve OLED performance.

### SUMMARY

Embodiments of the present disclosure generally relate to a display. More specifically, embodiments described herein relate to pixels and methods of forming pixels that may be utilized in a display such as an organic light-emitting diode (OLED) display.

In one or more embodiments, a method includes disposing a plurality of metal layers over a substrate. The plurality of metal layers include a plurality of first sub-layers, a plurality of second sub-layers, and a plurality of third sub-layers. Disposing the plurality of metal layers includes disposing the plurality of first sub-layers over the substrate, the second plurality of sub-layers over the plurality of first sub-layers, and the plurality of third sub-layers over the plurality of second sub-layers, wherein the plurality of first sub-layers comprise a first thickness, the plurality of second sub-layers comprise a second thickness, and the plurality of third sub-layers comprise a third thickness. Disposing the plurality of metal layers further includes disposing a supplemental material over the plurality of third sub-layers and patterning a resist over the supplemental material, the resist defining one or more openings, one or more upper surfaces of the supplemental material are exposed by the one or more openings. Disposing the plurality of metal layers further includes etching the one or more upper surfaces of the supplemental material exposed by the one or more openings and annealing the supplemental material to form one or more first upper surfaces and one or more second upper surfaces of the third sub-layer.

In one or more embodiments, a sub-pixel circuit includes a plurality of anodes deposited over a substrate. Each anode includes a first sub-layer, a second sub-layer, and a third sub-layer. The third sub-layer includes a first upper surface and a second upper surface offset from one another. An organic light emitting diode (OLED) material is disposed over the anode. A cathode is disposed over the OLED material. A first distance is defined by the distance from the second sub-layer to the cathode for the OLED material aligned with the first upper surface and second distance defined by the distance from the second sub-layer to the cathode for the OLED material aligned with the second upper surface, the first distance is greater than the second distance.

In one or more embodiments, a device includes a substrate and an inorganic layer disposed on the substrate. The inorganic layer defines sub-pixels of the device. The inorganic layer comprises a plurality of overhang structures. A pixel defining layer (PDL) is disposed on the substrate and below the inorganic layer. A first sub-pixel includes a first anode having a first thickness disposed over the substrate. A first organic light-emitting diode (OLED) material is disposed over and in contact with the first anode. A first color filter is disposed over the first OLED material. A second sub-pixel includes a second anode having a second thickness disposed over the substrate. A second OLED material is disposed over and in contact with the second anode. The first OLED material and the second OLED material are configured to emit the same color light. A second color filter is disposed over the second OLED material. A third sub-pixel includes a third anode having a third thickness disposed over the substrate. A third organic light-emitting diode (OLED) material is disposed over and in contact with the third anode. The first thickness the second thickness, and the third thickness are the same. A third color filter is disposed over the third OLED material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIGS. 1A-1F are schematic, cross-sectional views of a sub-pixel circuit for an organic light-emitting diode (OLED) display, according to embodiments described herein.

FIGS. 2A-2F are schematic, cross-sectional views of a sub-pixel circuit for an organic light-emitting diode (OLED) display, according to embodiments described herein.

FIG. 3 is a flow diagram of a method for forming a sub-pixel circuit, according embodiments described herein.

FIGS. 4A-4U are schematic, cross-sectional views of a substrate during a method for forming a sub-pixel circuit, according embodiments described herein.

FIGS. 5A-5C are schematic, cross-sectional views of sub-pixel circuits, according to embodiments described herein.

FIGS. 6A-6C are schematic, cross-sectional views of a sub-pixel circuit for an organic light-emitting diode (OLED) display, according to embodiments described herein.

FIG. 7 is a flow diagram of a method for forming a sub-pixel circuit, according embodiments described herein.

FIGS. 8A-8U are schematic, cross-sectional views of a substrate during a method for forming a sub-pixel circuit, according embodiments described herein.

FIGS. 9A-9F are schematic, cross-sectional views of sub-pixel circuits, according to embodiments described herein.

FIGS. 10A and 10B are flow diagrams of a method for forming a sub-pixel circuit, according embodiments described herein.

FIGS. 11A-11Y are schematic, cross-sectional views of a substrate during a method for forming a sub-pixel circuit, according embodiments described herein.

FIGS. 12A-12D are schematic, cross-sectional views of sub-pixel circuits, according to embodiments described herein.

FIGS. 13A-13D are schematic, cross-sectional views of a substrate, according to embodiments described herein.

FIGS. 14A-14B are schematic, cross-sectional views of a substrate, according to embodiments described herein.

FIGS. 15A-15B are schematic, cross-sectional views of a substrate, according to embodiments described herein.

FIGS. 16A-16B are a schematic, cross-sectional views of a substrate, according to one or more embodiments.

FIG. 17 is a flow a flow diagram of a method for forming a sub-pixel circuit, according to one or more embodiments.

FIGS. 18A-18E are schematic, cross-sectional views of a substrate during the method for forming a metal layer, according embodiments described herein.

FIGS. 19A and 19B are schematic top views of the substrate, according to one or more embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to a display. More specifically, embodiments described herein relate to pixels and methods of forming pixels that may be utilized in a display, such as an organic light-emitting diode (OLED) display.

The sub-pixel circuit and methods thereof have an inorganic layer is disposed on the substrate, the inorganic layer defining sub-pixels of the device. The inorganic layer including at least an overhang structure. Each sub-pixel includes an anode, an organic light-emitting diode (OLED) material disposed over and in direct contact with the anode, a local passivation layer disposed over the OLED material, a device resist material disposed over and in direct contact with the local passivation layer. A global passivation layer and/or an intermediate layer can be disposed over and in direct contact with the plurality of overhang structures and the device resist material of each of the sub-pixels. As used herein, the term “direct contact” refers to directly touching with no deposited layer there between for at least some points of contacts.

Each of the embodiments described herein of the sub-pixel circuit include a plurality of sub-pixels with each of the sub-pixels defined by adjacent inorganic overhang structures that are permanent to the sub-pixel circuit. While the Figures depict three sub-pixels with each sub-pixel defined by adjacent inorganic overhang structures, the sub-pixel circuit of the embodiments described herein can include a plurality of sub-pixels, such as three or more sub-pixels. Each sub-pixel has the OLED material configured to emit a white, red, green, blue or other color light when energized, e.g., the OLED material of a first sub-pixel emits a white and/or red light when energized, the OLED material of a second sub-pixel emits a white and/or green light when energized, and the OLED material of a third sub-pixel emits a white and/or blue light when energized.

The inorganic overhang structures, when present, are permanent to the sub-pixel circuit and include at least an upper portion disposed on a lower portion. A first configuration of the inorganic overhang structure includes the upper portion of a non-conductive inorganic material and the lower portion of a conductive inorganic material. A second configuration of the inorganic overhang structure includes the upper portion of a conductive inorganic material and the lower portion of a conductive inorganic material. A third configuration of the inorganic overhang structures includes the upper portion of a non-conductive inorganic material, the lower portion of a non-conductive inorganic material, and an optional assistant cathode disposed under the lower portion. A fourth configuration of the inorganic overhang structures includes the upper portion of a conductive inorganic material, the lower portion of a non-conductive inorganic material, and an optional assistant cathode disposed under the lower portion. Any of the first, second, third, and fourth embodiments include inorganic overhang structures of at least one of the first, second, third, or fourth configurations.

The adjacent inorganic overhang structures defining each sub-pixel of the sub-pixel circuit of the display provide for formation of the sub-pixel circuit using evaporation deposition and provide for the inorganic overhang structures to remain in place after the sub-pixel circuit is formed. Evaporation deposition may be utilized for deposition of an OLED material (including a hole injection layer (HIL), a hole transport layer (HTL), an emissive layer (EML), and an electron transport layer (ETL)) and cathode. One or more of an encapsulation layer, and a global passivation layer may be disposed via evaporation deposition. The encapsulation layer of a respective sub-pixel is disposed over the cathode with the encapsulation layer extending under at least a portion of each of the adjacent inorganic overhang structures.

Overall the sub-pixel circuit and methods thereof can improve OLED pixel patterning processes by preventing oxidation of the organic material, preventing oxidation of an overhang of an inorganic material, preventing poor cathode coverage, preventing residue of an encapsulation layer over an inorganic substrate, and preventing poor deposition under an overhang of the inorganic material, each of which can disrupt OLED performance.

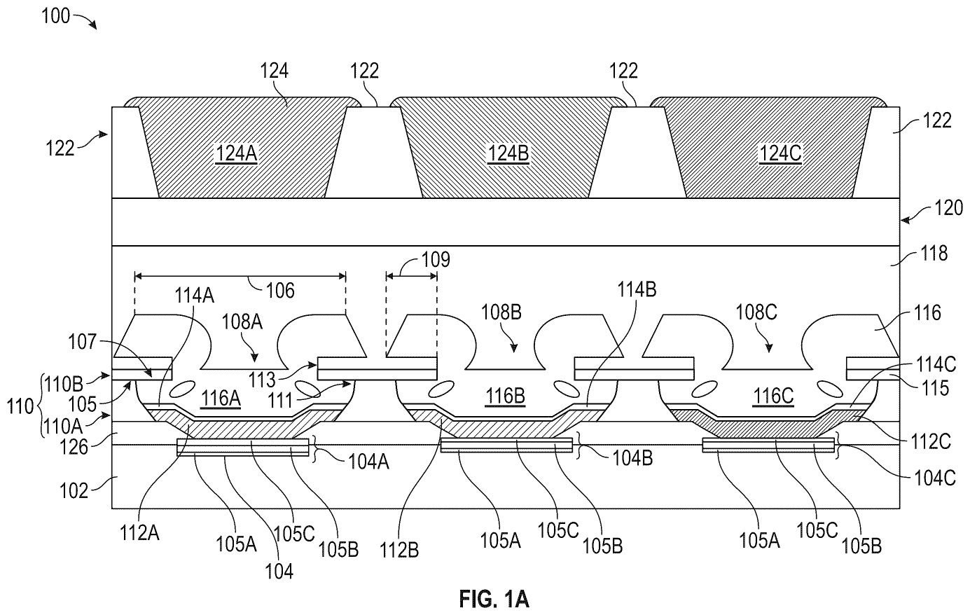

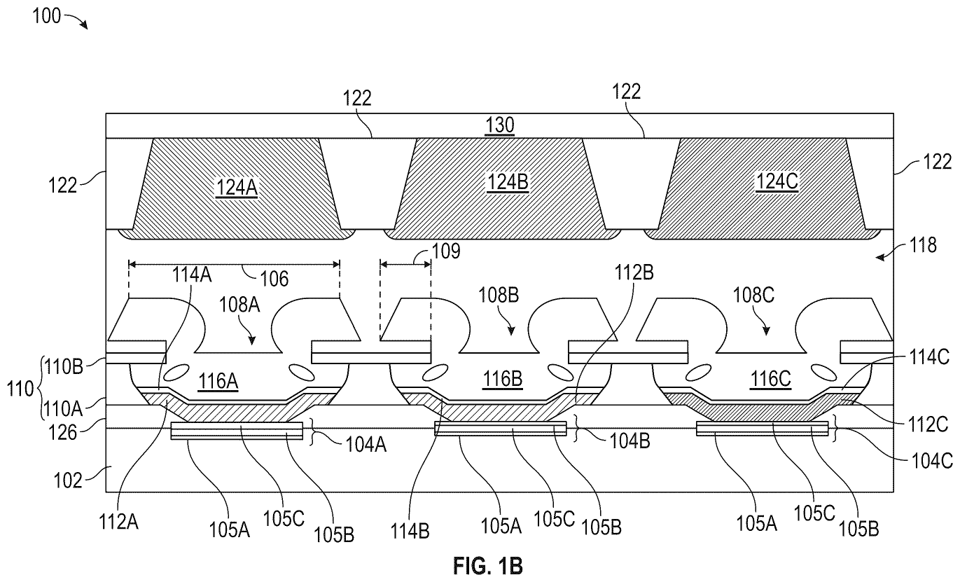

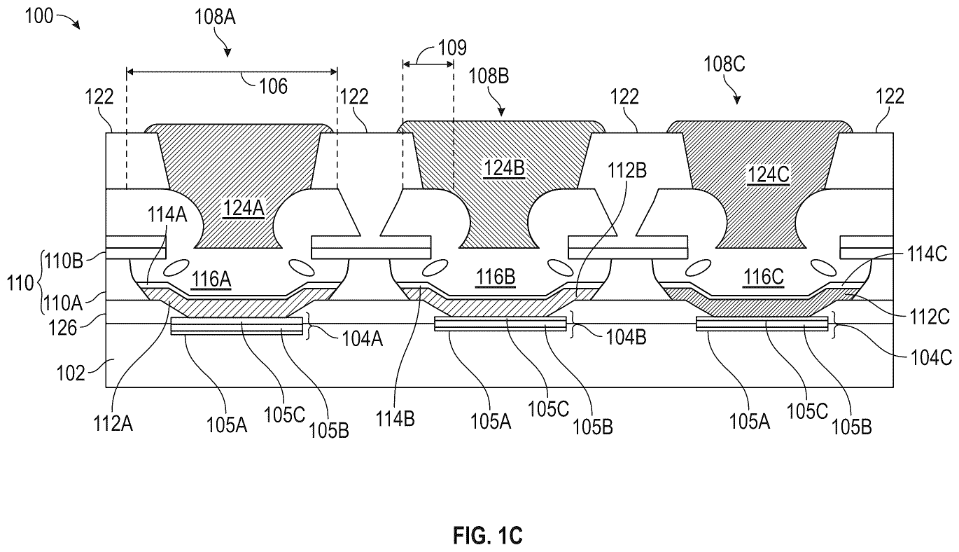

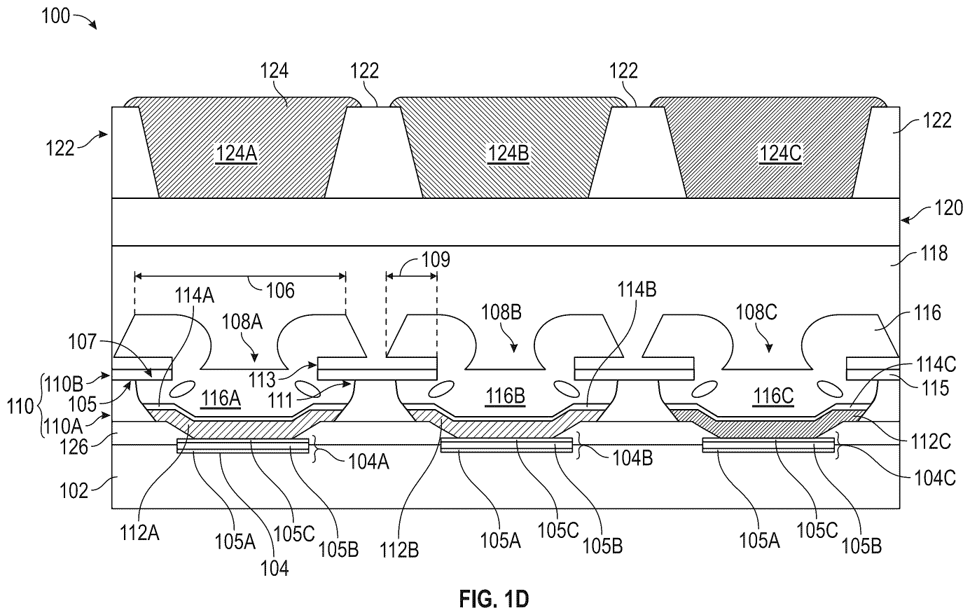

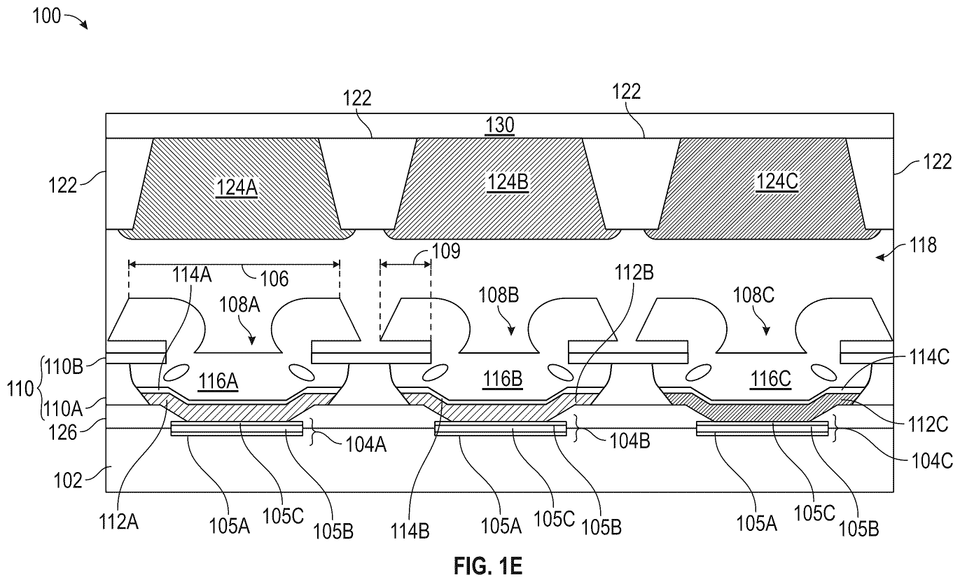

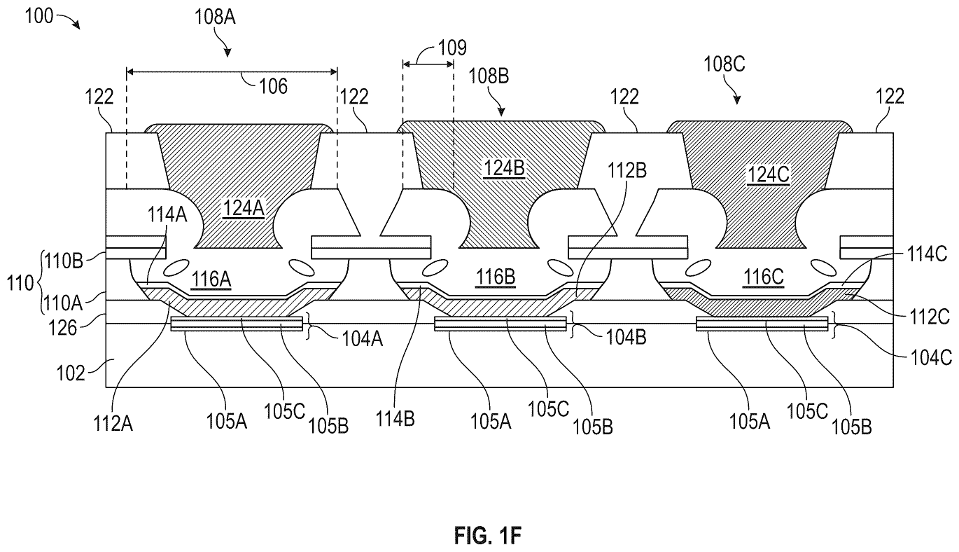

FIG. 1A is a schematic, cross-sectional view of a sub-pixel circuit 100. The sub-pixel circuit 100 includes a substrate 102. Metal layers 104 are be patterned on the substrate 102. The metal layers 104 are configured to operate anodes of respective sub-pixels. The metal layers 104 are a layer stack of a first sub-layer 105A, a second sub-layer 105B disposed over the first sub-layer 105A, and a third sub-layer 105C disposed over the second sub-layer 105B. The first sub-layer 105A includes a transparent conductive oxide (TCO) layer, e.g., indium tin oxide or indium zinc oxide. The first sub-layer 105A can include a thickness of about 1 nm to about 50 nm.

The second sub-layer 105B includes a metal layer, e.g., chromium, titanium, gold, silver, copper, aluminum, or a combination thereof, disposed on the first sub-layer 105A. The second sub-layer 105B can include a thickness of about 50 nm to about 200 nm.

The third sub-layer 105C includes a transparent conductive oxide (TCO) layer, e.g., indium tin oxide or indium zinc oxide. The third sub-layer 105C can include a thickness of about 1 nm to about 200 nm. Optionally, the third sub-layer 105C has a thickness that is greater than the thickness of the first sub-layer 105A and/or the second sub-layer 105B. Without being bound by theory, a thicker third sub-layer 105C can allow for controllable wavelength emission of the OLED material, thereby reducing power requirements during operation of the sub-pixel circuit 100.

In an embodiment, which can be combined with other embodiments described herein, the third sub-layer 105C of a first sub-pixel 108A is thicker than a third sub-layer 105C of a second sub-pixel 108B and/or a third sub-pixel 108C. Without being bound by theory, by having the third sub-layer 105C of a first sub-pixel 108A be thicker than the third sub-layer 105C of the second sub-pixel 108B and/or the third sub-pixel 108C, the light emitted from the first OLED material 112A may be red-shifted, thereby causing emission of a yellow and/or white emitting OLED material to be more red.

In one embodiment, which can be combined with other embodiments described herein, the metal layers 104 are pre-patterned on the substrate 102, e.g., the substrate 102 is a pre-patterned indium tin oxide (ITO) glass substrate. In one embodiment, which can be combined with other embodiments described herein, the metal layers 104 are pre-patterned on the substrate 102, e.g., the metal layers 104 include a first sub-layer 105A of indium tin oxide, a second sub-layer 105B of silver, and a third sub-layer 105C of indium tin oxide.

The pixels are defined by adjacent pixel defining layer (PDL) structures disposed on the substrate 102. The PDL structures 126 can be disposed on the substrate 102. The PDL structures 126 include one of an organic material, an organic material with an inorganic coating disposed thereover, or an inorganic material. The organic material of the PDL structures 126 includes, but is not limited to, polyimides. The inorganic material of the PDL structures 126 includes, but is not limited to, silicon oxide (SiO₂), silicon nitride (Si₃N₄), silicon oxynitride (Si₂N₂O), magnesium fluoride (MgF₂), or combinations thereof. Adjacent PDL structures define a respective sub-pixel and expose the anode (i.e., metal layer 104) of the respective sub-pixel of the sub-pixel circuit 100.

The sub-pixel circuit 100 has a plurality of sub-pixels 106 including at least a first sub-pixel 108A, a second sub-pixel 108B, and a third sub-pixel 108C. While the Figures depict the first sub-pixel 108A, the second sub-pixel 108B, and the third sub-pixel 108C, the sub-pixel circuit 100 of the embodiments described herein may include three or more sub-pixels 106, such as a fourth and a fifth sub-pixel. Each sub-pixel 106 has an OLED material, e.g., first OLED material 112A, second OLED material 112B, and third OLED material 112C, configured to emit a white, red, green, blue or other color light when energized, e.g., the first OLED material 112A of the first sub-pixel 108A emits a yellow light when energized, the second OLED material 112B of the second sub-pixel 108B emits a yellow light when energized, the third OLED material 112C of the third sub-pixel 108C emits a blue light when energized, and the OLED material of a fourth sub-pixel emits a different color light when energized. The third OLED material 112C may be configured to emit a wavelength of light of about 380 nm to about 500 nm.

Inorganic overhang structures 110 are disposed over the substrate 102, thereby defining each sub-pixel of the plurality of sub-pixels. In some embodiments, as shown in FIG. 1A, the inorganic overhang structures 110 are disposed over each of the PDL structures 126. The inorganic overhang structures 110 are permanent to the sub-pixel circuit. The inorganic overhang structures 110 further define each sub-pixel 106 of the sub-pixel circuit 100. The inorganic overhang structures 110 include at least an upper portion 110B disposed on a lower portion 110A. A first configuration of the inorganic overhang structures 110 includes the upper portion 110B of a non-conductive inorganic material and the lower portion 110A of a conductive inorganic material. A second configuration of the inorganic overhang structures 110 includes the upper portion 110B of a conductive inorganic material and the lower portion 110A of a conductive inorganic material. A third configuration of the inorganic overhang structures 110 includes the upper portion 110B of a non-conductive inorganic material, the lower portion 110A of a non-conductive inorganic material, and an optional assistant cathode (not shown) disposed under the lower portion 110A. A fourth configuration of the inorganic overhang structures 110 includes the upper portion 110B of a conductive inorganic material, the lower portion 110A of a non-conductive inorganic material, and an optional assistant cathode (not shown) disposed under the lower portion 110A. The first, second, third, and fourth embodiments of the sub-pixel circuit 100 include inorganic overhang structures 110 of at least one of the first, second, third, or fourth configurations. The inorganic overhang structures 110 are able to remain in place, e.g., are permanent.

The non-conductive inorganic material includes, but is not limited to, an inorganic silicon-containing material, e.g., the silicon-containing material includes oxides or nitrides of silicon, or combinations thereof. The conductive inorganic material includes, but is not limited to, a metal-containing material, e.g., the metal-containing material includes copper, titanium, aluminum, molybdenum, silver, indium tin oxide, indium zinc oxide, or combinations thereof.

At least a bottom surface 107 of the upper portion 110B is wider than a top surface 105 of the lower portion 110A to form an overhang 109. The bottom surface 107 larger than the top surface 105 forming the overhang 109 allows for the upper portion 110B to shadow the lower portion 110A. The shadowing of the overhang 109 provides for evaporation deposition each of the OLED material 112 and a cathode 114.

The OLED material, e.g., e.g., first OLED material 112A, second OLED material 112B, and third OLED material 112C, may include one or more of a HIL, a HTL, an EML, and an ETL. The OLED material, e.g., first OLED material 112A, second OLED material 112B, and third OLED material 112C, is disposed on the metal layer 104. In some embodiments, which can be combined with other embodiments described herein, the OLED material, e.g., first OLED material 112A, second OLED material 112B, and third OLED material 112C, is disposed on the metal layer 104 and over a portion of the PDL structures 126. A first cathode 114A, a second cathode 114B, and a third cathode 114C is disposed over the first OLED material 112A, second OLED material 112B, and third OLED material 112C, respectively, of the PDL structures 126 in each sub-pixel 106. The first cathode 114A, the second cathode 114B, and the third cathode 114C may be disposed on a portion of a sidewall 111 of the lower portion 110A. The first cathode 114A, the second cathode 114B, and the third cathode 114C includes a conductive material, such as a metal, e.g., chromium, titanium, aluminum, ITO, IZO, TCO or a combination thereof. In other embodiments, which can be combined with other embodiments described herein, the first OLED material 112A, second OLED material 112B, and third OLED material 112C and the first cathode 114A, the second cathode 114B, and the third cathode 114C are disposed over a top surface 115 of the upper portion 110B of the inorganic overhang structures 110, respectively.

Each sub-pixel 106 includes include an encapsulation layer 116. The encapsulation layer 116 may be or may correspond to a local passivation layer. The encapsulation layer 116 of a respective sub-pixel, e.g., first encapsulation layer 116A, second encapsulation layer 116B, and third encapsulation layer 116C, is disposed over the first cathode 114A, the second cathode 114B, and the third cathode 114C, respectively, with the encapsulation layer 116 extending under at least a portion of each of the inorganic overhang structures 110 and along a sidewall of each of the inorganic overhang structures 110. The encapsulation layer 116 is disposed over the cathode and over at least the sidewall 111 of the lower portion 110A. In some embodiments, which can be combined with other embodiments described herein, the encapsulation layer 116 is disposed over the sidewall 113 of the upper portion 110B. In some embodiments, which can be combined with other embodiments described herein, the encapsulation layer 116 is disposed over the top surface 115 of the upper portion 110B of the inorganic overhang structures 110. The encapsulation layer 116 can include a non-conductive inorganic material, such as the silicon-containing material. The silicon-containing material may include Si₃N₄ containing materials.

An intermediate layer 118 may be deposited over the encapsulation layers, as shown in FIG. 1A. The intermediate layer 118 can include a monomer and/or a polymer, e.g., an inorganic polymer or an organic polymer. In some embodiments, the intermediate layer 118 can include a thickness of about 1 μm to about 10 μm, e.g., about 1 μm to about 5 μm, about 2 μm to about 8 μm, or about 4 μm to about 6 μm. Optionally, a second encapsulation layer 120 may be deposited over the intermediate layer 118. The second encapsulation layer 120 can include any of the encapsulation layer 116. The second encapsulation layer 120 can include a thickness of about 1 μm to about 10 μm, e.g., about 1 μm to about 5 μm, about 2 μm to about 8 μm, or about 4 μm to about 6 μm.

A plurality of mask structures 122 may be disposed over the second encapsulation layer 120. The plurality of mask structures 122 can be a material suitable to absorb external and/or internal light, e.g., a black material such as a black absorbing material. The plurality of mask structures 122 are disposed according to the first sub-pixel 108A, a second sub-pixel 108B, and a third sub-pixel 108C. For example, the plurality of mask structures 122 are disposed to such that the plurality of mask structures are aligned with the PDL structures 126 and/or the inorganic overhang structures 110, thereby allowing light emission from the OLED materials through an opening between the plurality of mask structures 122.

A color filter is disposed in the opening between the plurality of mask structures 122. A first color filter 124A may be aligned with the first sub-pixel 108A, a second color filter 124B may be aligned with the second sub-pixel 108B, and a third color filter 124C may be aligned with the third sub-pixel 108C. Each of the first color filter 124A, the second color filter 124B, or the third color filter 124C may be configured to restrict light transparency from a bottom surface of the color filter to a top surface of the color filter to a specific color and/or wavelength, e.g., red, green, and/or blue. The third color filter may be configured to emit a wavelength of light of about 380 nm to about 500 nm. For example, the first color filter 124A may receive a yellow, white, and/or red light and restrict light transparency to the color red, thereby only emitting red emission from the first sub-pixel 108A. As a further example, the second color filter 124B may receive a yellow, white, and/or red light and may restrict light transparency to the color green, thereby only emitting green emission from the second sub-pixel 108B. As a further example, the third color filter 124C may receive a blue, white, and/or yellow light and may restrict light transparency to the color blue, thereby only emitting blue emission from the third sub-pixel 108C.

Optionally, the plurality of mask structures 122 and the color filters, e.g., the first color filter 124A, the second color filter 124B, or the third color filter 124C may be disposed on a backing material 130, as shown in FIG. 1B. The backing material 130 can include a transparent material suitable for supporting the plurality of mask structures 122 and the color filters, e.g., the first color filter 124A, the second color filter 124B, or the third color filter 124C. The plurality of mask structures 122 and the color filters, e.g., the first color filter 124A, the second color filter 124B, or the third color filter 124C may be disposed on the backing material 130, inverted, and placed on the intermediate layer 118, as shown in FIG. 1B, thereby allowing for manufacturing of the color filters to occur in parallel with the manufacturing of the sub-pixels, and reducing the time for manufacturing.

Optionally, the plurality of mask structures 122 may be deposited over the encapsulation layer 116, e.g., the first encapsulation layer 116A, the second encapsulation layer 116B, and/or the third encapsulation layer 116C, as shown in FIG. 1C. The color filters, e.g., the first color filter 124A, the second color filter 124B, or the third color filter 124C, are disposed over the first encapsulation layer 116A, and between the plurality of mask structures 122. Without being bound by theory, by disposing the color filters over the first encapsulation layer 116A, a reduction of manufacturing costs may occur.

FIG. 1D-1F are schematic, cross-sectional views of a sub-pixel circuit 100, according to one or more embodiments. The sub-pixel circuits 100 shown in FIGS. 1D-1F is similar to the sub-pixel circuits 100 shown in FIGS. 1A-1C, and include one or more of the aspects, features, components, properties, and/or operations thereof. The sub-pixel circuits 100 of FIG. 1D-1F include the first sub-pixel 108A, the second sub-pixel 108B, the third sub-pixel 108C have metal layers 104 with the same thickness. I.e., the thickness of first metal layer 104A, the thickness of the second metal layer 104B, and the thickness of the third metal layer 104C is the same for each of the first sub-pixel 108A, the second sub-pixel 108B, and the third sub-pixel 108C. FIG. 1D corresponds to FIG. 1A with metal layers 104 of each of the first sub-pixel 108A, the second sub-pixel 108B, the third sub-pixel 108C having the same thickness. FIG. 1E corresponds to FIG. 1B with metal layers 104 of each of the first sub-pixel 108A, the second sub-pixel 108B, the third sub-pixel 108C having the same thickness. FIG. 1F corresponds to FIG. 1C with metal layers 104 of each of the first sub-pixel 108A, the second sub-pixel 108B, the third sub-pixel 108C having the same thickness.

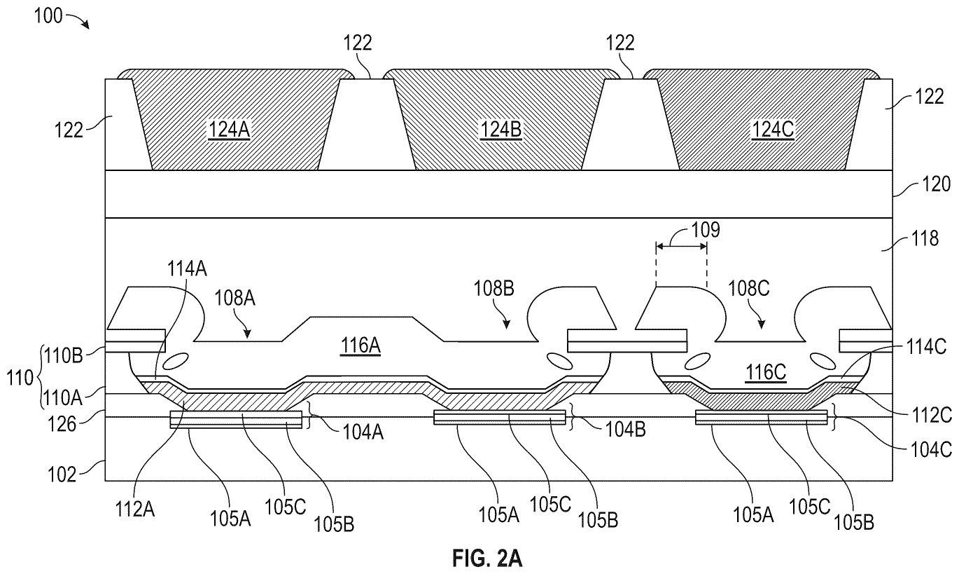

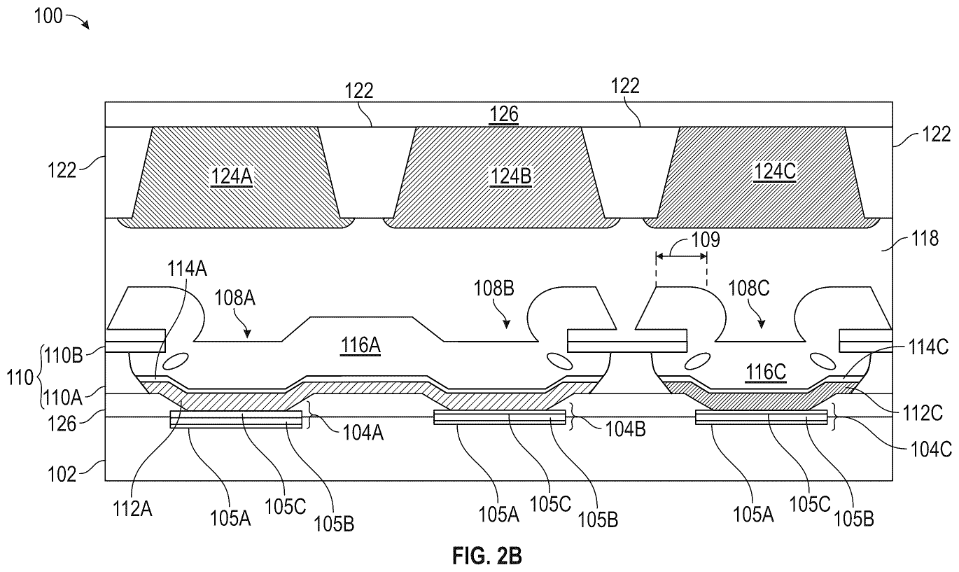

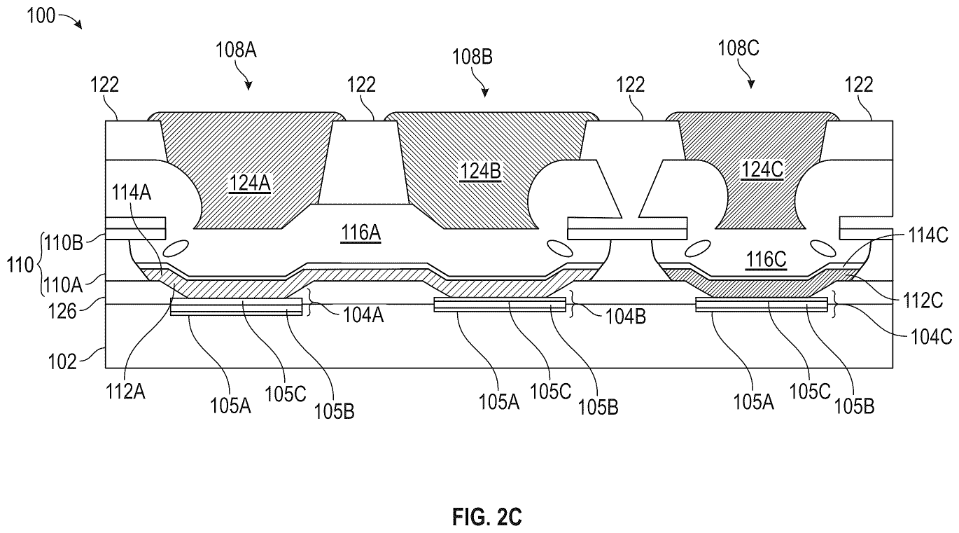

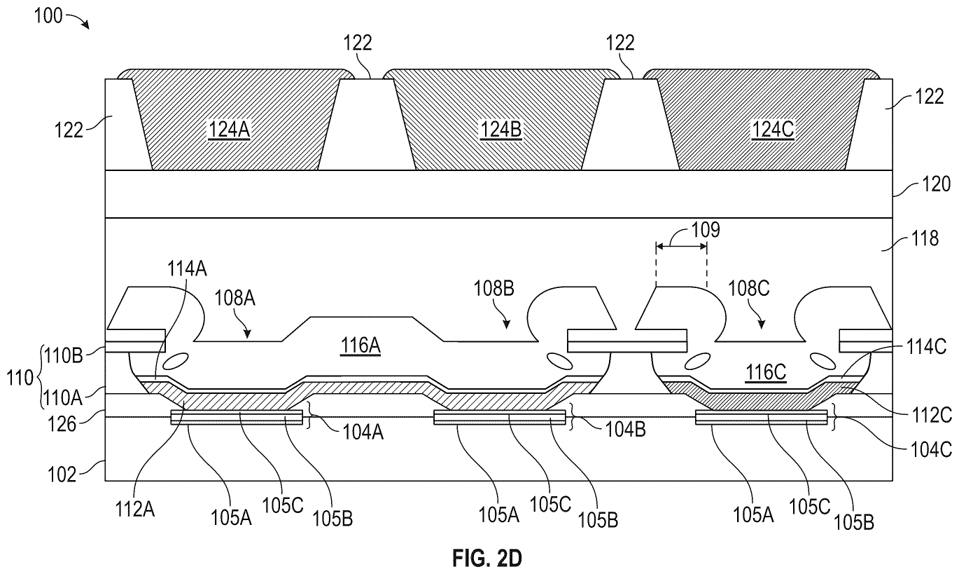

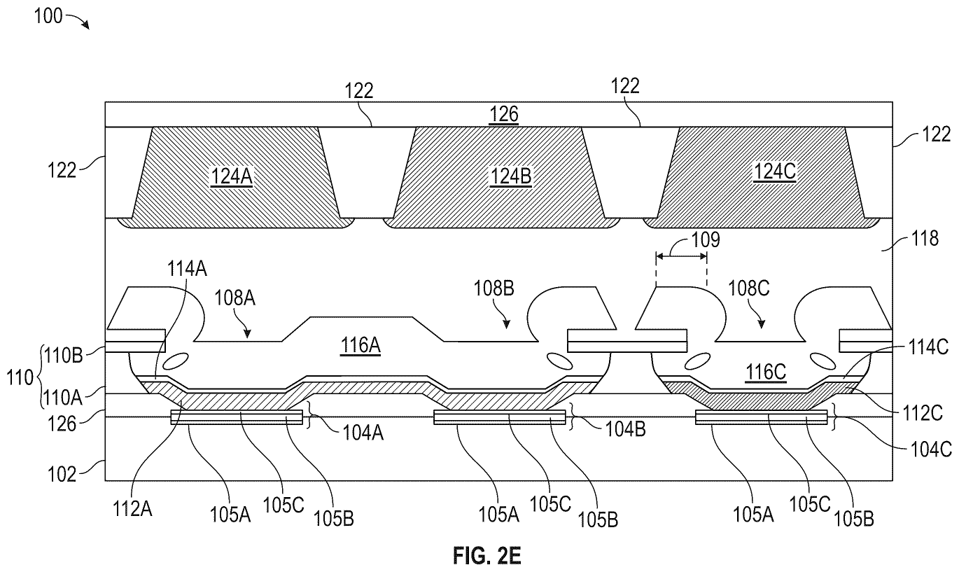

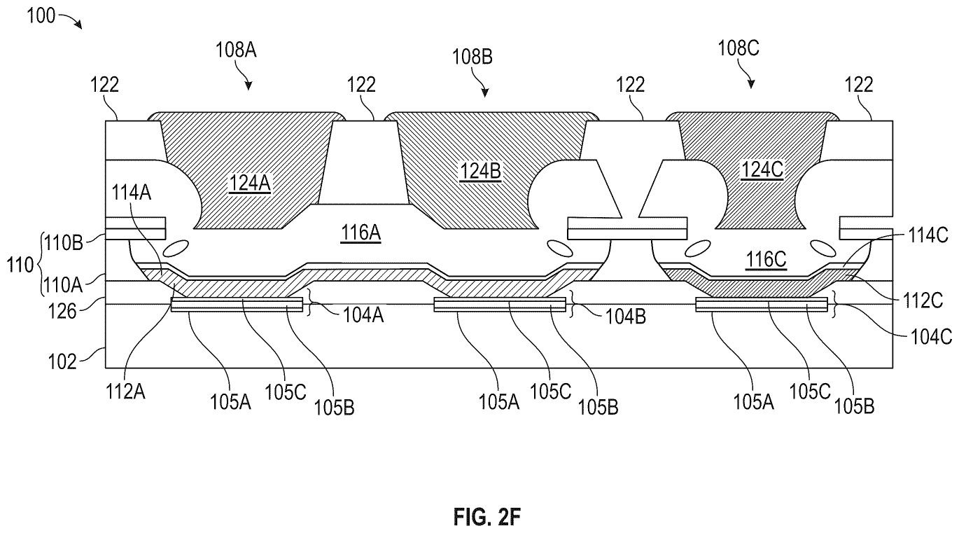

FIG. 2A is a schematic, cross-sectional view of a sub-pixel circuit 100 having the first OLED material 112A and the first cathode 114A shared across the first sub-pixel 108A and the second sub-pixel 108B. The first OLED material 112A can include a yellow and/or white emitting OLED material, as described herein. The first OLED material 112A and the first cathode 114A may be shared due to a removal of an inorganic overhangs structure 110 between the first sub-pixel 108A and the second sub-pixel 108B.

The third sub-layer 105C of the first sub-pixel 108A is thicker than a third sub-layer 105C of the second sub-pixel 108B. Without being bound by theory, by having the third sub-layer 105C of the first sub-pixel 108A be thicker than the third sub-layer 105C of the second sub-pixel 108B, the light emitted from the first OLED material 112A over the first sub-pixel 108A may be red-shifted compared to the light emission from the second OLED material 112B of the second sub-pixel 108B. Additionally, and without being bound by theory, a reduction of manufacturing costs occurs due to the reduced materials required to produce the sub-pixel circuit 100, e.g., reduction of overhang structures, and reduction of individualized OLED materials.

Optionally, the plurality of mask structures 122 and the color filters, e.g., the first color filter 124A, the second color filter 124B, or the third color filter 124C may be disposed on a backing material 130, as shown in FIG. 2B. The backing material 130 can include a transparent material suitable for supporting the plurality of mask structures 122 and the color filters, e.g., the first color filter 124A, the second color filter 124B, or the third color filter 124C. The plurality of mask structures 122 and the color filters, e.g., the first color filter 124A, the second color filter 124B, or the third color filter 124C may be disposed on the backing material 130, inverted, and placed on the intermediate layer 118, as shown in FIG. 2B, thereby allowing for manufacturing of the color filters to occur in parallel with the manufacturing of the sub-pixels, and reducing the time for manufacturing.

Optionally, the plurality of mask structures 122 may be patterned over the encapsulation layer 116, e.g., the first encapsulation layer 116A, the second encapsulation layer 116B, and/or the third encapsulation layer 116C, as shown in FIG. 2C. The plurality of mask structures 122 may be patterned such that the plurality of mask structures directly contacts the top surface 115 of the upper portion 110B. The color filters, e.g., the first color filter 124A, the second color filter 124B, or the third color filter 124C, are disposed over the first encapsulation layer 116A, and between the plurality of mask structures 122. Without being bound by theory, by disposing the color filters over the first encapsulation layer 116A, a reduction of manufacturing costs may occur.

FIG. 2D-2F are schematic, cross-sectional views of a sub-pixel circuit 100, according to one or more embodiments. The sub-pixel circuits 100 shown in FIGS. 2D-2F is similar to the sub-pixel circuits 100 shown in FIGS. 2A-2C, and include one or more of the aspects, features, components, properties, and/or operations thereof. The sub-pixel circuits 100 of FIG. 2D-2F include the first sub-pixel 108A, the second sub-pixel 108B, the third sub-pixel 108C have metal layers 104 with the same thickness. I.e., the thickness of first metal layer 104A, the thickness of the second metal layer 104B, and the thickness of the third metal layer 104C is the same for each of the first sub-pixel 108A, the second sub-pixel 108B, and the third sub-pixel 108C. FIG. 2D corresponds to FIG. 2A with metal layers 104 of each of the first sub-pixel 108A, the second sub-pixel 108B, the third sub-pixel 108C having the same thickness. FIG. 2E corresponds to FIG. 2B with metal layers 104 of each of the first sub-pixel 108A, the second sub-pixel 108B, the third sub-pixel 108C having the same thickness. FIG. 2F corresponds to FIG. 2C with metal layers 104 of each of the first sub-pixel 108A, the second sub-pixel 108B, the third sub-pixel 108C having the same thickness.

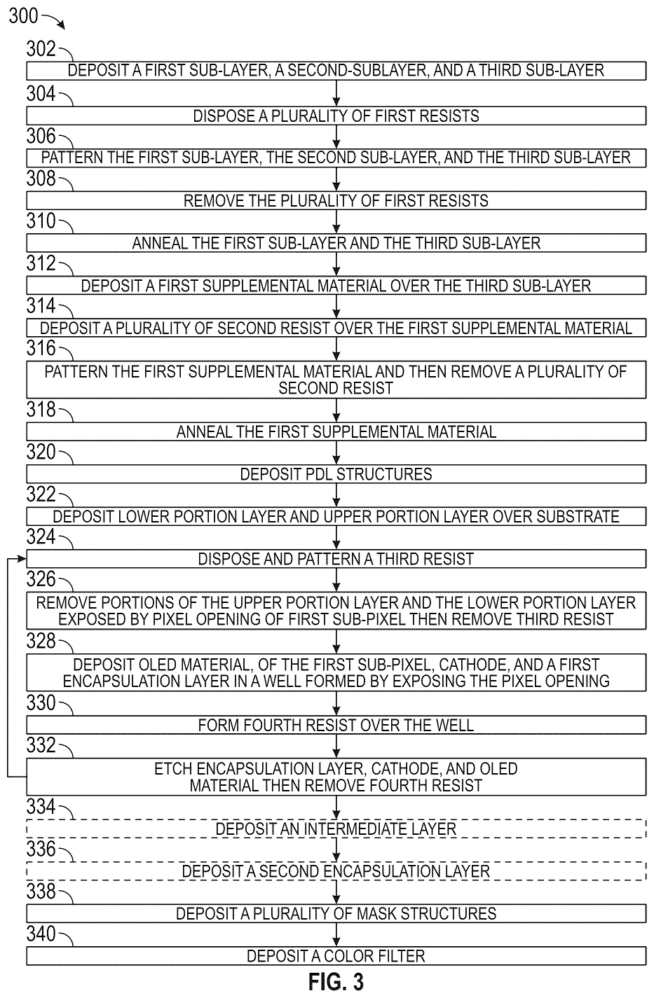

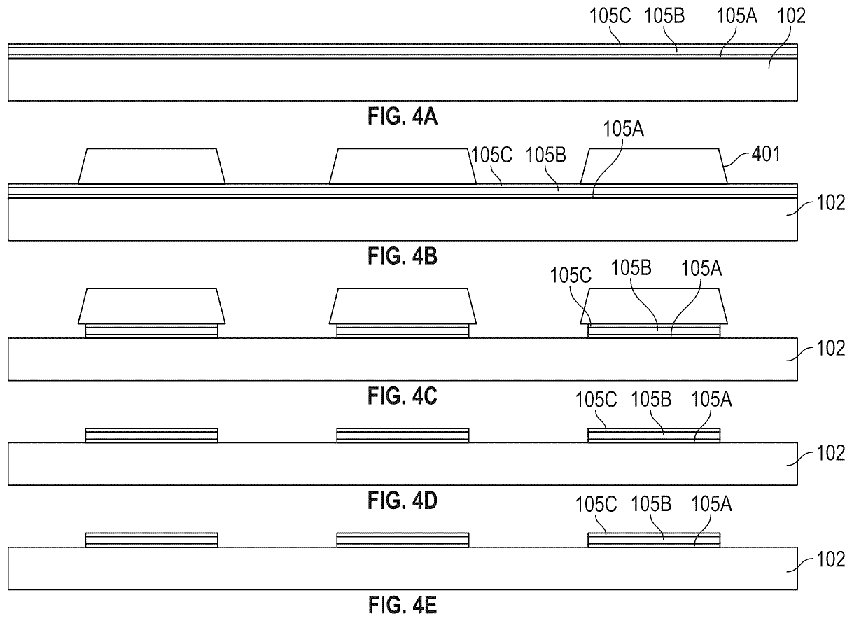

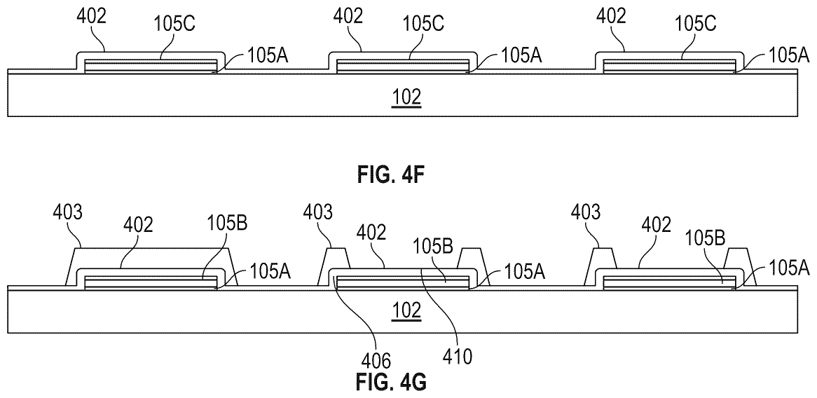

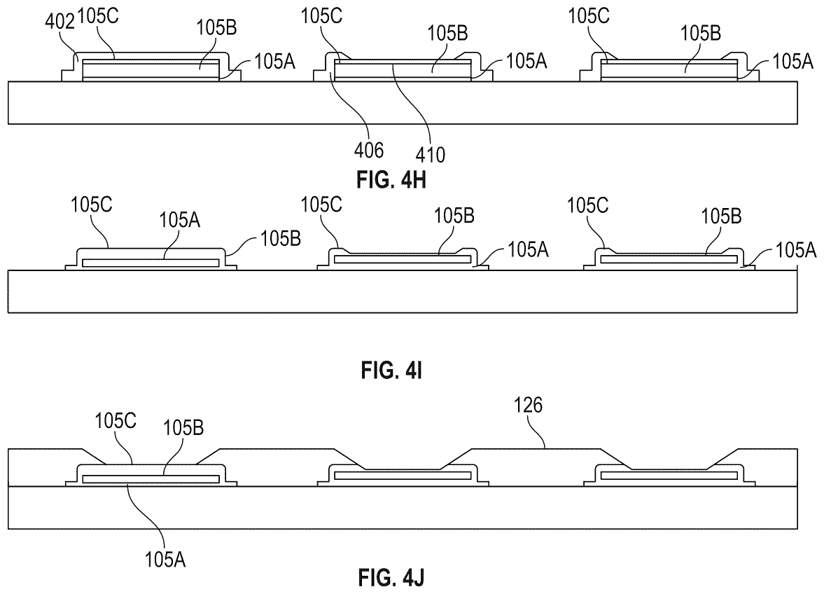

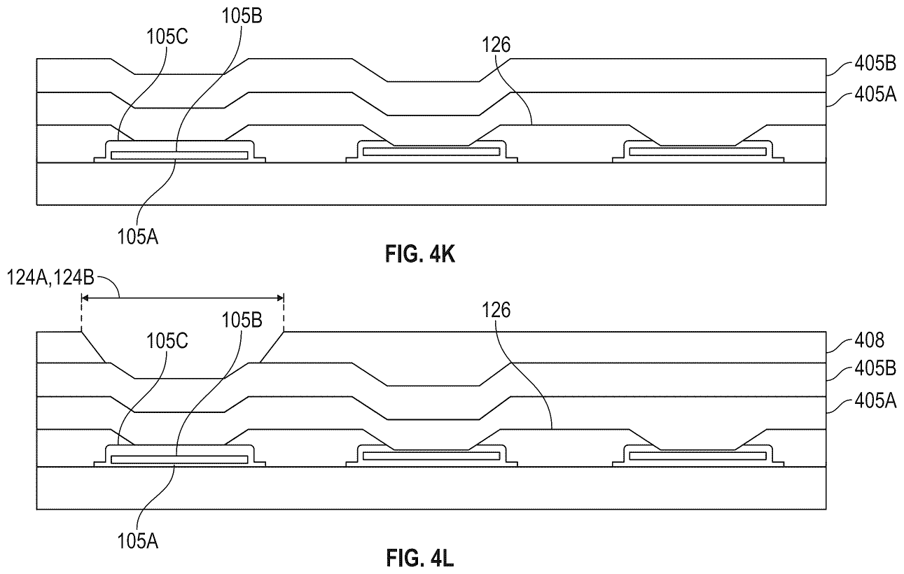

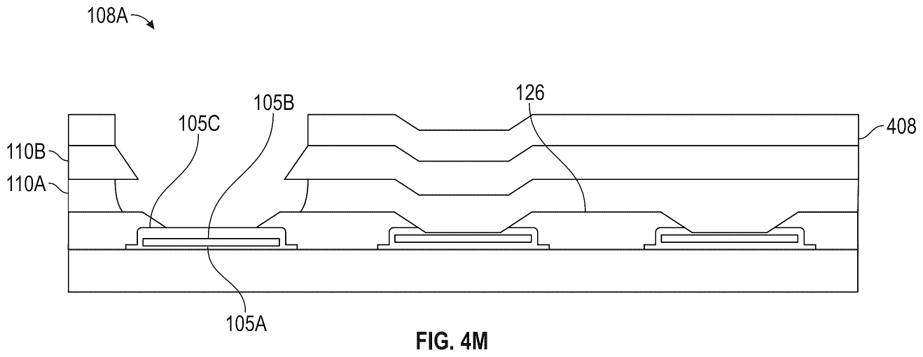

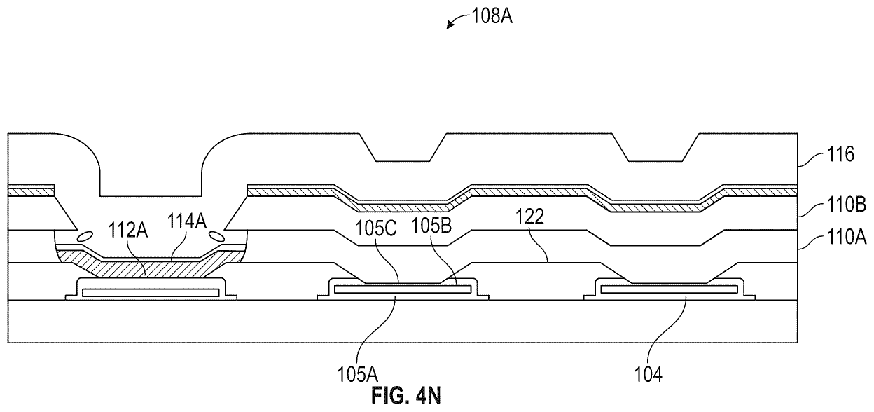

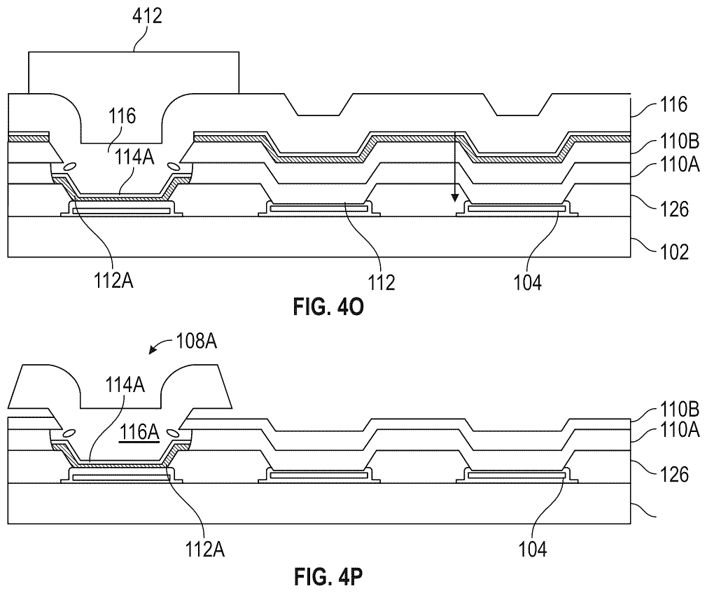

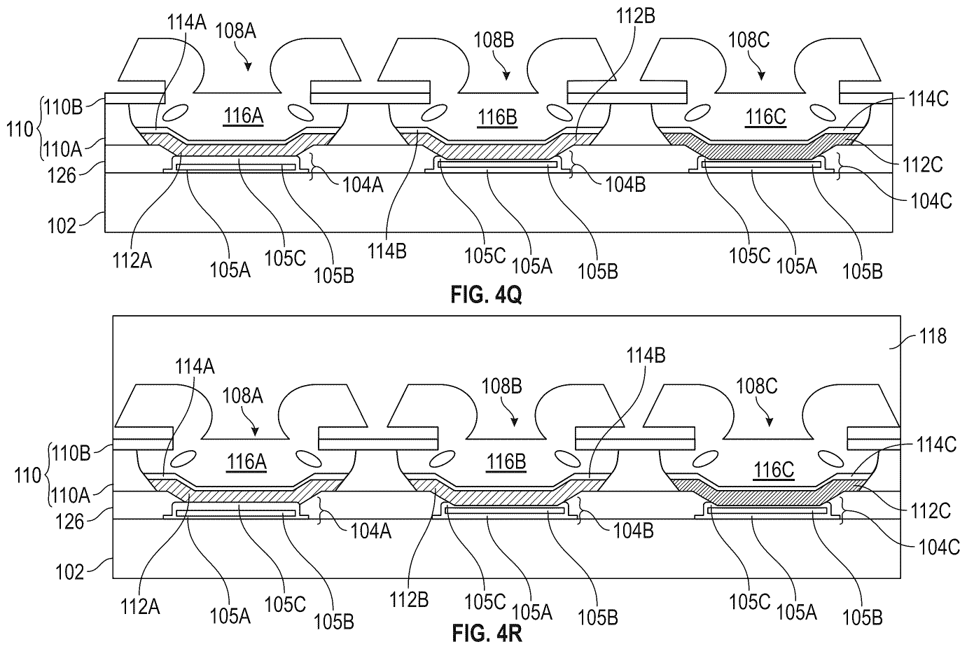

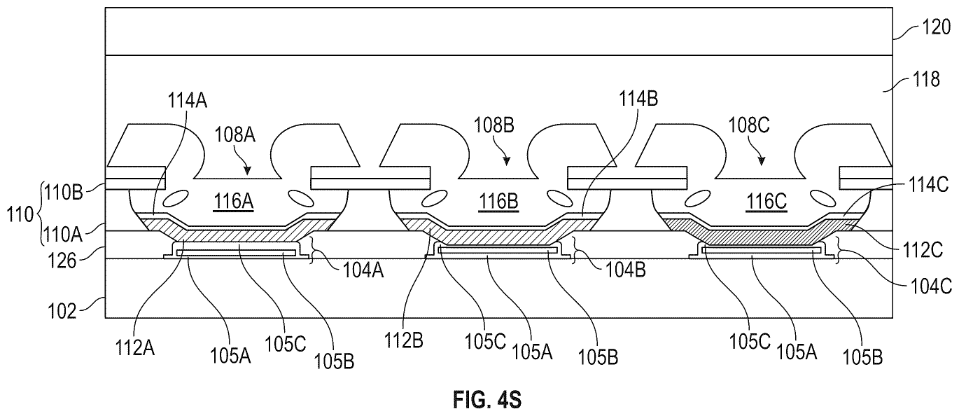

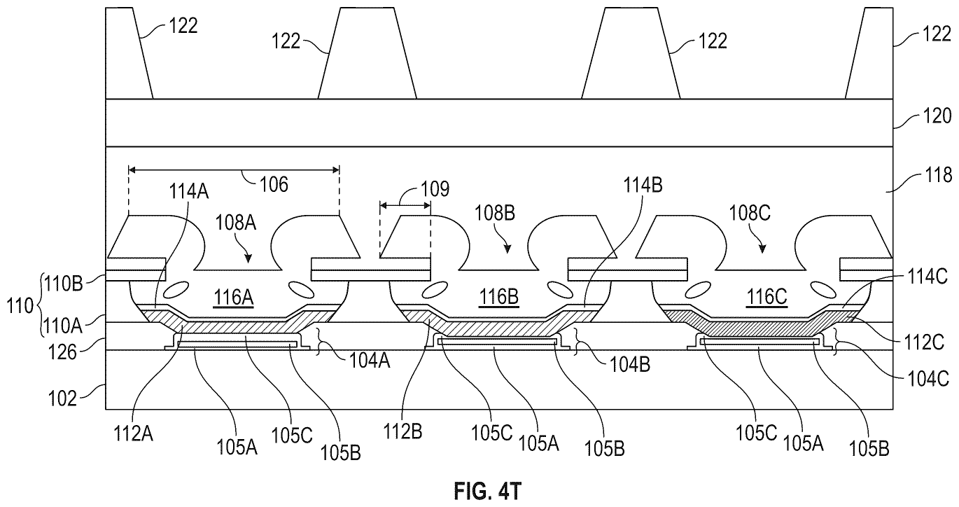

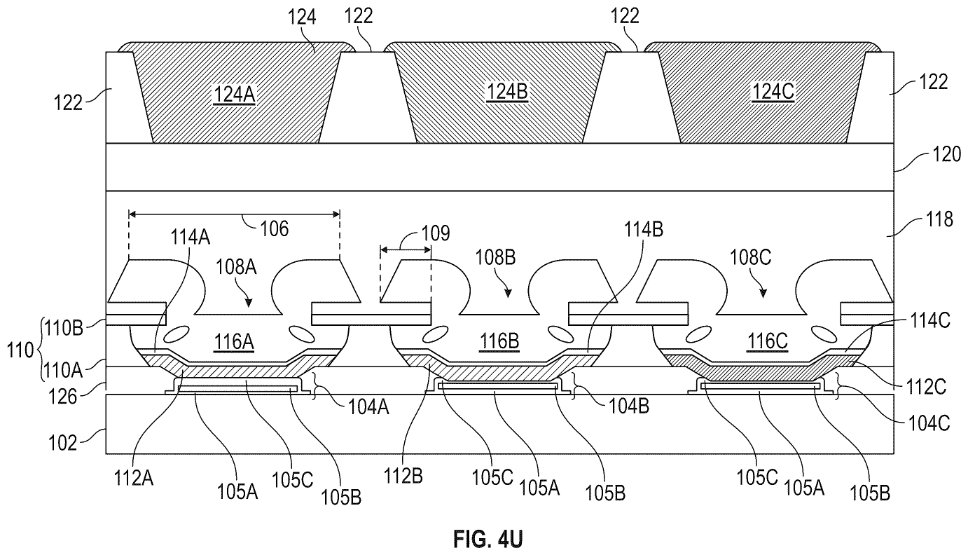

FIG. 3 is a flow a flow diagram of a method 300 for forming a sub-pixel circuit 100. FIGS. 4A-4U are schematic, cross-sectional views of a substrate 102 during the method 300 for forming the sub-pixel circuit 100 according embodiments described herein.

At operation 302, as shown in FIG. 4A, a first sub-layer 105A, a second sub-layer 105B, and a third sub-layer 105C is deposited on a substrate 102. The first sub-layer 105A, and the third sub-layer 105C include an amorphous transparent conductive oxide, e.g., amorphous indium tin oxide. The second sub-layer 105B includes a metal layer such as a silver layer. At operation 304, as shown in FIG. 4B, a plurality of first resists 401 are disposed the third sub-layer 105C. The plurality of first resists are deposited over the third sub-layer 105C such that each of a first metal layer 104A, a second metal layer 104B, and a third metal layer 104C is covered by each first resist of the plurality of first resists 401. At operation 306, as shown in FIG. 4C, the first sub-layer 105A, the second sub-layer 105B, and the third sub-layer 105C is patterned to form the first metal layer 104A, the second metal layer 104B, and the third metal layer 104C. The patterning is one of a photolithography, digital lithography process, or laser ablation process.

At operation 308, as shown in FIG. 4D, plurality of first resists 401 are removed to expose the first metal layer 104A, the second metal layer 104B, and the third metal layer 104C. At operation 310, as shown in FIG. 4E, the first sub-layer 105A and the third sub-layer 105C are annealed according to an annealing process. The first sub-layer 105A and the third sub-layer 105C are annealed to produce a poly-crystallized transparent conductive oxide from the amorphous transparent conductive oxide. For example, the first sub-layer 105A and the third sub-layer 105C may be annealed to form a poly-crystallized indium tin oxide.

At operation 312, as shown in FIG. 4F, a first supplemental material 402 is deposited over the third sub-layer 105C. It is contemplated that operation 312 is optional while performing the method 300. The first supplemental material 402 includes an amorphous transparent conductive oxide, e.g., amorphous indium tin oxide and/or amorphous indium zinc oxide. The first supplemental material 402 can be deposited to provide a thickness of about 50 nm to about 200 nm. The first supplemental material 402 can include a first oxide layer disposed over the third sub-layer 105C and/or the substrate 102 and a second oxide layer disposed over the first oxide layer. The second oxide layer can include a first amorphous transparent conductive oxide such as amorphous indium zinc oxide. The second oxide layer can include a second amorphous transparent conductive oxide such as amorphous indium tin oxide.

The first oxide layer can include a thickness of about 45 nm to about 160 nm. The second oxide layer can include a thickness of about less than 40 nm, e.g., about 5 nm to about 40 nm. Without being bound by theory, by reducing the thickness of the second oxide layer to be less than 40 nm, a reduction of partial crystallization of the second oxide layer may occur, thereby improving an etch selectivity and/or efficiency during subsequent processing steps. For example, a thickness of about 40 nm or less of indium tin oxide may have greater etch selectivity and/or efficiency compared to a thickness of about 50 nm or greater of indium tin oxide. Additionally, and without being bound by theory, a first supplemental material 402 including a first oxide layer comprising indium zinc oxide having a thickness of about 45 nm to about 160 nm, and a second oxide layer comprising indium tin oxide having a thickness of less than 40 nm may provide enhanced etch selectivity and/or efficiency during subsequent processing steps, e.g., etching such as etching with oxalic acid.

At operation 314, as shown in FIG. 4G, a plurality of second resists 403 is deposited over the first supplemental material 402. It is contemplated that operation 314 is optional while performing the method 300. The plurality of second resists 403 is deposited over the first supplemental material 402 such that a first metal layer 104A is covered by the plurality of second resists 403. Optionally, the plurality of second resists 403 may be deposited over a lateral edge 406 of a second metal layer 104B and a third metal layer 104C, thereby exposing a top central surface 410 of the second metal layer 104B and the third metal layer 104C. Without being bound by theory, the plurality of second resists 403 may be deposited over the lateral edge of the second metal layer 104B and the third metal layer 104C such that the third sub-layer 105C does not get etched over the lateral edge, thereby providing enhanced protection of the edge of the second sub-layer 105B.

The plurality of second resists 403 is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the plurality of second resists 403 determines whether the resist is a positive resist or a negative resist.

At operation 316, as shown in FIG. 4H, the first supplemental material 402 is patterned and the plurality of second resists 403 are removed. It is contemplated that operation 316 is optional while performing the method 300. The patterning is one of a photolithography, digital lithography process, or laser ablation process. At operation 318, as shown in FIG. 4I, the second oxide layer of the first supplemental material 402 is annealed. It is contemplated that operation 318 is optional while performing the method 300. The first oxide layer remains an amorphous transparent conductive oxide, e.g., amorphous indium zinc oxide. The second oxide layer of the first supplemental material 402 is annealed to produce a poly-crystallized transparent conductive oxide from the amorphous transparent conductive oxide. For example, the second oxide layer of the first supplemental material 402 may be annealed to form a poly-crystallized indium tin oxide. In some embodiments, which may be combined with other embodiments, by annealing the second oxide layer of the first supplemental material 402 to produce a poly-crystallized transparent conductive oxide, the second oxide layer of the first supplemental material 402 may be similar to the third sub-layer 105C. For example, the second oxide layer of the first supplemental material 402, when annealed, may become the third sub-layer 105C. At operation 320, as shown in FIG. 4J, PDL structures 126 are deposited over the substrate 102 such that only the metal layers 104 remain exposed. In one or more embodiments, operations 312 to 318 are omitted from the method 300. In one or more embodiments, operation 320 is performed subsequent to operation 310. In one or more embodiments, the first metal layer 104A, the second metal layer 104B, and the third metal layer 104C have the same thickness as one another. In one or more embodiments, operation 320 is performed immediately subsequent to operation 310, such that each metal layer 104 has the same thickness as shown in FIGS. 1D-1F and FIGS. 2D-2F.

At operation 322, as shown in FIG. 4K, a lower portion layer 405A and an upper portion layer 405B are deposited over the substrate 102. The lower portion layer 405A is disposed over the PDL structures 126 and the metal layers 104, e.g., the first metal layer 104A, the second metal layer 104B, and the third metal layer 104C. The upper portion layer 405B is disposed over the lower portion layer 405A. In various embodiments, the lower portion layer 405A corresponds to the lower portion 110A and the upper portion layer 405B corresponds to the upper portion 110B of the inorganic overhang structures 110. In some embodiments, an assistant cathode layer is disposed between the lower portion layer 405A and the PDL structures 126 and the metal layers 104.

At operation 324, as shown in FIG. 4L, a third resist 408 is disposed and patterned. The third resist 408 is disposed over the upper portion layer 405B. The third resist 408 is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the third resist 408 determines whether the resist is a positive resist or a negative resist. The third resist 408 is patterned to form one of a pixel opening of a first sub-pixel 108a. The patterning is one of a photolithography, digital lithography process, or laser ablation process.

At operation 326, as shown in FIG. 4M, portions of the upper portion layer 405B and the lower portion layer 405A exposed by the pixel opening are removed and the third resist 408 is removed. The upper portion layer 405B exposed by the pixel opening may be removed by a dry etch process. The lower portion layer 405A exposed by the pixel opening may be removed by a wet etch process. In embodiments including the assistant cathode layer, a portion of the assistant cathode layer may be removed by a dry etch process or a wet etch process to form an assistant cathode (not shown) disposed under the lower portion 110A. Operation 326 forms the inorganic overhang structures 110 of the first sub-pixel 108a. The etch selectivity of the materials of the upper portion layer 405B (corresponding to the upper portion 110B) and the lower portion layer 405A (corresponding to the lower portion 110A) coupled with the etch processes can remove the exposed portions of the upper portion layer 405B and the lower portion layer 405A. This can provide for the bottom surface 107 of the upper portion 110B being wider than the top surface 105 of the lower portion 110A, thereby forming the overhang 109 (as shown in FIGS. 1A-1F).

At operation 328, as shown in FIG. 4N, the first OLED material 112A of the first sub-pixel 108a, the first cathode 114A, and the first encapsulation layer 116A are deposited. In some embodiments, the first OLED material 112A does not contact the lower portion 110A and the first cathode 114A directly contacts the lower portion 110A of the inorganic overhang structures 110. The first encapsulation layer 116A is deposited over the first cathode 114A. In embodiments including capping layers (not shown), the capping layers are deposited between the first cathode 114A and the first encapsulation layer 116A. The capping layers may be deposited by evaporation deposition.

At operation 330, as shown in FIG. 4O, a fourth resist 412 is formed in a well of the first sub-pixel 108a and over the first encapsulation layer 116A disposed on the upper portion layer 402B. The fourth resist 412 can be formed in the well, in which the fourth resist 412 can fill the sub-pixel and produce a second resist thickness of about 0.1 μm to about 10 μm, e.g., about 0.1 μm to about 8 μm, about 0.5 μm to about 5 μm, or about 0.9 μm to about 1.1 μm, over the upper portion 110B. At operation 332, as shown in FIG. 4P the first encapsulation layer 116A, the first cathode 114A, and the first OLED material 112A are etched, and the fourth resist 412 is removed, wherein the portion of the fourth resist 412 that is removed is disposed outside of the well. For example, the portion of the fourth resist 412 that is removed can include the portion of the fourth resist that is disposed over the upper portion 110B. The fourth resist 412 may be removed by a plasma ashing process.

Operations 324-332 are repeated to produce the second sub-pixel 108B and the third sub-pixel 108C, as shown in FIG. 4Q. In some embodiments, which can be combined with other embodiments, operations 324-332 can be iteratively repeated to provide for the formation of a plurality of sub-pixels. Each sub-pixel of the plurality of sub-pixels can include an OLED for a specific color, e.g., white, green, red, blue, or a combination thereof.

Optionally, at operation 334, as shown in FIG. 4R, an intermediate layer 118 may be deposited over the first encapsulation layer 116A, the second encapsulation layer 116B, the third encapsulation layer 116C, and the plurality of inorganic overhang structures 110. The intermediate layer 118 can include a monomer and/or a polymer, e.g., an inorganic polymer or an organic polymer. In some embodiments, the intermediate layer 118 can include a thickness of about 1 μm to about 10 μm, e.g., about 1 μm to about 5 μm, about 2 μm to about 8 μm, or about 4 μm to about 6 μm. Optionally, at operation 336, as shown in FIG. 4S, a second encapsulation layer 120 is deposited over the intermediate layer 118. The second encapsulation layer 120 can include any of the encapsulation layer 116. The second encapsulation layer 120 can have a thickness of about 1 μm to about 10 μm, e.g., about 1 μm to about 5 μm, about 2 μm to about 8 μm, or about 4 μm to about 6 μm.

At operation 338, as shown in FIG. 4T, a plurality of mask structures 122 are disposed over the encapsulation layer 116, the intermediate layer 118, and/or the second encapsulation layer 120. The plurality of mask structures 122 may be disposed according to the first sub-pixel 108A, a second sub-pixel 108B, and a third sub-pixel 108C. For example, the plurality of mask structures 122 may be disposed such that the mask structures align with the PDL structures 126 and/or the inorganic overhang structures 110, thereby allowing light emission emitted from the OLED materials through an opening between the plurality of mask structures 122.

At operation 340, as shown in FIG. 4U, a color filter 124 is disposed in the opening between the plurality of mask structures 122. A first color filter 124A may be aligned with the first sub-pixel 108A, a second color filter 124B may be aligned with the second sub-pixel 108B, and a third color filter 124C may be aligned with the third sub-pixel 108C. Each of the first color filter 124A, the second color filter 124B, or the third color filter 124C may be configured to restrict light transparency from a bottom surface of the color filter to a top surface of the color filter to a specific color and/or wavelength, e.g., red, green, and/or blue. For example, the first color filter 124A may receive a yellow, white, and/or red light and restrict light transparency to the color red, thereby only emitting red emission from the first sub-pixel 108A. As a further example, the second color filter 124B may receive a yellow, white, and/or red light and may restrict light transparency to the color green, thereby only emitting green emission from the second sub-pixel 108B. As a further example, the third color filter 124C may receive a blue, white, and/or yellow light and may restrict light transparency to the color blue, thereby only emitting blue emission from the third sub-pixel 108C.

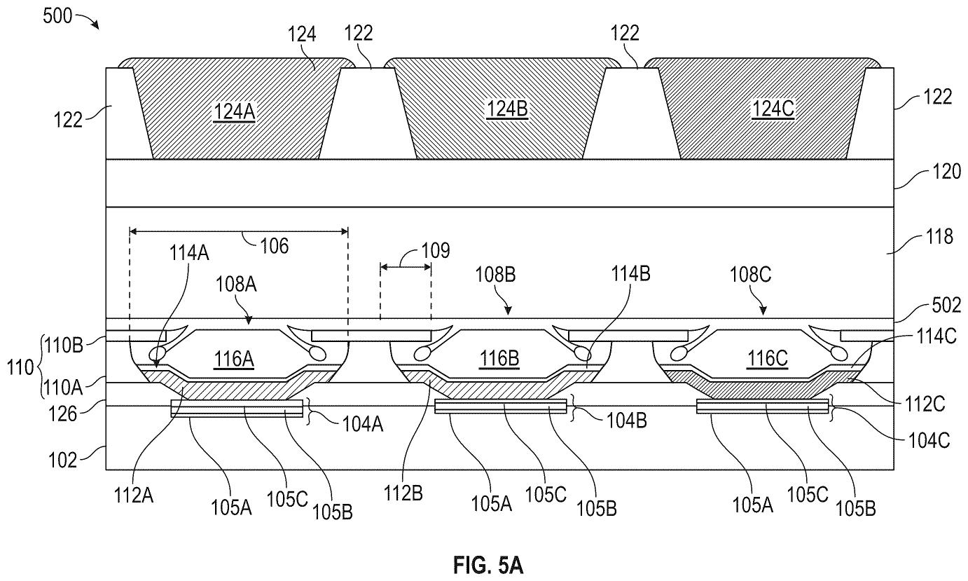

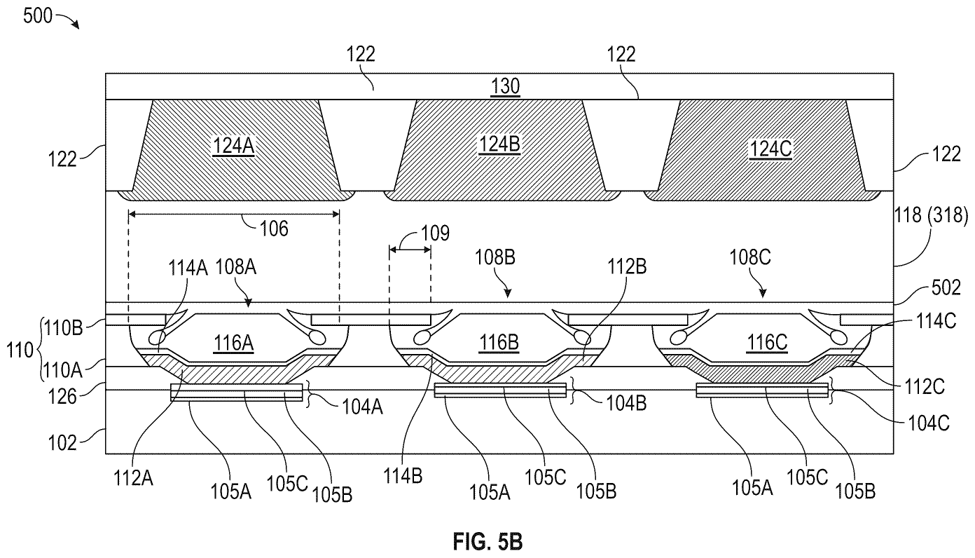

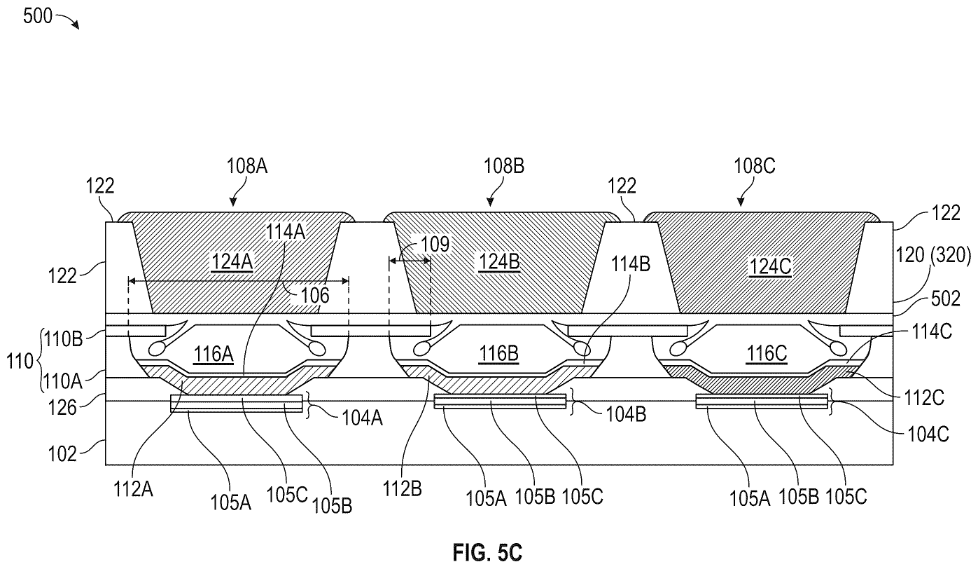

FIG. 5A is a schematic, cross-sectional view of a sub-pixel circuit 500. The sub-pixel circuit 500 includes a substrate 102. Metal layers 104 are be patterned on the substrate 102. The metal layers 104 are configured to operate anodes of respective sub-pixels. The metal layers 104 are a layer stack of a first sub-layer 105A, a second sub-layer 105B disposed over the first sub-layer 105A, and a third sub-layer 105C disposed over the second sub-layer 105B. The first sub-layer 105A includes a transparent conductive oxide (TCO) layer, e.g., indium tin oxide or indium zinc oxide. The first sub-layer 105A can include a thickness of about 1 nm to about 50 nm.

The second sub-layer 105B includes a metal layer, e.g., chromium, titanium, gold, silver, copper, aluminum, or a combination thereof, disposed on the first sub-layer 105A. The second sub-layer 105B can include a thickness of about 50 nm to about 200 nm.

The third sub-layer 105C includes a transparent conductive oxide (TCO) layer, e.g., indium tin oxide or indium zinc oxide. The third sub-layer 105C can include a thickness of about 1 nm to about 200 nm. Optionally, the third sub-layer 105C has a thickness that is greater than the thickness of the first sub-layer 105A and/or the second sub-layer 105B. Without being bound by theory, a thicker third sub-layer 105C can allow for controllable wavelength emission of the OLED material, thereby reducing power requirements during operation of the sub-pixel circuit 500.

In an embodiment, which can be combined with other embodiments described herein, the third sub-layer 105C of a first sub-pixel 108A is thicker than a third sub-layer 105C of a second sub-pixel 108B and/or a third sub-pixel 108C. Without being bound by theory, by having the third sub-layer 105C of a first sub-pixel 108A be thicker than the third sub-layer 105C of the second sub-pixel 108B and/or the third sub-pixel 108C, the light emitted from the first OLED material 112A may be red-shifted, thereby causing emission of a yellow and/or white emitting OLED material to be more red.

In one embodiment, which can be combined with other embodiments described herein, the metal layers 104 are pre-patterned on the substrate 102, e.g., the substrate 102 is a pre-patterned indium tin oxide (ITO) glass substrate. In one embodiment, which can be combined with other embodiments described herein, the metal layers 104 are pre-patterned on the substrate 102, e.g., the metal layers 104 include a first sub-layer 105A of indium tin oxide, a second sub-layer 105B of silver, and a third sub-layer 105C of indium tin oxide.

The pixels are defined by adjacent pixel-defining layer (PDL) structures disposed on the substrate 102. The PDL structures 126 can be disposed on the substrate 102. The PDL structures 126 include one of an organic material, an organic material with an inorganic coating disposed thereover, or an inorganic material. The organic material of the PDL structures 126 includes, but is not limited to, polyimides. The inorganic material of the PDL structures 126 includes, but is not limited to, silicon oxide (SiO₂), silicon nitride (Si₃N₄), silicon oxynitride (Si₂N₂O), magnesium fluoride (MgF₂), or combinations thereof. Adjacent PDL structures define a respective sub-pixel and expose the anode (i.e., metal layer 104) of the respective sub-pixel of the sub-pixel circuit 100.

The sub-pixel circuit 500 has a plurality of sub-pixels 106 including at least a first sub-pixel 108A, a second sub-pixel 108B, and a third sub-pixel 108C. While the Figures depict the first sub-pixel 108A, the second sub-pixel 108B, and the third sub-pixel 108C, the sub-pixel circuit 100 of the embodiments described herein may include three or more sub-pixels 106, such as a fourth and a fifth sub-pixel. Each sub-pixel 106 has an OLED material, e.g., first OLED material 112A, second OLED material 112B, and third OLED material 112C, configured to emit a white, red, green, blue or other color light when energized, e.g., the first OLED material 112A of the first sub-pixel 108A emits a yellow light when energized, the second OLED material 112B of the second sub-pixel 108B emits a yellow light when energized, the third OLED material 112C of the third sub-pixel 108C emits a blue light when energized, and the OLED material of a fourth sub-pixel emits a different color light when energized.

Inorganic overhang structures 110 are disposed over the substrate 102, thereby defining each sub-pixel of the plurality of sub-pixels. In some embodiments, as shown in FIG. 5A, the inorganic overhang structures 110 are disposed over each of the PDL structures 126. The inorganic overhang structures 110 are permanent to the sub-pixel circuit. The inorganic overhang structures 110 further define each sub-pixel 106 of the sub-pixel circuit 100. The inorganic overhang structures 110 include at least an upper portion 110B disposed on a lower portion 110A. A first configuration of the inorganic overhang structures 110 includes the upper portion 110B of a non-conductive inorganic material and the lower portion 110A of a conductive inorganic material. A second configuration of the inorganic overhang structures 110 includes the upper portion 110B of a conductive inorganic material and the lower portion 110A of a conductive inorganic material. A third configuration of the inorganic overhang structures 110 includes the upper portion 110B of a non-conductive inorganic material, the lower portion 110A of a non-conductive inorganic material, and an optional assistant cathode (not shown) disposed under the lower portion 110A. A fourth configuration of the inorganic overhang structures 110 includes the upper portion 110B of a conductive inorganic material, the lower portion 110A of a non-conductive inorganic material, and an optional assistant cathode (not shown) disposed under the lower portion 110A. The first, second, third, and fourth embodiments of the sub-pixel circuit 100 include inorganic overhang structures 110 of at least one of the first, second, third, or fourth configurations. The inorganic overhang structures 110 are able to remain in place, e.g., are permanent.

The non-conductive inorganic material includes, but is not limited to, an inorganic silicon-containing material, e.g., the silicon-containing material includes oxides or nitrides of silicon, or combinations thereof. The conductive inorganic material includes, but is not limited to, a metal-containing material, e.g., the metal-containing material includes copper, titanium, aluminum, molybdenum, silver, indium tin oxide, indium zinc oxide, or combinations thereof.

At least a bottom surface 107 of the upper portion 110B is wider than a top surface 105 of the lower portion 110A to form an overhang 109. The bottom surface 107 larger than the top surface 105 forming the overhang 109 allows for the upper portion 110B to shadow the lower portion 110A. The shadowing of the overhang 109 provides for evaporation deposition each of the OLED material 112 and a cathode 114.

The OLED material, e.g., e.g., first OLED material 112A, second OLED material 112B, and third OLED material 112C, may include one or more of a HIL, a HTL, an EML, and an ETL. The OLED material, e.g., first OLED material 112A, second OLED material 112B, and third OLED material 112C, is disposed on the metal layer 104. In some embodiments, which can be combined with other embodiments described herein, the OLED material, e.g., first OLED material 112A, second OLED material 112B, and third OLED material 112C, is disposed on the metal layer 104 and over a portion of the PDL structures 126. A first cathode 114A, a second cathode 114B, and a third cathode 114C is disposed over the first OLED material 112A, second OLED material 112B, and third OLED material 112C, respectively, of the PDL structures 126 in each sub-pixel 106. The first cathode 114A, the second cathode 114B, and the third cathode 114C may be disposed on a portion of a sidewall 111 of the lower portion 110A. The first cathode 114A, the second cathode 114B, and the third cathode 114C includes a conductive material, such as a metal, e.g., chromium, titanium, aluminum, ITO, or a combination thereof. In other embodiments, which can be combined with other embodiments described herein, the first OLED material 112A, second OLED material 112B, and third OLED material 112C and the first cathode 114A, the second cathode 114B, and the third cathode 114C are disposed over a top surface 115 of the upper portion 110B of the inorganic overhang structures 110, respectively.

Each sub-pixel 106 includes include an encapsulation layer 116. The encapsulation layer 116 may be or may correspond to a local passivation layer. The encapsulation layer 116 of a respective sub-pixel, e.g., first encapsulation layer 116A, second encapsulation layer 116B, and third encapsulation layer 116C, is disposed over the first cathode 114A, the second cathode 114B, and the third cathode 114C, respectively, with the encapsulation layer 116 extending under at least a portion of each of the inorganic overhang structures 110 and along a sidewall of each of the inorganic overhang structures 110. The encapsulation layer 116 is disposed over the cathode and over at least the sidewall 111 of the lower portion 110A. In some embodiments, which can be combined with other embodiments described herein, the encapsulation layer 116 is disposed over the sidewall 113 of the upper portion 110B. In some embodiments, which can be combined with other embodiments described herein, the encapsulation layer 116 is disposed over the top surface 115 of the upper portion 110B of the inorganic overhang structures 110. The encapsulation layer 116 can include a non-conductive inorganic material, such as the silicon-containing material. The silicon-containing material may include Si₃N₄ containing materials.

A global passivation layer 502 can be disposed over the encapsulation layer 116 and the upper portion 110B. The global passivation layer 502 can include a thickness of about 1 nm to about 3 μm, e.g., about 1 nm to about 1.8 μm, about 120 nm to about 1.5 μm, or about 500 nm to about 1 μm. In some embodiments, the global passivation layer 502 can include one or more non-conductive inorganic materials, such as the silicon-containing material. The silicon-containing material may include Si₃N₄ containing materials. Without being bound by theory, the global passivation layer 502 can have a uniform thickness across the encapsulation layer 116 and the upper portion 110B.

An intermediate layer 118 may be deposited over the global passivation layer 502, as shown in FIG. 5A. The intermediate layer 118 can include a monomer and/or a polymer, e.g., an inorganic polymer or an organic polymer. In some embodiments, the intermediate layer 118 can include a thickness of about 1 μm to about 10 μm, e.g., about 1 μm to about 5 μm, about 2 μm to about 8 μm, or about 4 μm to about 6 μm. Optionally, a second encapsulation layer 120 may be deposited over the intermediate layer 118. The second encapsulation layer 120 can include any of the encapsulation layer 116. The second encapsulation layer 120 can include a thickness of about 1 μm to about 10 μm, e.g., about 1 μm to about 5 μm, about 2 μm to about 8 μm, or about 4 μm to about 6 μm.

A plurality of mask structures 122 may be disposed over the second encapsulation layer 120. The plurality of mask structures 122 can be a material suitable to absorb external and/or internal light, e.g., a black material such as a black absorbing material. The plurality of mask structures 122 are disposed according to the first sub-pixel 108A, a second sub-pixel 108B, and a third sub-pixel 108C. For example, the plurality of mask structures 122 are disposed to such that the plurality of mask structures are aligned with the PDL structures 126 and/or the inorganic overhang structures 110, thereby allowing light emission from the OLED materials through an opening between the plurality of mask structures 122.

A color filter is disposed in the opening between the plurality of mask structures 122. A first color filter 124A may be aligned with the first sub-pixel 108A, a second color filter 124B may be aligned with the second sub-pixel 108B, and a third color filter 124C may be aligned with the third sub-pixel 108C. Each of the first color filter 124A, the second color filter 124B, or the third color filter 124C may be configured to restrict light transparency from a bottom surface of the color filter to a top surface of the color filter to a specific color and/or wavelength, e.g., red, green, and/or blue. For example, the first color filter 124A may receive a yellow, white, and/or red light and restrict light transparency to the color red, thereby only emitting red emission from the first sub-pixel 108A. As a further example, the second color filter 124B may receive a yellow, white, and/or red light and may restrict light transparency to the color green, thereby only emitting green emission from the second sub-pixel 108B. As a further example, the third color filter 124C may receive a blue, white, and/or yellow light and may restrict light transparency to the color blue, thereby only emitting blue emission from the third sub-pixel 108C.

Optionally, the plurality of mask structures 122 and the color filters, e.g., the first color filter 124A, the second color filter 124B, or the third color filter 124C may be disposed on a backing material 130, as shown in FIG. 5B. The backing material 130 can include a transparent material suitable for supporting the plurality of mask structures 122 and the color filters, e.g., the first color filter 124A, the second color filter 124B, or the third color filter 124C. The plurality of mask structures 122 and the color filters, e.g., the first color filter 124A, the second color filter 124B, or the third color filter 124C may be disposed on the backing material 130, inverted, and placed on the intermediate layer 118, as shown in FIG. 5B, thereby allowing for manufacturing of the color filters to occur in parallel with the manufacturing of the sub-pixels, and reducing the time for manufacturing.

Optionally, the plurality of mask structures 122 may be deposited over the second encapsulation layer 120, where no intermediate layer 118 separates the global passivation layer 502 and the second encapsulation layer 120, as shown in FIG. 5C. The color filters, e.g., the first color filter 124A, the second color filter 124B, or the third color filter 124C, are disposed over the second encapsulation layer 120, and between the plurality of mask structures 122. Without being bound by theory, by disposing the color filters over the second encapsulation layer 120, a reduction of manufacturing costs may occur.

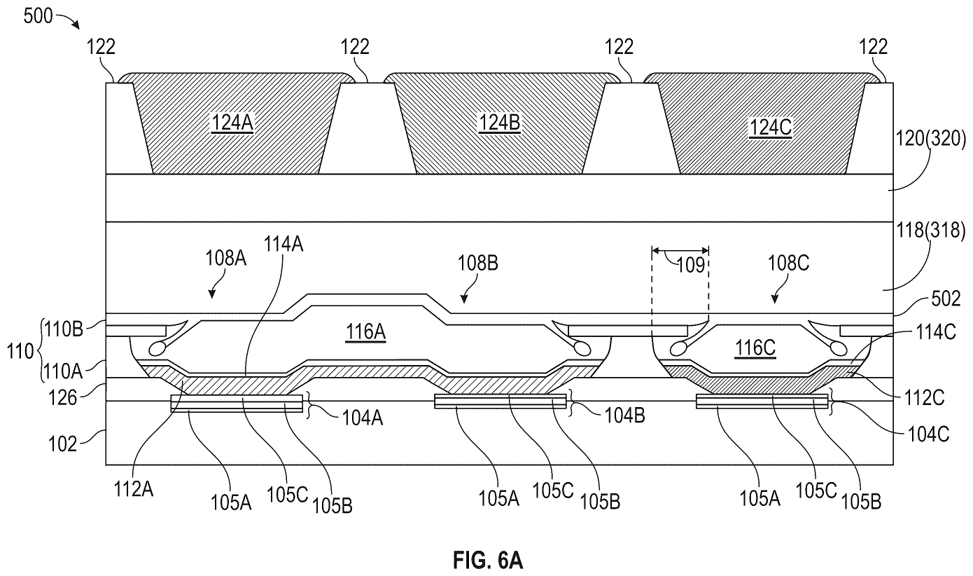

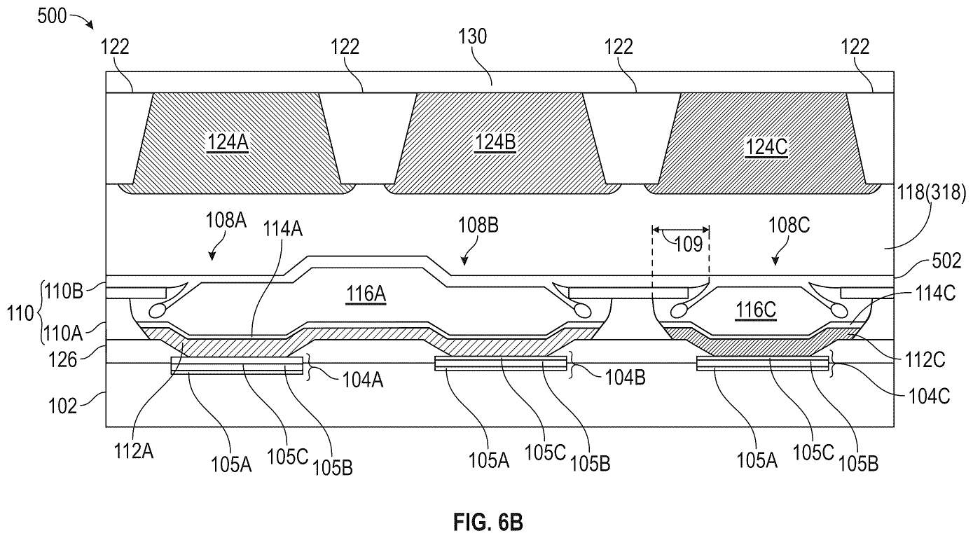

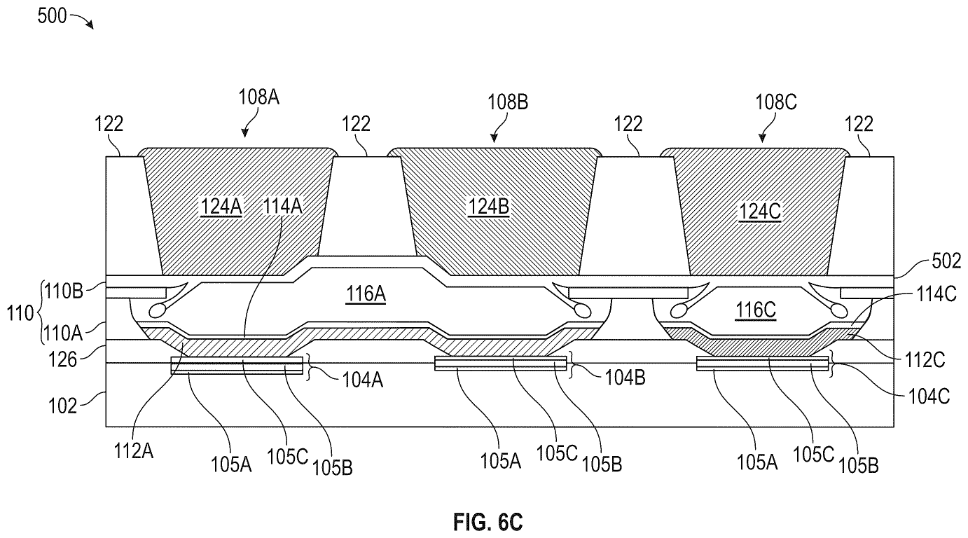

FIG. 6A is a schematic, cross-sectional view of a sub-pixel circuit 500 having a global passivation layer 502, in which the sub-pixel circuit 500 has the first OLED material 112A and the first cathode 114A shared across the first sub-pixel 108A and the second sub-pixel 108B. The first OLED material 112A can include a yellow and/or white emitting OLED material, as described herein. The first OLED material 112A and the first cathode 114A may be shared due to a removal of an inorganic overhangs structure 110 between the first sub-pixel 108A and the second sub-pixel 108B.

The third sub-layer 105C of the first sub-pixel 108A is thicker than a third sub-layer 105C of the second sub-pixel 108B. Without being bound by theory, by having the third sub-layer 105C of the first sub-pixel 108A be thicker than the third sub-layer 105C of the second sub-pixel 108B, the light emitted from the first OLED material 112A over the first sub-pixel 108A may be red-shifted compared to the light emission from the second OLED material 112B of the second sub-pixel 108B. Additionally, and without being bound by theory, a reduction of manufacturing costs occurs due to the reduced materials required to produce the sub-pixel circuit 100, e.g., reduction of overhang structures, and reduction of individualized OLED materials.

Optionally, the plurality of mask structures 122 and the color filters, e.g., the first color filter 124A, the second color filter 124B, or the third color filter 124C may be disposed on a backing material 130, as shown in FIG. 6B. The backing material 130 can include a transparent material suitable for supporting the plurality of mask structures 122 and the color filters, e.g., the first color filter 124A, the second color filter 124B, or the third color filter 124C. The plurality of mask structures 122 and the color filters, e.g., the first color filter 124A, the second color filter 124B, or the third color filter 124C may be disposed on the backing material 130, inverted, and placed on the intermediate layer 118, as shown in FIG. 6B, thereby allowing for manufacturing of the color filters to occur in parallel with the manufacturing of the sub-pixels, and reducing the time for manufacturing.

Optionally, the plurality of mask structures 122 may be patterned over the global passivation layer 502, as shown in FIG. 6C. The plurality of mask structures 122 may be patterned such that the plurality of mask structures directly contacts the global passivation layer 502. The color filters, e.g., the first color filter 124A, the second color filter 124B, or the third color filter 124C, are disposed over the global passivation layer 502, and between the plurality of mask structures 122. Without being bound by theory, by disposing the color filters over the global passivation layer 502, a reduction of manufacturing costs may occur.

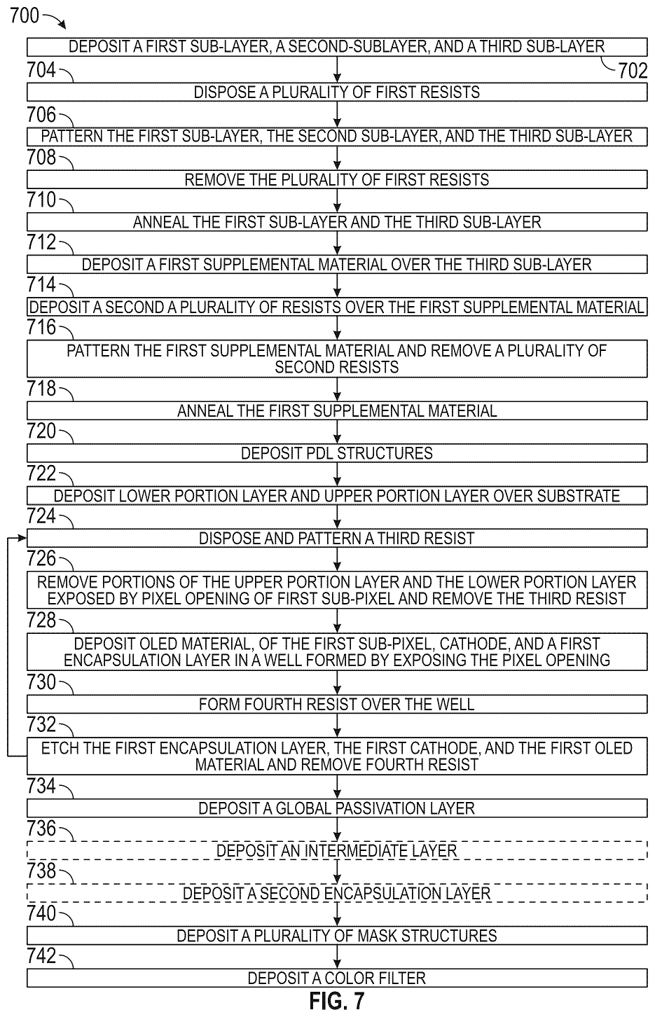

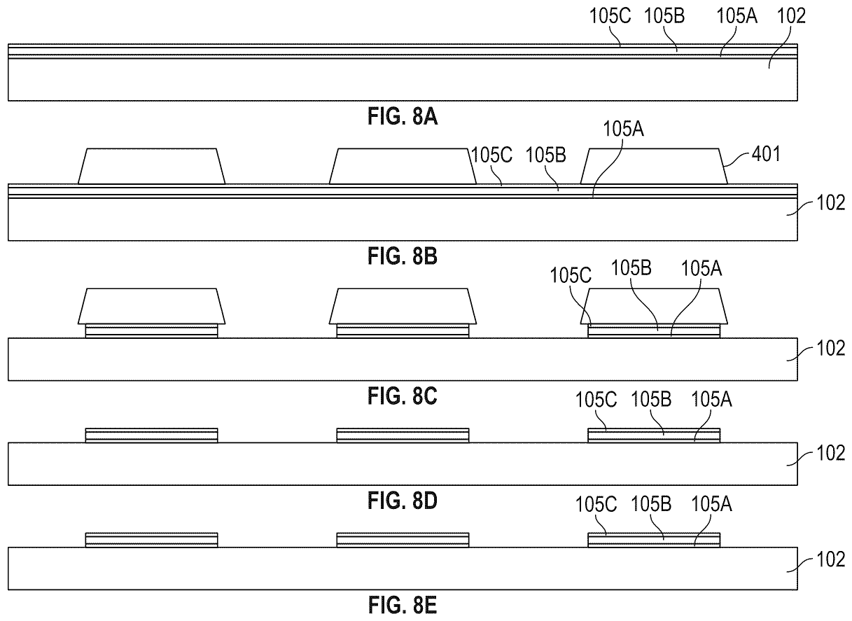

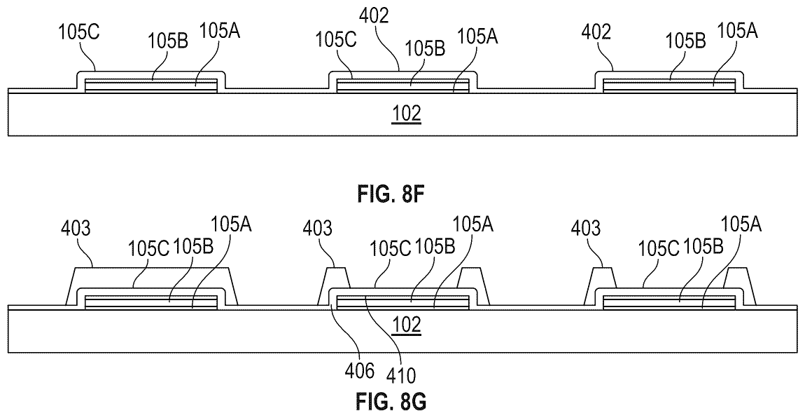

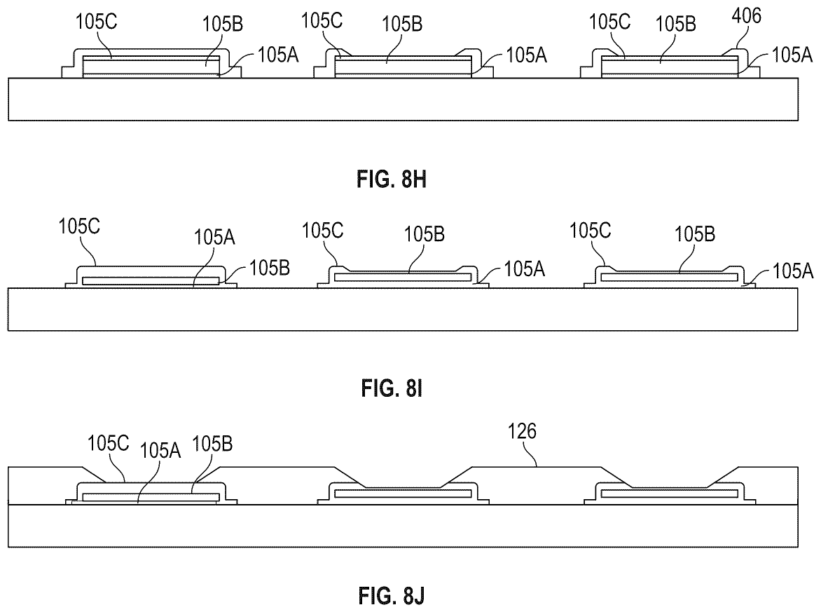

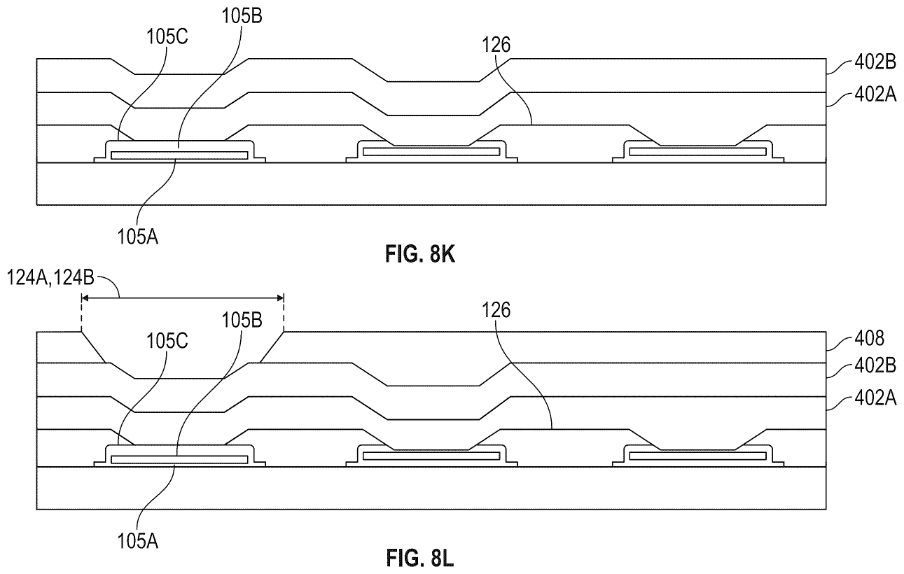

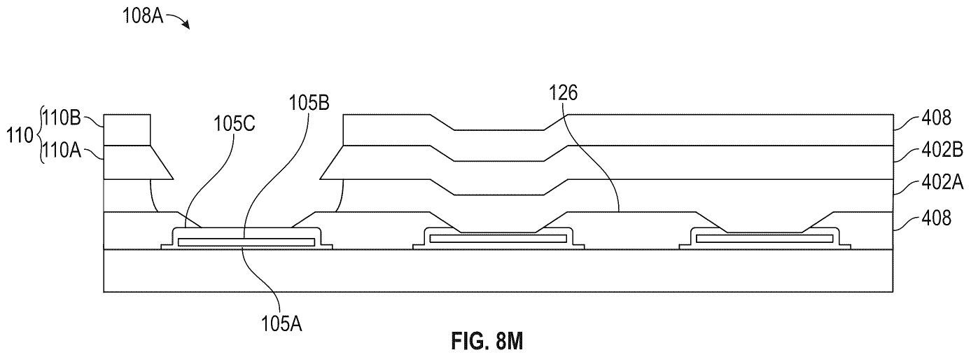

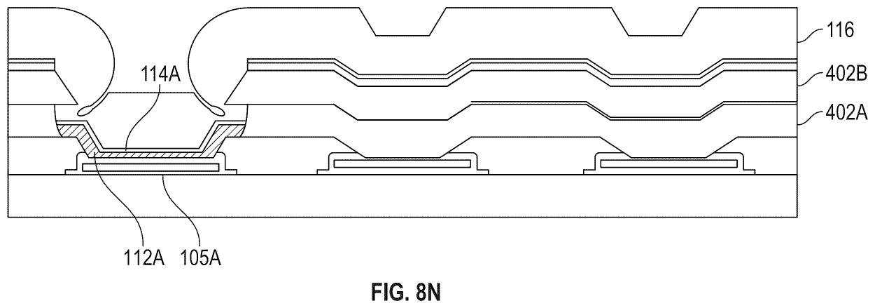

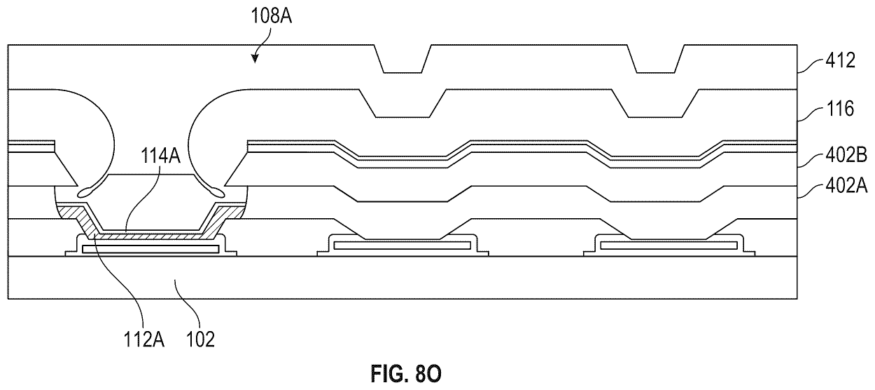

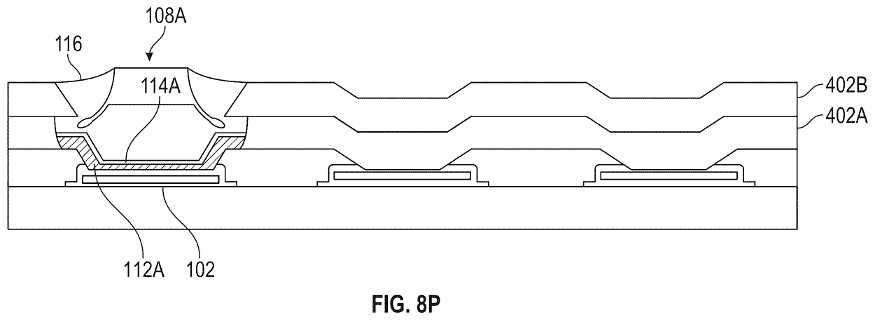

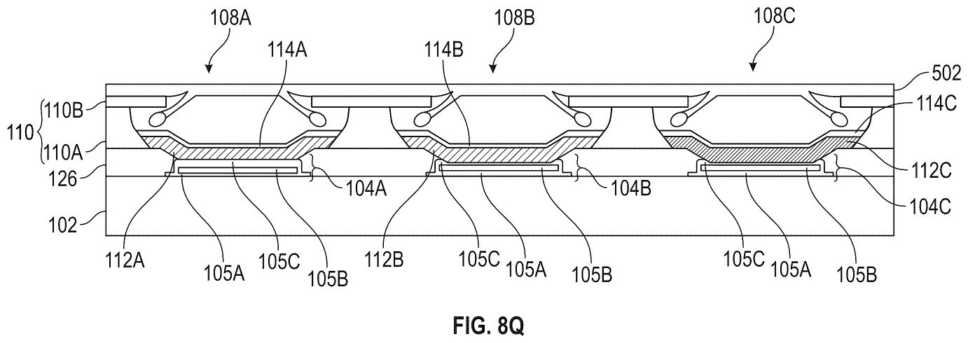

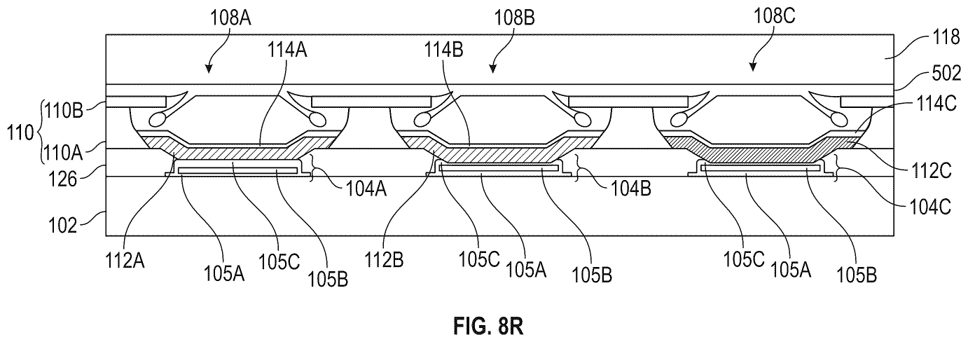

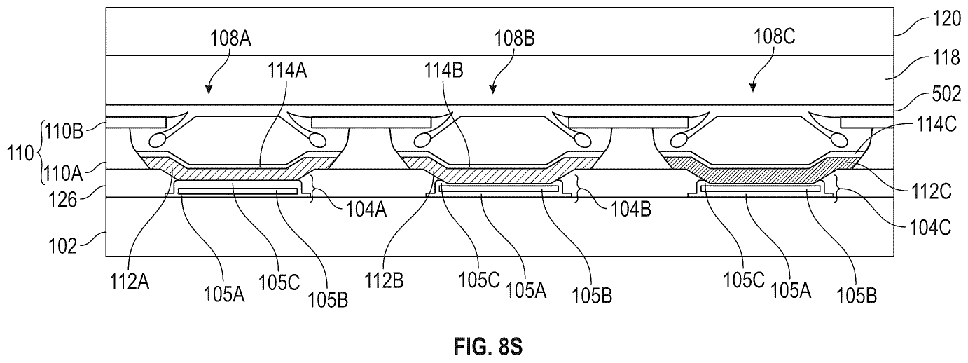

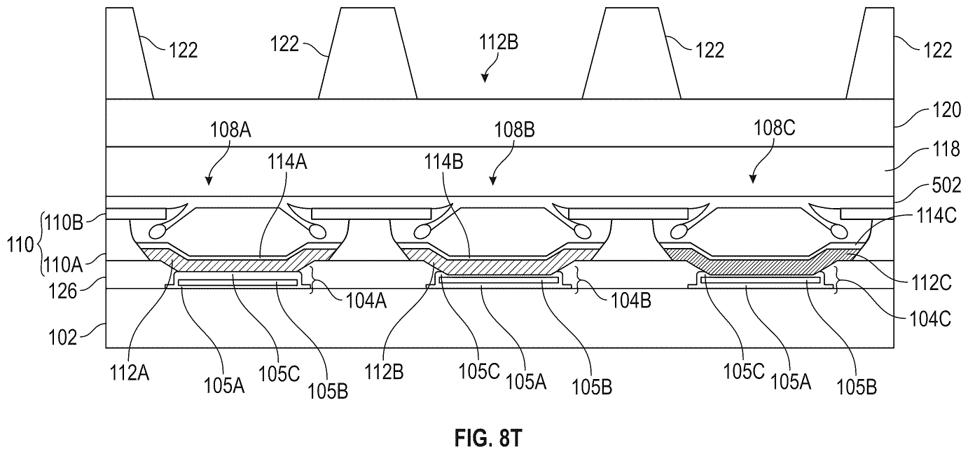

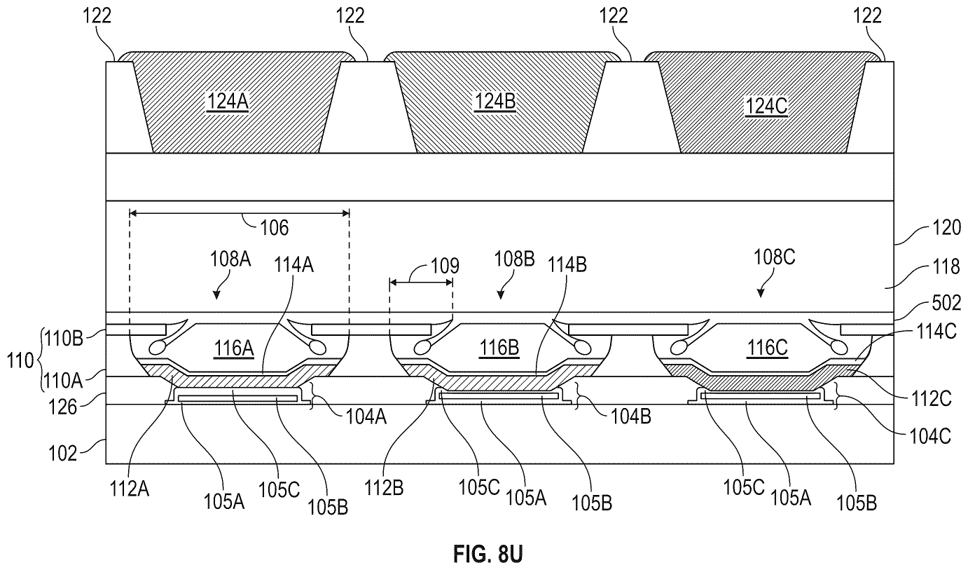

FIG. 7 is a flow a flow diagram of a method 700 for forming a sub-pixel circuit 500. FIGS. 8A-8U are schematic, cross-sectional views of a substrate 102 during the method 700 for forming the sub-pixel circuit 500 according embodiments described herein.

At operation 702, as shown in FIG. 8A, a first sub-layer 105A, a second sub-layer 105B, and a third sub-layer 105C is deposited on a substrate 102. The first sub-layer 105A, and the third sub-layer 105C include an amorphous transparent conductive oxide, e.g., amorphous indium tin oxide. The second sub-layer 105B includes a metal layer such as a silver layer. At operation 704, as shown in FIG. 8B, a plurality of first resists 401 are disposed the third sub-layer 105C. The plurality of first resists are deposited over the third sub-layer 105C such that each of a first metal layer 104A, a second metal layer 104B, and a third metal layer 104C is covered by each first resist of the plurality of first resists 401. At operation 706, as shown in FIG. 8C, the first sub-layer 105A, the second sub-layer 105B, and the third sub-layer 105C is patterned to form the first metal layer 104A, the second metal layer 104B, and the third metal layer 104C. The patterning is one of a photolithography, digital lithography process, or laser ablation process.

At operation 708, as shown in FIG. 8D, plurality of first resists 401 are removed to expose the first metal layer 104A, the second metal layer 104B, and the third metal layer 104C. At operation 710, as shown in FIG. 8E, the first sub-layer 105A and the third sub-layer 105C are annealed according to an annealing process. The first sub-layer 105A and the third sub-layer 105C are annealed to produce a poly-crystallized transparent conductive oxide from the amorphous transparent conductive oxide. For example, the first sub-layer 105A and the third sub-layer 105C may be annealed to form a poly-crystallized indium tin oxide.

At operation 712, as shown in FIG. 8F, a first supplemental material 402 is deposited over the third sub-layer 105C. It is contemplated that operation 712 is optional while performing the method 700. The first supplemental material 402 includes an amorphous transparent conductive oxide, e.g., amorphous indium tin oxide. The first supplemental material 402 can be deposited to provide a thickness of about 50 nm to about 100 nm. The first supplemental material 402 can include a first oxide layer disposed over the third sub-layer 105C and/or the substrate 102 and a second oxide layer disposed over the first oxide layer. The second oxide layer can include a first amorphous transparent conductive oxide such as amorphous indium zinc oxide. The second oxide layer can include a second amorphous transparent conductive oxide such as amorphous indium tin oxide.

The first oxide layer can include a thickness of about 45 nm to about 160 nm. The second oxide layer can include a thickness of about less than 40 nm, e.g., about 5 nm to about 40 nm. Without being bound by theory, by reducing the thickness of the second oxide layer to be less than 40 nm, a reduction of partial crystallization of the second oxide layer may occur, thereby improving an etch selectivity and/or efficiency during subsequent processing steps. For example, a thickness of about 40 nm or less of indium tin oxide may have greater etch selectivity and/or efficiency compared to a thickness of about 50 nm or greater of indium tin oxide. Additionally, and without being bound by theory, a first supplemental material 402 including a first oxide layer comprising indium zinc oxide having a thickness of about 45 nm to about 160 nm, and a second oxide layer comprising indium tin oxide having a thickness of less than 40 nm may provide enhanced etch selectivity and/or efficiency during subsequent processing steps, e.g., etching such as etching with oxalic acid.

At operation 714, as shown in FIG. 8G, a plurality of second resists 403 is deposited over the first supplemental material 402. It is contemplated that operation 714 is optional while performing the method 700. The plurality of second resists 403 is deposited over the first supplemental material 402 such that a first metal layer 104A is covered by the plurality of second resists 403. Optionally, the plurality of second resists 403 may be deposited over a lateral edge 406 of a second metal layer 104B and a third metal layer 104C, thereby exposing a top central surface 410 of the second metal layer 104B and the third metal layer 104C. Without being bound by theory, the plurality of second resists 403 may be deposited over the lateral edge of the second metal layer 104B and the third metal layer 104C such that the third sub-layer 105C does not get etched over the lateral edge, thereby providing enhanced protection of the edge of the second sub-layer 105B.

The plurality of second resists 403 is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the plurality of second resists 403 determines whether the resist is a positive resist or a negative resist.

At operation 716, as shown in FIG. 8H, the first supplemental material 402 is patterned and the plurality of second resists 403 are removed. It is contemplated that operation 716 is optional while performing the method 700. The patterning is one of a photolithography, digital lithography process, or laser ablation process. At operation 718, as shown in FIG. 8I, the second oxide layer of the first supplemental material 402 is annealed. It is contemplated that operation 718 is optional while performing the method 700. The first oxide layer remains an amorphous transparent conductive oxide, e.g., amorphous indium zinc oxide. The second oxide layer of the first supplemental material 402 is annealed to produce a poly-crystallized transparent conductive oxide from the amorphous transparent conductive oxide. For example, the second oxide layer of the first supplemental material 402 may be annealed to form a poly-crystallized indium tin oxide. In some embodiments, which may be combined with other embodiments, by annealing the second oxide layer of the first supplemental material 402 to produce a poly-crystallized transparent conductive oxide, the second oxide layer of the first supplemental material 402 may be similar to the third sub-layer 105C. For example, the second oxide layer of the first supplemental material 402, when annealed, may become the third sub-layer 105C. At operation 720, as shown in FIG. 8J, PDL structures 126 are deposited over the substrate 102 such that only the metal layers 104 remain exposed. In one or more embodiments, operations 712 to 718 are omitted from the method 700. In one or more embodiments, operation 720 is performed subsequent to operation 710. In one or more embodiments, the first metal layer 104A, the second metal layer 104B, and the third metal layer 104C have the same thickness as one another.

At operation 722, as shown in FIG. 8K, a lower portion layer 402A and an upper portion layer 402B are deposited over the substrate 102. The lower portion layer 402A is disposed over the PDL structures 126 and the metal layers 104, e.g., the first metal layer 104A, the second metal layer 104B, and the third metal layer 104C. The upper portion layer 402B is disposed over the lower portion layer 402A. In various embodiments, the lower portion layer 402A corresponds to the lower portion 110A and the upper portion layer 402B corresponds to the upper portion 110B of the inorganic overhang structures 110. In some embodiments, an assistant cathode layer is disposed between the lower portion layer 402A and the PDL structures 126 and the metal layers 104.

At operation 724, as shown in FIG. 8L, a third resist 408 is disposed and patterned. The third resist 408 is disposed over the upper portion layer 402B. The third resist 408 is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the third resist 408 determines whether the resist is a positive resist or a negative resist. The third resist 408 is patterned to form one of a pixel opening of a first sub-pixel 108a. The patterning is one of a photolithography, digital lithography process, or laser ablation process.

At operation 726, as shown in FIG. 8M, portions of the upper portion layer 402B and the lower portion layer 402A exposed by the pixel opening are removed and the third resist 408 is removed. The upper portion layer 402B exposed by the pixel opening may be removed by a dry etch process. The lower portion layer 402A exposed by the pixel opening may be removed by a wet etch process. In embodiments including the assistant cathode layer, a portion of the assistant cathode layer may be removed by a dry etch process or a wet etch process to form an assistant cathode (not shown) disposed under the lower portion 110A. Operation 726 forms the inorganic overhang structures 110 of the first sub-pixel 108a. The etch selectivity of the materials of the upper portion layer 402B (corresponding to the upper portion 110B) and the lower portion layer 402A (corresponding to the lower portion 110A) coupled with the etch processes can remove the exposed portions of the upper portion layer 402B and the lower portion layer 402A. This can provide for the bottom surface 107 of the upper portion 110B being wider than the top surface 105 of the lower portion 110A, thereby forming the overhang 109 (as shown in FIGS. 5A-5C).

At operation 728, as shown in FIG. 8N, the first OLED material 112A of the first sub-pixel 108a, the first cathode 114A, and the first encapsulation layer 116A are deposited. In some embodiments, the first OLED material 112A does not contact the lower portion 110A and the first cathode 114A directly contacts the lower portion 110A of the inorganic overhang structures 110. The first encapsulation layer 116A is deposited over the first cathode 114A. In embodiments including capping layers (not shown), the capping layers are deposited between the first cathode 114A and the first encapsulation layer 116A. The capping layers may be deposited by evaporation deposition.

At operation 730, as shown in FIG. 8O, a fourth resist 412 is formed in a well of the first sub-pixel 108a and over the first encapsulation layer 116A disposed on the upper portion layer 402B. The fourth resist 412 can be formed in the well, in which the fourth resist 412 can fill the sub-pixel the well and one or more cavities within the encapsulation layer 116, which are formed due to the overhang 109. The fourth resist 412 can include a fourth resist thickness of about 0.1 μm to about 10 μm, e.g., about 0.1 μm to about 8 μm, about 0.5 μm to about 5 μm, or about 0.9 μm to about 1.1 μm, over the upper portion 110B. At operation 732, as shown in FIG. 8P, the first encapsulation layer 116A, the first cathode 114A, and the first OLED material 112A are removed, and the fourth resist 412 is removed. For example, the portion of the fourth resist 412 that is removed can include the portion of the fourth resist 412 that is disposed over the upper portion layer 402B. The fourth resist 412 may be removed by a plasma ashing process.

Operations 724-732 are repeated to produce the second sub-pixel 108B and the third sub-pixel 108C. In some embodiments, which can be combined with other embodiments, operations 724-732 can be iteratively repeated to provide for the formation of a plurality of sub-pixels. Each sub-pixel of the plurality of sub-pixels can include an OLED for a specific color, e.g., white, green, red, blue, or a combination thereof.

At operation 734, as shown in FIG. 8Q, a global passivation layer 502 is be deposited over the encapsulation layer 116 and the upper portion layer 402B. The global passivation layer 502 can include any of the global passivation layer as described in the present disclosure. The global passivation layer 502 can include a thickness of about 1 nm to about 3 μm, e.g., about 1 nm to about 1.8 μm, about 120 nm to about 1.5 μm, or about 500 nm to about 1 μm. In some embodiments, the global passivation layer 502 can include one or more non-conductive inorganic materials, such as the silicon-containing material. The silicon-containing material may include Si₃N₄ containing materials. Without being bound by theory, the global passivation layer 502 can have a uniform thickness across the upper portion layer 402B.

Optionally, at operation 736, as shown in FIG. 8R, an intermediate layer 118 may be deposited over the global passivation layer 502. The intermediate layer 118 can include a monomer and/or a polymer, e.g., an inorganic polymer or an organic polymer. In some embodiments, the intermediate layer 118 can include a thickness of about 1 μm to about 10 μm, e.g., about 1 μm to about 5 μm, about 2 μm to about 8 μm, or about 4 μm to about 6 μm. Optionally, at operation 738, as shown in FIG. 8S, a second encapsulation layer 120 is deposited over the intermediate layer 118. The second encapsulation layer 120 can include any of the encapsulation layer 116. The second encapsulation layer 120 can have a thickness of about 1 μm to about 10 μm, e.g., about 1 μm to about 5 μm, about 2 μm to about 8 μm, or about 4 μm to about 6 μm.

At operation 740, as shown in FIG. 8T, a plurality of mask structures 122 are disposed over the global passivation layer 502, the intermediate layer 118, and/or the second encapsulation layer 120. The plurality of mask structures 122 may be disposed according to the first sub-pixel 108A, a second sub-pixel 108B, and a third sub-pixel 108C. For example, the plurality of mask structures 122 may be disposed such that the mask structures align with the PDL structures 126 and/or the inorganic overhang structures 110, thereby allowing light emission emitted from the OLED materials through an opening between the plurality of mask structures 122.

At operation 742, as shown in FIG. 8U, a color filter 124 is disposed in the opening between the plurality of mask structures 122. A first color filter 124A may be aligned with the first sub-pixel 108A, a second color filter 124B may be aligned with the second sub-pixel 108B, and a third color filter 124C may be aligned with the third sub-pixel 108C. Each of the first color filter 124A, the second color filter 124B, or the third color filter 124C may be configured to restrict light transparency from a bottom surface of the color filter to a top surface of the color filter to a specific color and/or wavelength, e.g., red, green, and/or blue. For example, the first color filter 124A may receive a yellow, white, and/or red light and restrict light transparency to the color red, thereby only emitting red emission from the first sub-pixel 108A. As a further example, the second color filter 124B may receive a yellow, white, and/or red light and may restrict light transparency to the color green, thereby only emitting green emission from the second sub-pixel 108B. As a further example, the third color filter 124C may receive a blue, white, and/or yellow light and may restrict light transparency to the color blue, thereby only emitting blue emission from the third sub-pixel 108C.

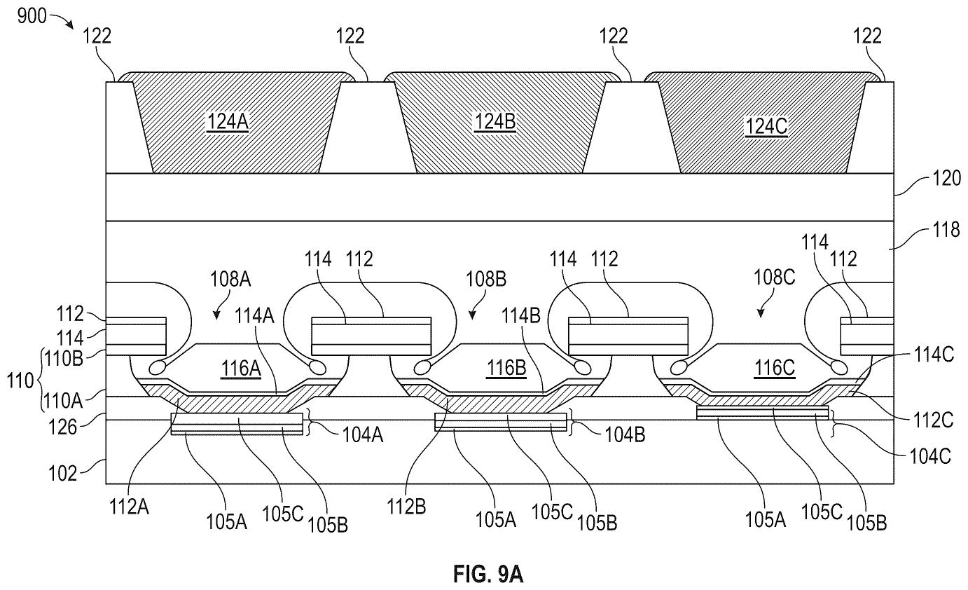

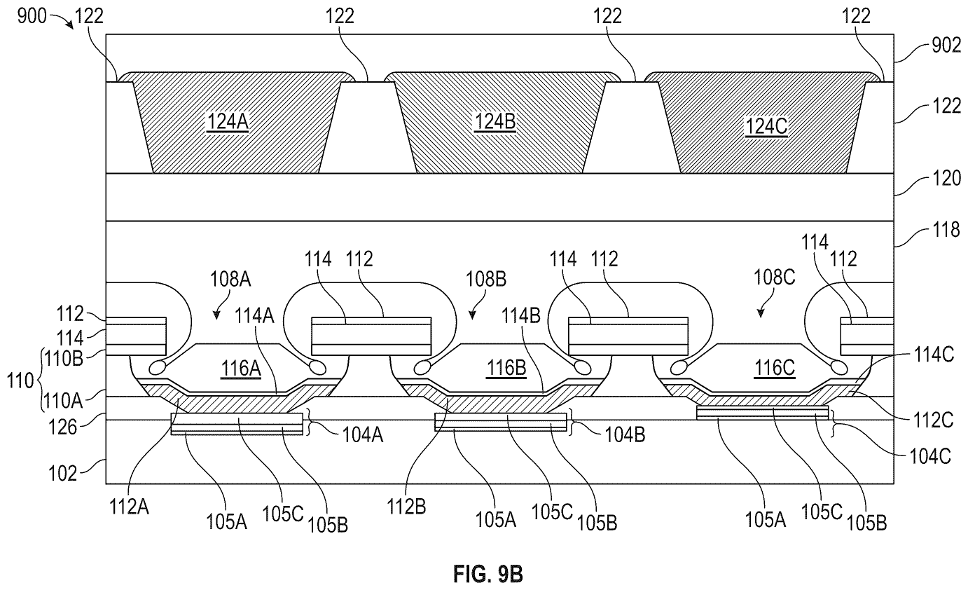

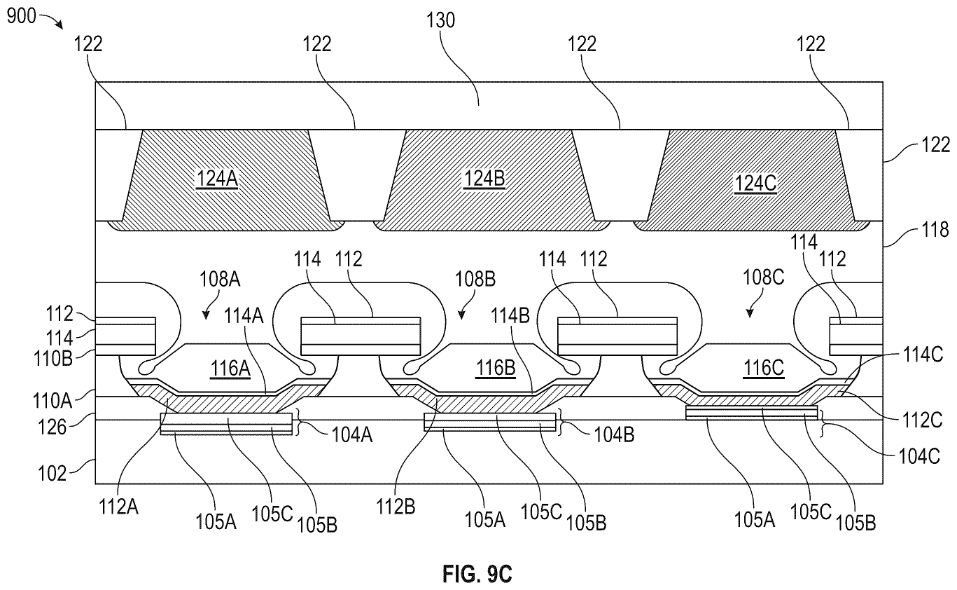

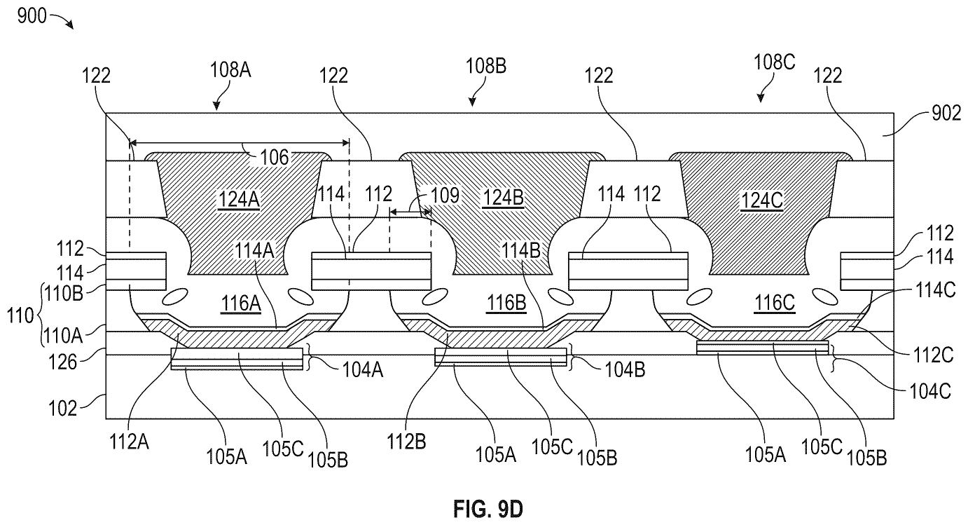

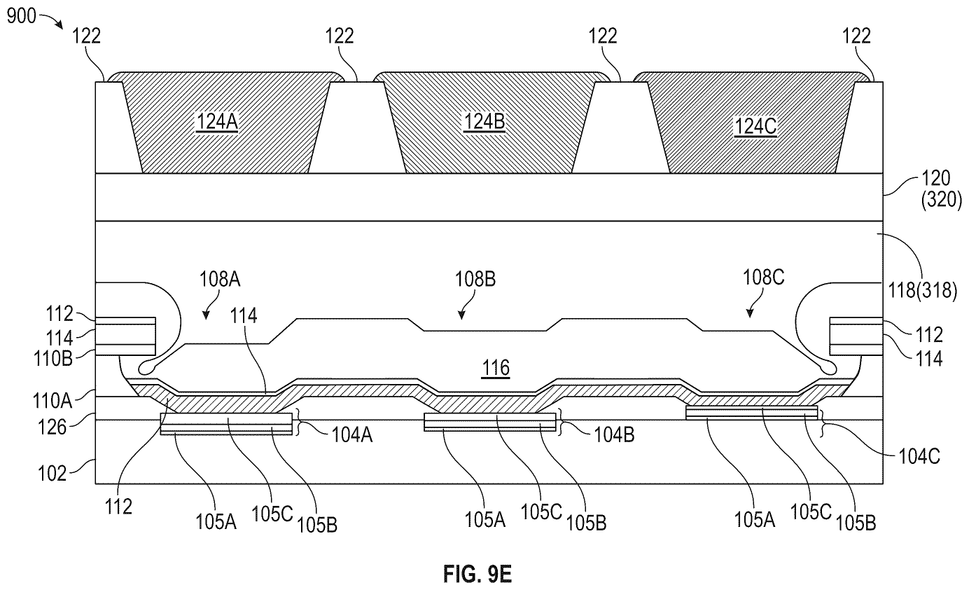

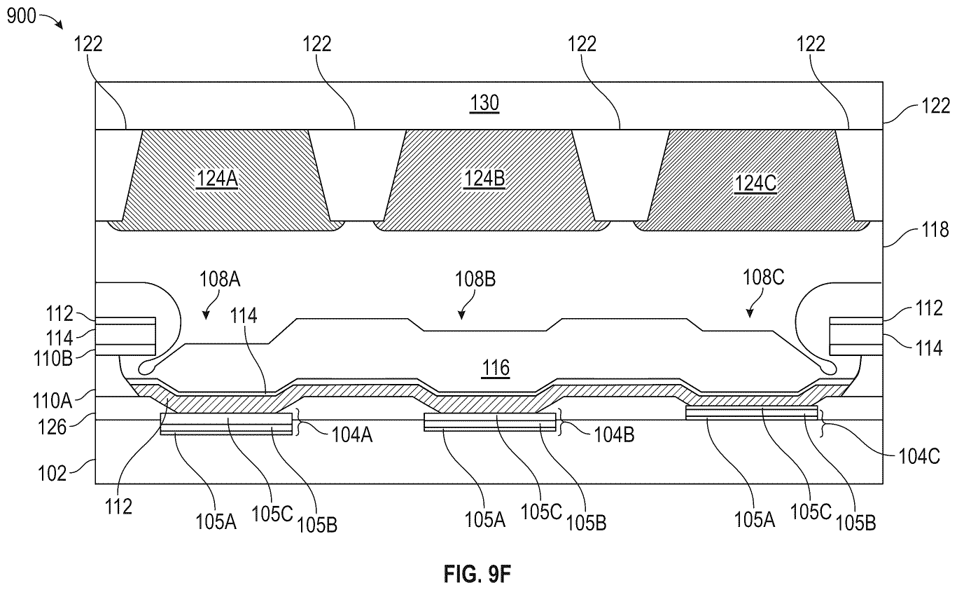

FIG. 9A is a schematic, cross-sectional view of a sub-pixel circuit 900. The sub-pixel circuit 900 includes a substrate 102. Metal layers 104 are be patterned on the substrate 102. The metal layers 104 are configured to operate anodes of respective sub-pixels. The metal layers 104 are a layer stack of a first sub-layer 105A, a second sub-layer 105B disposed over the first sub-layer 105A, and a third sub-layer 105C disposed over the second sub-layer 105B. The first sub-layer 105A includes a transparent conductive oxide (TCO) layer, e.g., indium tin oxide or indium zinc oxide. The first sub-layer 105A can include a thickness of about 1 nm to about 50 nm.

The second sub-layer 105B includes a metal layer, e.g., chromium, titanium, gold, silver, copper, aluminum, or a combination thereof, disposed on the first sub-layer 105A. The second sub-layer 105B can include a thickness of about 50 nm to about 200 nm.

The third sub-layer 105C includes a transparent conductive oxide (TCO) layer, e.g., indium tin oxide or indium zinc oxide. The third sub-layer 105C can include a thickness of about 1 nm to about 200 nm. Optionally, the third sub-layer 105C has a thickness that is greater than the thickness of the first sub-layer 105A and/or the second sub-layer 105B. Optionally, the second sub-layer 105B has a thickness that is greater than the thickness of the first sub-layer 105A. Without being bound by theory, a thicker third sub-layer 105C can allow for controllable wavelength emission of the OLED material, thereby reducing power requirements during operation of the sub-pixel circuit 900.

Optionally, the third sub-layer 105C of a first sub-pixel 108A is thicker than a third sub-layer 105C of a second sub-pixel 108B and/or a third sub-pixel 108C. Optionally, the third sub-layer 105C of a second sub-pixel 108B is thicker than a third sub-layer 105C of a third sub-pixel 108C. Without being bound by theory, by having the third sub-layer 105C of a first sub-pixel 108A be thicker than the third sub-layer 105C of the second sub-pixel 108B and/or the third sub-pixel 108C, and the third sub-layer 105C of the second sub-pixel 108B be thicker than the third sub-layer 105C of the third sub-pixel 108C, the light emitted from the first OLED material 112A may be red-shifted and/or green-shifted, thereby causing emission of a white emitting OLED material to be more red or green, without the need for a red, yellow, or green OLED emitting material.

In one embodiment, which can be combined with other embodiments described herein, the metal layers 104 are pre-patterned on the substrate 102, e.g., the substrate 102 is a pre-patterned indium tin oxide (ITO) glass substrate. In one embodiment, which can be combined with other embodiments described herein, the metal layers 104 are pre-patterned on the substrate 102, e.g., the metal layers 104 include a first sub-layer 105A of indium tin oxide, a second sub-layer 105B of silver, and a third sub-layer 105C of indium tin oxide.

The pixels are defined by adjacent pixel-defining layer (PDL) structures disposed on the substrate 102. The PDL structures 126 can be disposed on the substrate 102. The PDL structures 126 include one of an organic material, an organic material with an inorganic coating disposed thereover, or an inorganic material. The organic material of the PDL structures 126 includes, but is not limited to, polyimides. The inorganic material of the PDL structures 126 includes, but is not limited to, silicon oxide (SiO₂), silicon nitride (Si₃N₄), silicon oxynitride (Si₂N₂O), magnesium fluoride (MgF₂), or combinations thereof. Adjacent PDL structures define a respective sub-pixel and expose the anode (i.e., metal layer 104) of the respective sub-pixel of the sub-pixel circuit 900.

The sub-pixel circuit 900 has a plurality of sub-pixels 106 including at least a first sub-pixel 108A, a second sub-pixel 108B, and a third sub-pixel 108C. While the Figures depict the first sub-pixel 108A, the second sub-pixel 108B, and the third sub-pixel 108C, the sub-pixel circuit 100 of the embodiments described herein may include three or more sub-pixels 106, such as a fourth and a fifth sub-pixel. Each sub-pixel 106 has an OLED material, e.g., first OLED material 112A, second OLED material 112B, and third OLED material 112C, configured to emit a white, red, green, blue or other color light when energized, e.g., the first OLED material 112A of the first sub-pixel 108A emits a yellow light when energized, the second OLED material 112B of the second sub-pixel 108B emits a yellow light when energized, the third OLED material 112C of the third sub-pixel 108C emits a blue light when energized, and the OLED material of a fourth sub-pixel emits a different color light when energized.

Inorganic overhang structures 110 are disposed over the substrate 102, thereby defining each sub-pixel of the plurality of sub-pixels. In some embodiments, as shown in FIG. 9A, the inorganic overhang structures 110 are disposed over each of the PDL structures 126. The inorganic overhang structures 110 are permanent to the sub-pixel circuit. The inorganic overhang structures 110 further define each sub-pixel 106 of the sub-pixel circuit 900. The inorganic overhang structures 110 include at least an upper portion 110B disposed on a lower portion 110A. A first configuration of the inorganic overhang structures 110 includes the upper portion 110B of a non-conductive inorganic material and the lower portion 110A of a conductive inorganic material. A second configuration of the inorganic overhang structures 110 includes the upper portion 110B of a conductive inorganic material and the lower portion 110A of a conductive inorganic material. A third configuration of the inorganic overhang structures 110 includes the upper portion 110B of a non-conductive inorganic material, the lower portion 110A of a non-conductive inorganic material, and an optional assistant cathode (not shown) disposed under the lower portion 110A. A fourth configuration of the inorganic overhang structures 110 includes the upper portion 110B of a conductive inorganic material, the lower portion 110A of a non-conductive inorganic material, and an optional assistant cathode (not shown) disposed under the lower portion 110A. The first, second, third, and fourth embodiments of the sub-pixel circuit 900 include inorganic overhang structures 110 of at least one of the first, second, third, or fourth configurations. The inorganic overhang structures 110 are able to remain in place, e.g., are permanent.

The non-conductive inorganic material includes, but is not limited to, an inorganic silicon-containing material, e.g., the silicon-containing material includes oxides or nitrides of silicon, or combinations thereof. The conductive inorganic material includes, but is not limited to, a metal-containing material, e.g., the metal-containing material includes copper, titanium, aluminum, molybdenum, silver, indium tin oxide, indium zinc oxide, or combinations thereof.

At least a bottom surface 107 of the upper portion 110B is wider than a top surface 105 of the lower portion 110A to form an overhang 109. The bottom surface 107 larger than the top surface 105 forming the overhang 109 allows for the upper portion 110B to shadow the lower portion 110A. The shadowing of the overhang 109 provides for evaporation deposition each of the OLED material 112 and a cathode 114.

The OLED material, e.g., e.g., first OLED material 112A, second OLED material 112B, and third OLED material 112C, may include one or more of a HIL, a HTL, an EML, and an ETL. The OLED material, e.g., first OLED material 112A, second OLED material 112B, and third OLED material 112C, is disposed on the metal layer 104. In some embodiments, which can be combined with other embodiments described herein, the OLED material, e.g., first OLED material 112A, second OLED material 112B, and third OLED material 112C, is disposed on the metal layer 104 and over a portion of the PDL structures 126. A first cathode 114A, a second cathode 114B, and a third cathode 114C is disposed over the first OLED material 112A, second OLED material 112B, and third OLED material 112C, respectively, of the PDL structures 126 in each sub-pixel 106. The first cathode 114A, the second cathode 114B, and the third cathode 114C may be disposed on a portion of a sidewall 111 of the lower portion 110A. The first cathode 114A, the second cathode 114B, and the third cathode 114C includes a conductive material, such as a metal, e.g., chromium, titanium, aluminum, ITO, or a combination thereof. In other embodiments, which can be combined with other embodiments described herein, the first OLED material 112A, second OLED material 112B, and third OLED material 112C and the first cathode 114A, the second cathode 114B, and the third cathode 114C are disposed over a top surface 115 of the upper portion 110B of the inorganic overhang structures 110, respectively.

Each sub-pixel 106 includes include an encapsulation layer 116. The encapsulation layer 116 may be or may correspond to a local passivation layer. The encapsulation layer 116 of a respective sub-pixel, e.g., first encapsulation layer 116A, second encapsulation layer 116B, and third encapsulation layer 116C, is disposed over the first cathode 114A, the second cathode 114B, and the third cathode 114C, respectively, with the encapsulation layer 116 extending under at least a portion of each of the inorganic overhang structures 110 and along a sidewall of each of the inorganic overhang structures 110. The encapsulation layer 116 is disposed over the cathode and over at least the sidewall 111 of the lower portion 110A. In some embodiments, which can be combined with other embodiments described herein, the encapsulation layer 116 is disposed over the sidewall 113 of the upper portion 110B. In some embodiments, which can be combined with other embodiments described herein, the encapsulation layer 116 is disposed over the top surface 115 of the upper portion 110B of the inorganic overhang structures 110. The encapsulation layer 116 can include a non-conductive inorganic material, such as the silicon-containing material. The silicon-containing material may include Si₃N₄ containing materials.

An intermediate layer 118 may be deposited over the encapsulation layer 116, as shown in FIG. 9A. The intermediate layer 118 can include a monomer and/or a polymer, e.g., an inorganic polymer or an organic polymer. In some embodiments, the intermediate layer 118 can include a thickness of about 1 μm to about 10 μm, e.g., about 1 μm to about 5 μm, about 2 μm to about 8 μm, or about 4 μm to about 6 μm. Optionally, a second encapsulation layer 120 may be deposited over the intermediate layer 118. The second encapsulation layer 120 can include any of the encapsulation layer 116. The second encapsulation layer 120 can include a thickness of about 1 μm to about 10 μm, e.g., about 1 μm to about 5 μm, about 2 μm to about 8 μm, or about 4 μm to about 6 μm.

A plurality of mask structures 122 may be disposed over the second encapsulation layer 120. The plurality of mask structures 122 can be a material suitable to absorb external and/or internal light, e.g., a black material such as a black absorbing material. The plurality of mask structures 122 are disposed according to the first sub-pixel 108A, a second sub-pixel 108B, and a third sub-pixel 108C. For example, the plurality of mask structures 122 are disposed to such that the plurality of mask structures are aligned with the PDL structures 126 and/or the inorganic overhang structures 110, thereby allowing light emission from the OLED materials through an opening between the plurality of mask structures 122.

A color filter is disposed in the opening between the plurality of mask structures 122. A first color filter 124A may be aligned with the first sub-pixel 108A, a second color filter 124B may be aligned with the second sub-pixel 108B, and a third color filter 124C may be aligned with the third sub-pixel 108C. Each of the first color filter 124A, the second color filter 124B, or the third color filter 124C may be configured to restrict light transparency from a bottom surface of the color filter to a top surface of the color filter to a specific color and/or wavelength, e.g., red, green, and/or blue. For example, the first color filter 124A may receive a yellow, white, and/or red light and restrict light transparency to the color red, thereby only emitting red emission from the first sub-pixel 108A. As a further example, the second color filter 124B may receive a yellow, white, and/or red light and may restrict light transparency to the color green, thereby only emitting green emission from the second sub-pixel 108B. As a further example, the third color filter 124C may receive a blue, white, and/or yellow light and may restrict light transparency to the color blue, thereby only emitting blue emission from the third sub-pixel 108C.

Optionally, a third encapsulation layer 902 may be deposited over the plurality of mask structures 122, the first color filter 124A, the second color filter 124B, and the third color filter 124C, as shown in FIG. 9B. The third encapsulation layer 902 can include any of the encapsulation layer 116 and/or the second encapsulation layer 120. The third encapsulation layer 902 can include a thickness of about 1 μm to about 10 μm, e.g., about 1 μm to about 5 μm, about 2 μm to about 8 μm, or about 4 μm to about 6 μm.

Optionally, the plurality of mask structures 122 and the color filters, e.g., the first color filter 124A, the second color filter 124B, or the third color filter 124C may be disposed on a backing material 130, as shown in FIG. 9C. The backing material 130 can include a transparent material suitable for supporting the plurality of mask structures 122 and the color filters, e.g., the first color filter 124A, the second color filter 124B, or the third color filter 124C. The plurality of mask structures 122 and the color filters, e.g., the first color filter 124A, the second color filter 124B, or the third color filter 124C may be disposed on the backing material 130, inverted, and placed on the intermediate layer 118, as shown in FIG. 9C, thereby allowing for manufacturing of the color filters to occur in parallel with the manufacturing of the sub-pixels, and reducing the time for manufacturing.

Optionally, the plurality of mask structures 122 may be deposited over the first encapsulation layer 116A, where no intermediate layer 118 separates the plurality of mask structures 122 and the first encapsulation layer 116A, as shown in FIG. 9D. The color filters, e.g., the first color filter 124A, the second color filter 124B, or the third color filter 124C, are disposed over the first encapsulation layer 116A, and between the plurality of mask structures 122. Without being bound by theory, by disposing the color filters over the encapsulation layer 116, a reduction of manufacturing costs may occur. Optionally, the third encapsulation layer 902 may be deposited over the plurality of mask structures 122, the first color filter 124A, the second color filter 124B, and the third color filter 124C, as shown in FIG. 9D.

FIG. 9E is a schematic, cross-sectional view of a sub-pixel circuit 900, in which the sub-pixel circuit 500 has the OLED material 112 and the cathode 114 shared across the first sub-pixel 108A, the second sub-pixel 108B, and the third sub-pixel 108C. The OLED material 112 can includes a white emitting OLED material, as described herein. The OLED material 112 and the cathode 114 may be shared due to a removal of an inorganic overhangs structure 110 between the first sub-pixel 108A and the second sub-pixel 108B, and the second sub-pixel 108B and the third sub-pixel 108C.

The third sub-layer 105C of the first sub-pixel 108A is thicker than a third sub-layer 105C of the second sub-pixel 108B. Additionally, the third sub-layer 105C of the second sub-pixel 108B is thicker than the third sub-layer 105C of the third metal layer 104C. Without being bound by theory, by having the third sub-layer 105C of the first sub-pixel 108A be thicker than the third sub-layer 105C of the second sub-pixel 108B, and the third sub-layer 105C of the second sub-pixel 108B be thicker than the third sub-layer 105C of the third metal layer 104C, the light emitted from the OLED material 112 may be shifted such that the first sub-pixel 108A emits a red light, the second sub-pixel 108B emits a green light, and the third sub-pixel 108C emits a blue light. Additionally, and without being bound by theory, a reduction of manufacturing costs occurs due to the reduced materials required to produce the sub-pixel circuit 900, e.g., reduction of overhang structures, and reduction of individualized OLED materials.

Optionally, the plurality of mask structures 122 and the color filters, e.g., the first color filter 124A, the second color filter 124B, or the third color filter 124C may be disposed on a backing material 130, as shown in FIG. 9F. The backing material 130 can include a transparent material suitable for supporting the plurality of mask structures 122 and the color filters, e.g., the first color filter 124A, the second color filter 124B, or the third color filter 124C. The plurality of mask structures 122 and the color filters, e.g., the first color filter 124A, the second color filter 124B, or the third color filter 124C may be disposed on the backing material 130, inverted, and placed on the intermediate layer 118, as shown in FIG. 9F, thereby allowing for manufacturing of the color filters to occur in parallel with the manufacturing of the sub-pixels, and reducing the time for manufacturing.

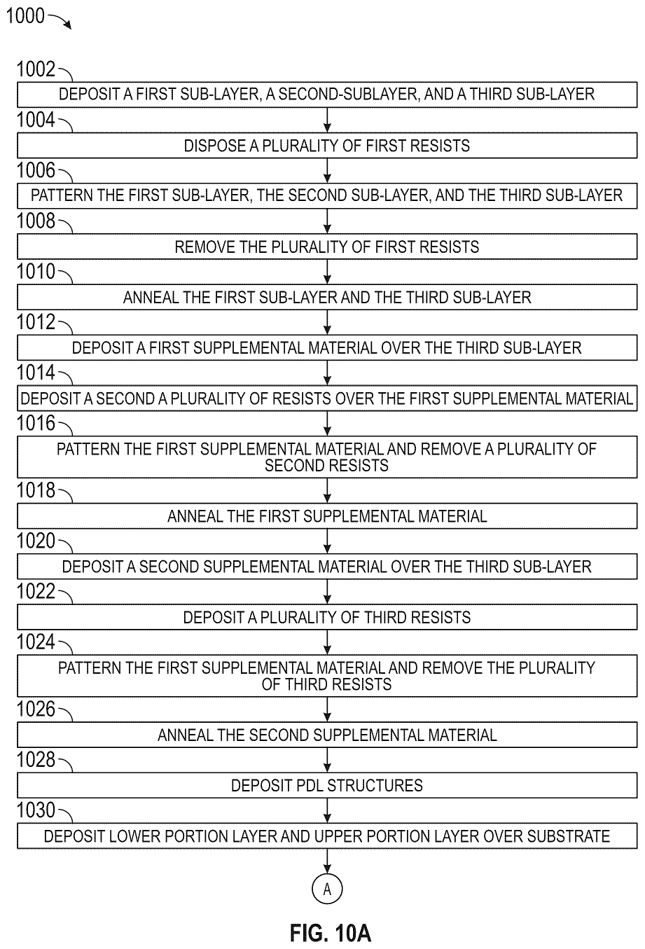

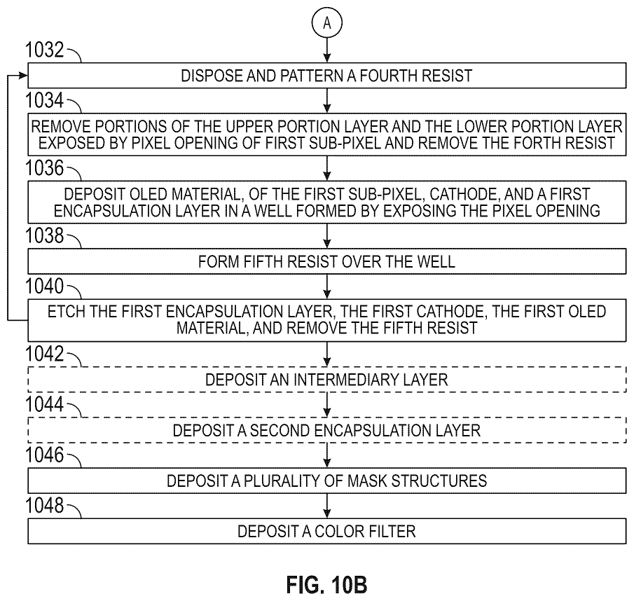

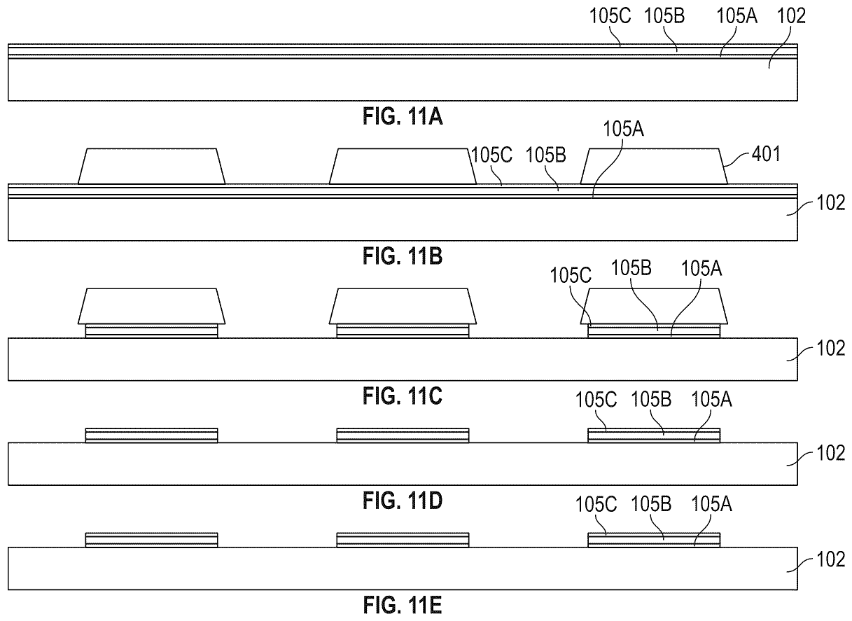

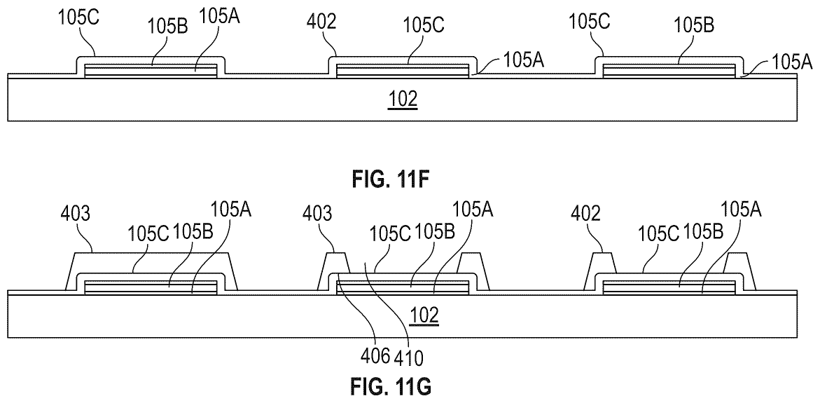

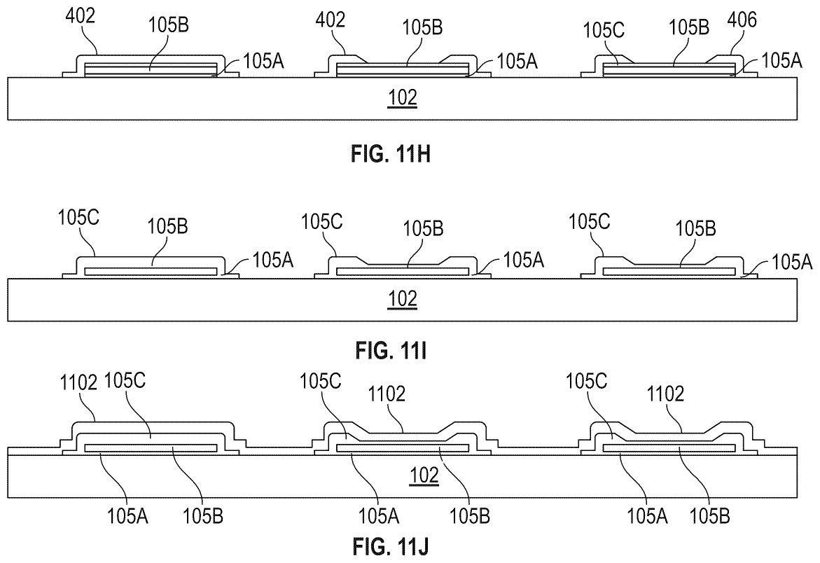

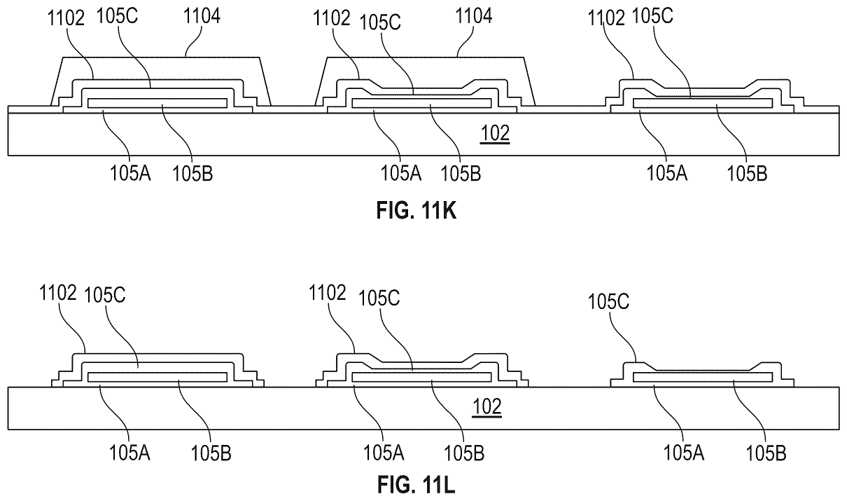

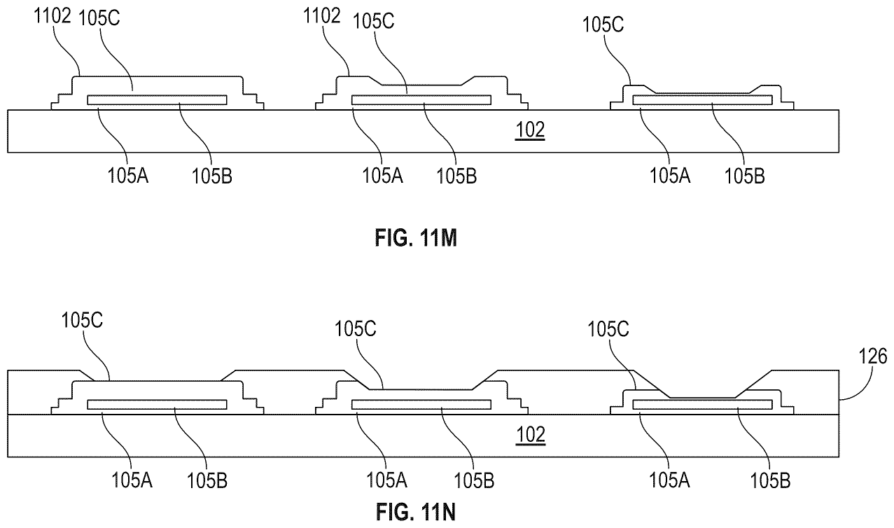

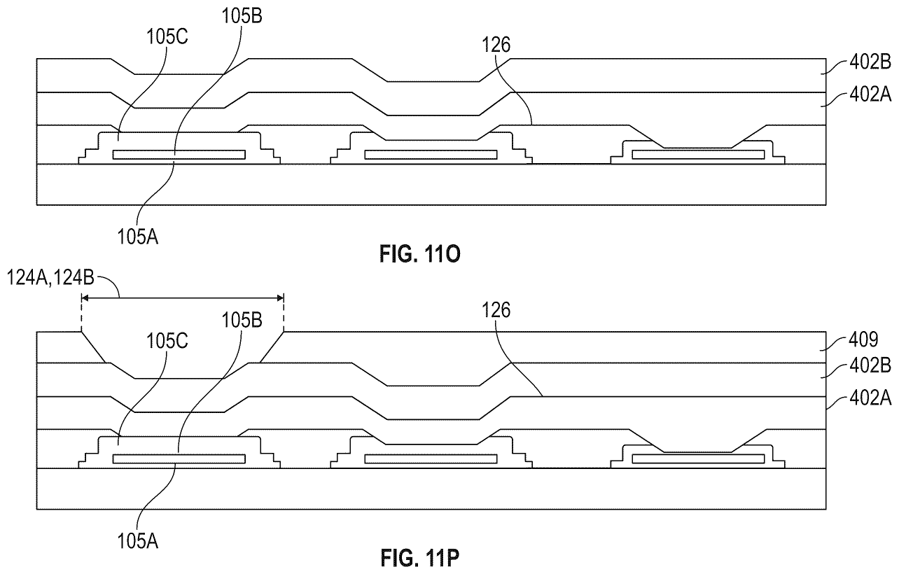

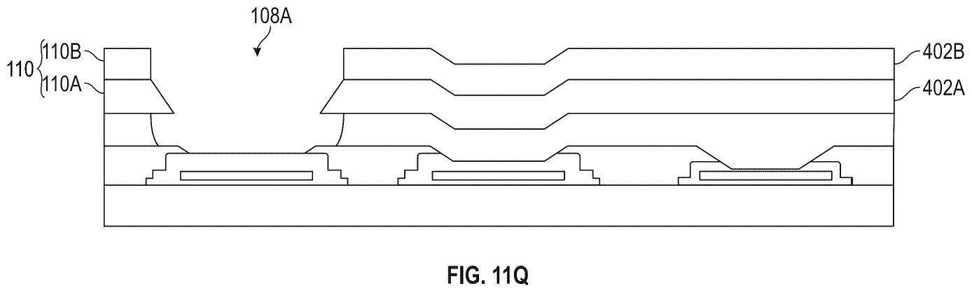

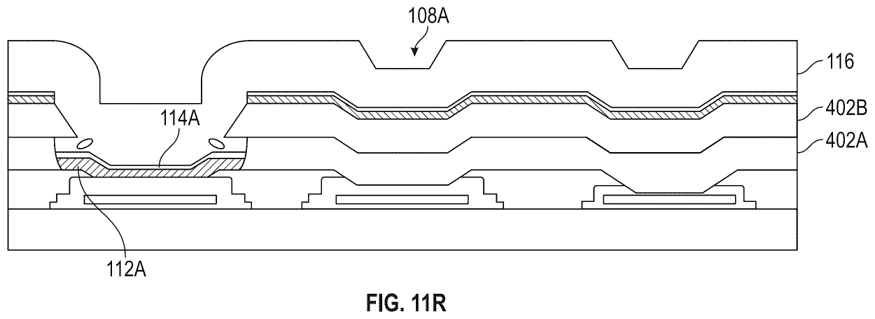

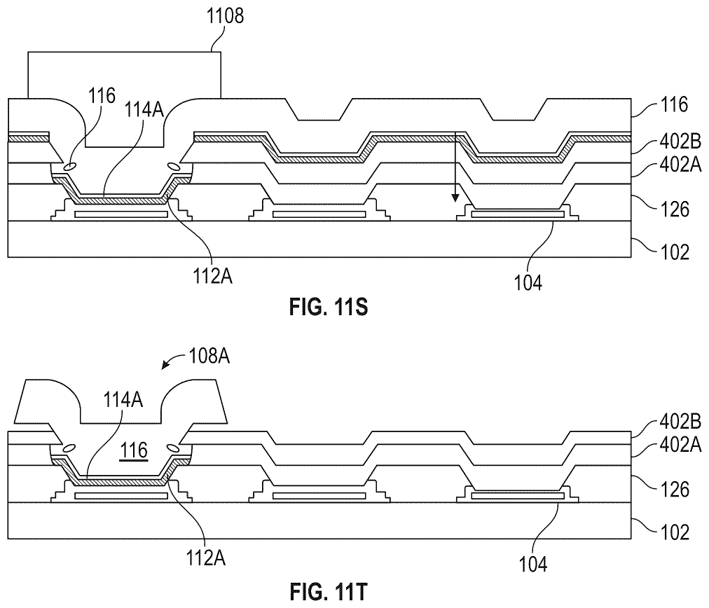

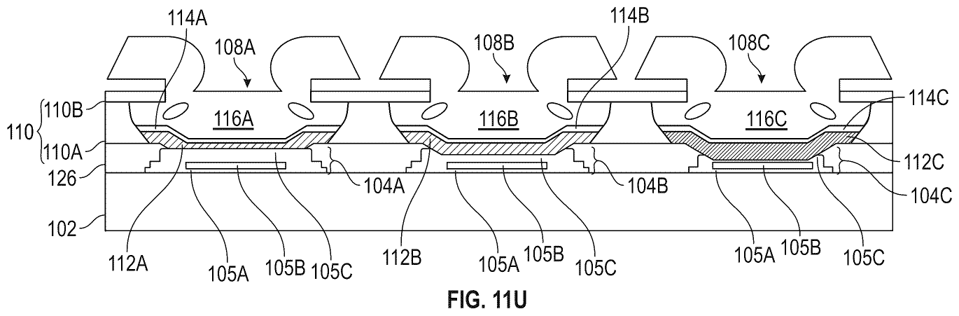

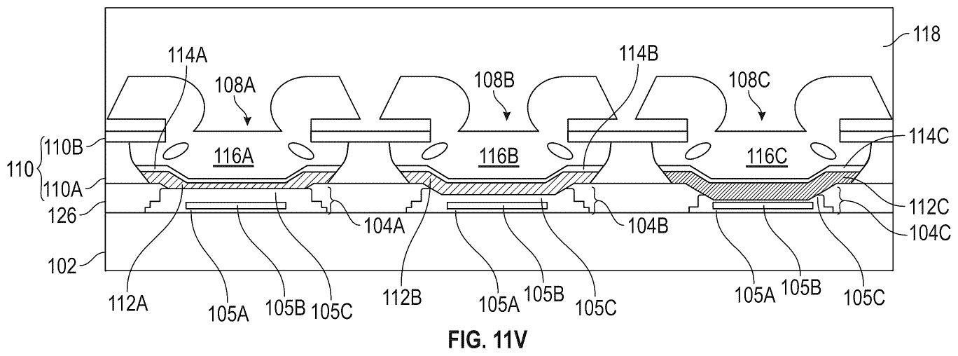

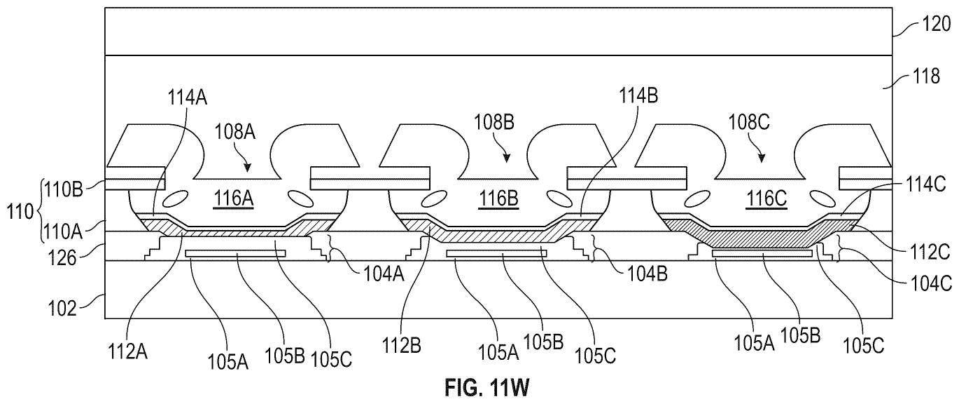

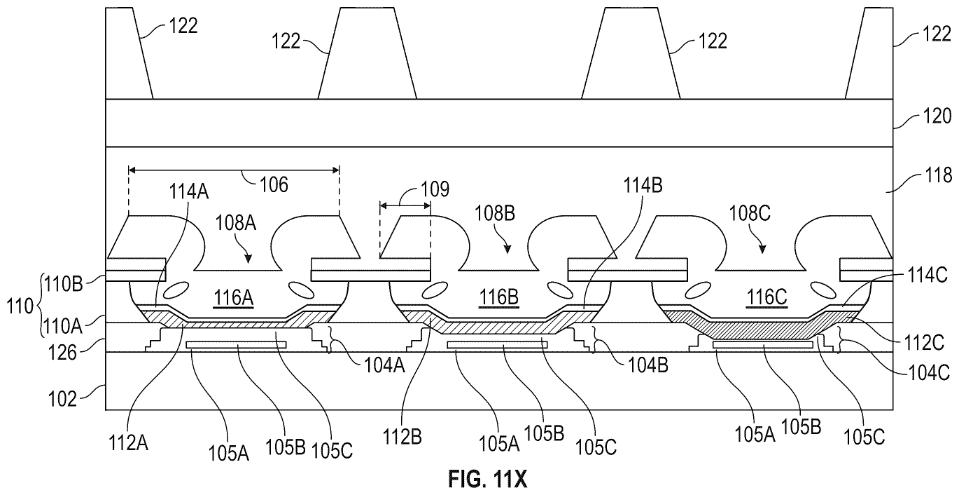

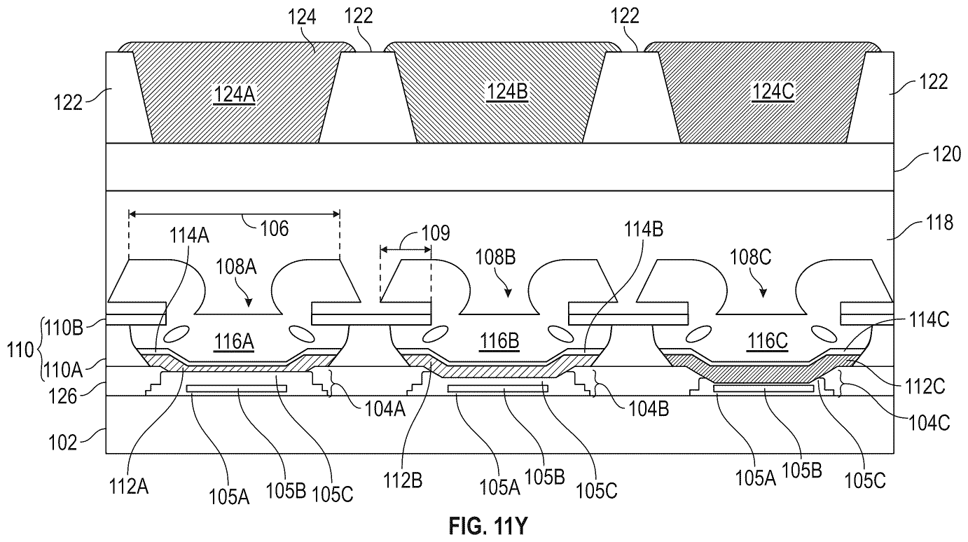

FIGS. 10A and 10B are flow diagrams of a method 1000 for forming a sub-pixel circuit 900. FIGS. 11A-11Y are schematic, cross-sectional views of a substrate 102 during the method 1000 for forming the sub-pixel circuit 900 according embodiments described herein.

At operation 1002, as shown in FIG. 11A, a first sub-layer 105A, a second sub-layer 105B, and a third sub-layer 105C is deposited on a substrate 102. The first sub-layer 105A, and the third sub-layer 105C include an amorphous transparent conductive oxide, e.g., amorphous indium tin oxide. The second sub-layer 105B includes a metal layer such as a silver layer. At operation 1004, as shown in FIG. 11B, a plurality of first resists 401 are disposed the third sub-layer 105C. The plurality of first resists are deposited over the third sub-layer 105C such that each of a first metal layer 104A, a second metal layer 104B, and a third metal layer 104C is covered by each first resist of the plurality of first resists 401. At operation 1006, as shown in FIG. 11C, the first sub-layer 105A, the second sub-layer 105B, and the third sub-layer 105C is patterned to form the first metal layer 104A, the second metal layer 104B, and the third metal layer 104C. The patterning is one of a photolithography, digital lithography process, or laser ablation process.

At operation 1008, as shown in FIG. 11D, the plurality of first resists 401 are removed to expose the first metal layer 104A, the second metal layer 104B, and the third metal layer 104C. At operation 1010, as shown in FIG. 11E, the first sub-layer 105A and the third sub-layer 105C are annealed according to an annealing process. The first sub-layer 105A and the third sub-layer 105C are annealed to produce a poly-crystallized transparent conductive oxide from the amorphous transparent conductive oxide. For example, the first sub-layer 105A and the third sub-layer 105C may be annealed to form a poly-crystallized indium tin oxide.

At operation 1012, as shown in FIG. 11F, a first supplemental material 402 is deposited over the third sub-layer 105C. It is contemplated that operation 1012 is optional while performing the method 1000. The first supplemental material 402 includes an amorphous transparent conductive oxide, e.g., amorphous indium tin oxide. The first supplemental material 402 can be deposited to provide a thickness of about 50 nm to about 100 nm. The first supplemental material 402 can include a first oxide layer disposed over the third sub-layer 105C and/or the substrate 102 and a second oxide layer disposed over the first oxide layer. The second oxide layer can include a first amorphous transparent conductive oxide such as amorphous indium zinc oxide. The second oxide layer can include a second amorphous transparent conductive oxide such as amorphous indium tin oxide.

The first oxide layer can include a thickness of about 45 nm to about 160 nm. The second oxide layer can include a thickness of about less than 40 nm, e.g., about 5 nm to about 40 nm. Without being bound by theory, by reducing the thickness of the second oxide layer to be less than 40 nm, a reduction of partial crystallization of the second oxide layer may occur, thereby improving an etch selectivity and/or efficiency during subsequent processing steps. For example, a thickness of about 40 nm or less of indium tin oxide may have greater etch selectivity and/or efficiency compared to a thickness of about 50 nm or greater of indium tin oxide. Additionally, and without being bound by theory, a first supplemental material 402 including a first oxide layer comprising indium zinc oxide having a thickness of about 45 nm to about 160 nm, and a second oxide layer comprising indium tin oxide having a thickness of less than 40 nm may provide enhanced etch selectivity and/or efficiency during subsequent processing steps, e.g., etching such as etching with oxalic acid.

At operation 1014, as shown in FIG. 11G, a plurality of second resists 403 is deposited over the first supplemental material 402. It is contemplated that operation 1014 is optional while performing the method 1000. The plurality of second resists 403 is deposited over the first supplemental material 402 such that a first metal layer 104A is covered by the plurality of second resists 403. Optionally, the plurality of second resists 403 may be deposited over a lateral edge 406 of a second metal layer 104B and a third metal layer 104C, thereby exposing a top central surface 410 of the second metal layer 104B and the third metal layer 104C. Without being bound by theory, the plurality of second resists 403 may be deposited over the lateral edge of the second metal layer 104B and the third metal layer 104C such that the third sub-layer 105C does not get etched over the lateral edge, thereby providing enhanced protection of the edge of the second sub-layer 105B.

The plurality of second resists 403 is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the plurality of second resists 403 determines whether the resist is a positive resist or a negative resist.

At operation 1016, as shown in FIG. 11H, the first supplemental material 402 is patterned and the plurality of second resists 403 are removed. It is contemplated that operation 1016 is optional while performing the method 1000. The patterning is one of a photolithography, digital lithography process, or laser ablation process. At operation 1018, as shown in FIG. 11I, the second oxide layer of the first supplemental material 402 is annealed. It is contemplated that operation 1018 is optional while performing the method 1000. The first oxide layer remains an amorphous transparent conductive oxide, e.g., amorphous indium zinc oxide. The second oxide layer of the first supplemental material 402 is annealed to produce a poly-crystallized transparent conductive oxide from the amorphous transparent conductive oxide. For example, the second oxide layer of the first supplemental material 402 may be annealed to form a poly-crystallized indium tin oxide. In some embodiments, which may be combined with other embodiments, by annealing the second oxide layer of the first supplemental material 402 to produce a poly-crystallized transparent conductive oxide, the second oxide layer of the first supplemental material 402 may be similar to the third sub-layer 105C. For example, second oxide layer of the first supplemental material 402, when annealed, may become the third sub-layer 105C. In one or more embodiments, operations 1012 to 1018 are omitted from the method 1000. In one or more embodiments, operation 1020 is performed subsequent to operation 1010. In one or more embodiments, the first metal layer 104A, the second metal layer 104B, and the third metal layer 104C have the same thickness as one another.

At operation 1020, as shown in FIG. 11J, a second supplemental material 1102 is disposed on the third sub-layer 105C. The second deposition process includes depositing of the second supplemental material 1102 over the third sub-layer 105C of the first metal layer 104A, the second metal layer 104B, and/or the third metal layer 104C. The second supplemental material 1102 can be deposited to provide a thickness of about 50 nm to about 100 nm of the second supplemental material 1102.

At operation 1022, as shown in FIG. 11K, a plurality of third resists 1104 is deposited over the second supplemental material 1102. The plurality of third resists 1104 is deposited over the second supplemental material 1102 such that a first metal layer 104A and a second metal layer 104B is covered by the plurality of third resists 1104. Optionally, the plurality of third resists 1104 is not deposited over a third metal layer 104C, thereby exposing the third metal layer 104C. The plurality of third resists 1104 is a positive resist or a negative resist. The chemical composition of the plurality of third resists 1104 determines whether the resist is a positive resist or a negative resist.

At step 1024, as shown in FIG. 11L, the first supplemental material 402 is patterned and the plurality of third resists 1104 are removed. The patterning is one of a photolithography, digital lithography process, or laser ablation process. At step 1026, as shown in FIG. 11M, the second supplemental material 1102 is annealed. The second supplemental material 1102 is annealed to produce a poly-crystallized transparent conductive oxide from the amorphous transparent conductive oxide. For example, the second supplemental material 1102 may be annealed to form a poly-crystallized indium tin oxide. In some embodiments, when annealed, the second supplemental material 1102 may be the third sub-layer 105C.

At operation 1028, as shown in FIG. 11N, PDL structures 126 are deposited over the substrate 102 such that only the metal layers 104 remain exposed. At operation 1030, as shown in FIG. 11O, a lower portion layer 402A and an upper portion layer 402B are deposited over the substrate 102. The lower portion layer 402A is disposed over the PDL structures 126 and the metal layers 104, e.g., the first metal layer 104A, the second metal layer 104B, and the third metal layer 104C. The upper portion layer 402B is disposed over the lower portion layer 402A. In various embodiments, the lower portion layer 402A corresponds to the lower portion 110A and the upper portion layer 402B corresponds to the upper portion 110B of the inorganic overhang structures 110. In some embodiments, an assistant cathode layer is disposed between the lower portion layer 402A and the PDL structures 126 and the metal layers 104.

At operation 1032, as shown in FIG. 11P, a fourth resist 409 is disposed and patterned. The fourth resist 1106 is disposed over the upper portion layer 402B. The fourth resist 409 is a positive resist or a negative resist. The chemical composition of the fourth resist 409 determines whether the resist is a positive resist or a negative resist. The fourth resist 409 is patterned to form one of a pixel opening of a first sub-pixel 108a. The patterning is one of a photolithography, digital lithography process, or laser ablation process.

At operation 1034, as shown in FIG. 11Q, portions of the upper portion layer 402B and the lower portion layer 402A exposed by the pixel opening are removed and the fourth resist 409 is removed. The upper portion layer 402B exposed by the pixel opening may be removed by a dry etch process. The lower portion layer 402A exposed by the pixel opening may be removed by a wet etch process. In embodiments including the assistant cathode layer, a portion of the assistant cathode layer may be removed by a dry etch process or a wet etch process to form an assistant cathode (not shown) disposed under the lower portion 110A. Operation 1034 forms the inorganic overhang structures 110 of the first sub-pixel 108a. The etch selectivity of the materials of the upper portion layer 402B (corresponding to the upper portion 110B) and the lower portion layer 402A (corresponding to the lower portion 110A) coupled with the etch processes can remove the exposed portions of the upper portion layer 402B and the lower portion layer 402A. This can provide for the bottom surface 107 of the upper portion 110B being wider than the top surface 105 of the lower portion 110A, thereby forming the overhang 109 (as shown in FIGS. 9A-9F).

At operation 1036, as shown in FIG. 11R, the first OLED material 112A of the first sub-pixel 108a, the first cathode 114A, and the first encapsulation layer 116A are deposited. In some embodiments, the first OLED material 112A does not contact the lower portion 110A and the first cathode 114A directly contacts the lower portion 110A of the inorganic overhang structures 110. The first encapsulation layer 116A is deposited over the first cathode 114A. In embodiments including capping layers (not shown), the capping layers are deposited between the first cathode 114A and the first encapsulation layer 116A. The capping layers may be deposited by evaporation deposition.

At operation 1038, as shown in FIG. 11S, a fifth resist 1108 is formed in a well of the first sub-pixel 108a and over the first encapsulation layer 116A disposed on the upper portion layer 402B. The fifth resist 1108 can be formed in the well, in which the fifth resist 1108 can fill the sub-pixel the well and one or more cavities within the encapsulation layer 116, which are formed due to the overhang 109. The fifth resist 1108 can include a fifth resist thickness of about 0.1 μm to about 10 μm, e.g., about 0.1 μm to about 8 μm, about 0.5 μm to about 5 μm, or about 0.9 μm to about 1.1 μm, over the upper portion 110B. At operation 1040, as shown in FIG. 11T, the first encapsulation layer 116A, the first cathode 114A, and the first OLED material 112A are etched and the fifth resist 1108 is removed.

Operations 1032-1040 are repeated to produce the second sub-pixel 108B and the third sub-pixel 108C, as shown in FIG. 11U. In some embodiments, which can be combined with other embodiments, operations 1032-1040 can be iteratively repeated to provide for the formation of a plurality of sub-pixels. Each sub-pixel of the plurality of sub-pixels can include an OLED for a specific color, e.g., white, green, red, blue, or a combination thereof.

Optionally, at operation 1042, as shown in FIG. 11V, an intermediate layer 118 may be deposited over the encapsulation layer 116 and the inorganic overhang structures 110. The intermediate layer 118 can include a monomer and/or a polymer, e.g., an inorganic polymer or an organic polymer. In some embodiments, the intermediate layer 118 can include a thickness of about 1 μm to about 10 μm, e.g., about 1 μm to about 5 μm, about 2 μm to about 8 μm, or about 4 μm to about 6 μm. Optionally, at operation 1044, as shown in FIG. 11W, a second encapsulation layer 120 is deposited over the intermediate layer 118. The second encapsulation layer 120 can include any of the encapsulation layer 116. The second encapsulation layer 120 can have a thickness of about 1 μm to about 10 μm, e.g., about 1 μm to about 5 μm, about 2 μm to about 8 μm, or about 4 μm to about 6 μm.

At operation 1046, as shown in FIG. 11X a plurality of mask structures 122 are disposed over the intermediate layer 118 and/or the second encapsulation layer 120. The plurality of mask structures 122 may be disposed according to the first sub-pixel 108A, a second sub-pixel 108B, and a third sub-pixel 108C. For example, the plurality of mask structures 122 may be disposed such that the mask structures align with the PDL structures 126 and/or the inorganic overhang structures 110, thereby allowing light emission emitted from the OLED materials through an opening between the plurality of mask structures 122.

At operation 1048, as shown in FIG. 11Y, a color filter 124 is disposed in the opening between the plurality of mask structures 122. A first color filter 124A may be aligned with the first sub-pixel 108A, a second color filter 124B may be aligned with the second sub-pixel 108B, and a third color filter 124C may be aligned with the third sub-pixel 108C. Each of the first color filter 124A, the second color filter 124B, or the third color filter 124C may be configured to restrict light transparency from a bottom surface of the color filter to a top surface of the color filter to a specific color and/or wavelength, e.g., red, green, and/or blue. For example, the first color filter 124A may receive a yellow, white, and/or red light and restrict light transparency to the color red, thereby only emitting red emission from the first sub-pixel 108A. As a further example, the second color filter 124B may receive a yellow, white, and/or red light and may restrict light transparency to the color green, thereby only emitting green emission from the second sub-pixel 108B. As a further example, the third color filter 124C may receive a blue, white, and/or yellow light and may restrict light transparency to the color blue, thereby only emitting blue emission from the third sub-pixel 108C.

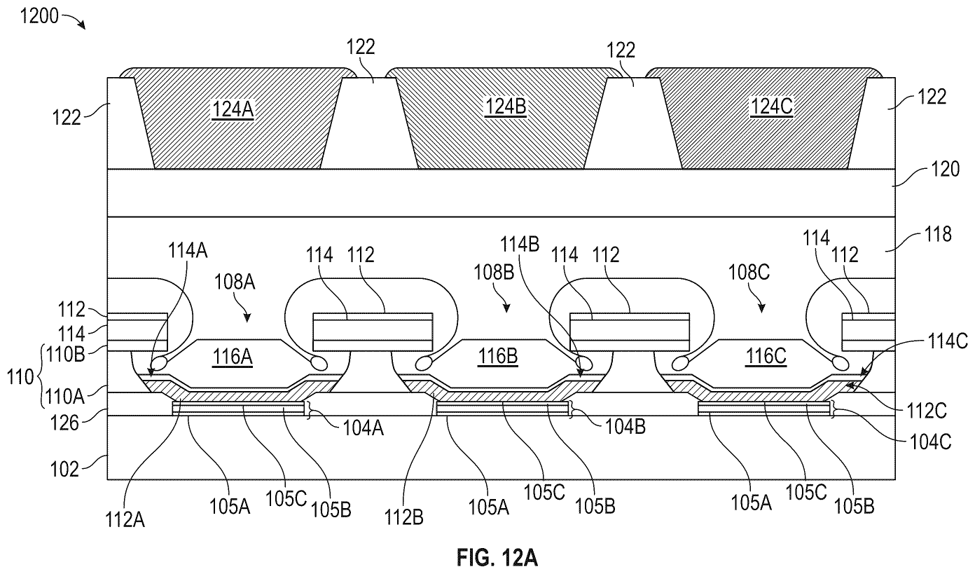

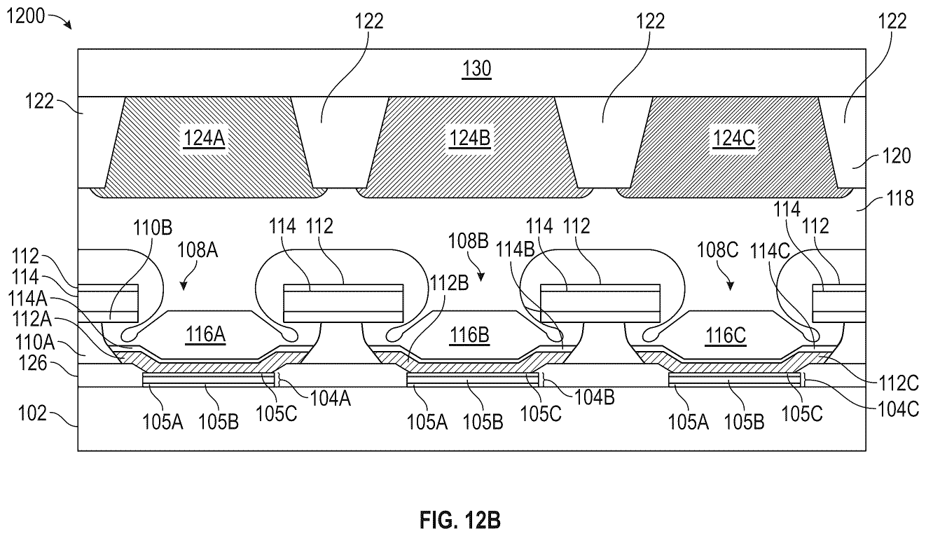

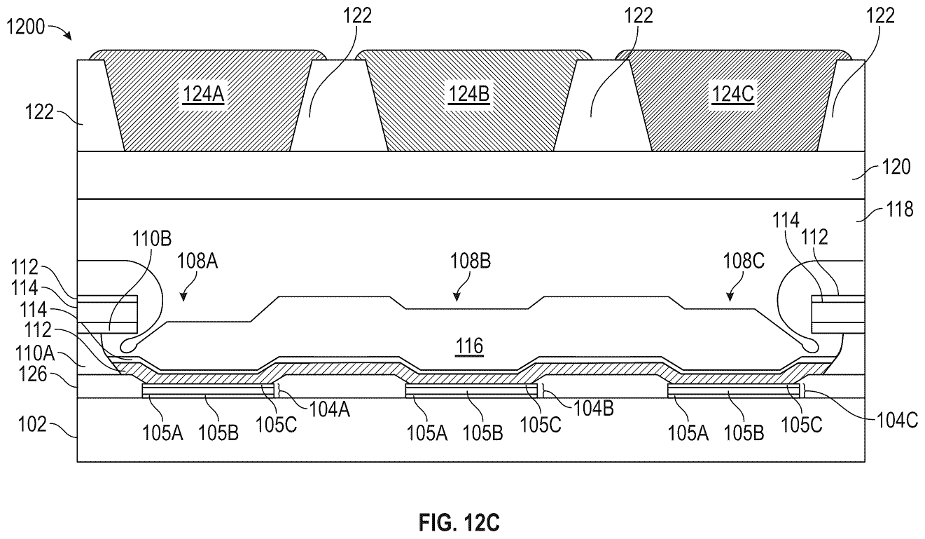

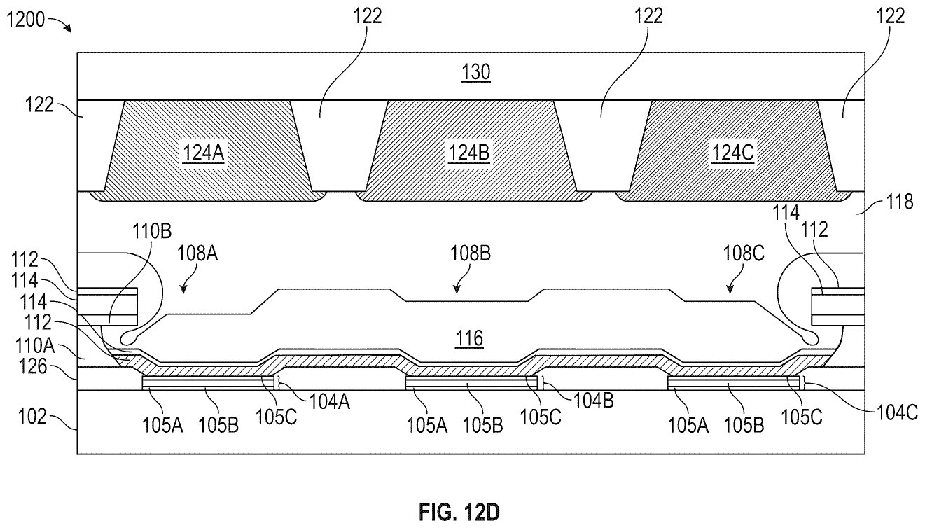

FIG. 12A is a schematic, cross-sectional view of a sub-pixel circuit 1200. The sub-pixel circuit 1200 includes a substrate 102. Metal layers 104 are be patterned on the substrate 102. The metal layers 104 are configured to operate anodes of respective sub-pixels. The metal layers 104 are a layer stack of a first sub-layer 105A, a second sub-layer 105B disposed over the first sub-layer 105A, and a third sub-layer 105C disposed over the second sub-layer 105B. The first sub-layer 105A includes a transparent conductive oxide (TCO) layer, e.g., indium tin oxide or indium zinc oxide. The first sub-layer 105A can include a thickness of about 1 nm to about 50 nm.

The second sub-layer 105B includes a metal layer, e.g., chromium, titanium, gold, silver, copper, aluminum, or a combination thereof, disposed on the first sub-layer 105A. The second sub-layer 105B can include a thickness of about 50 nm to about 200 nm.

The third sub-layer 105C includes a transparent conductive oxide (TCO) layer, e.g., indium tin oxide or indium zinc oxide. The third sub-layer 105C can include a thickness of about 1 nm to about 200 nm. Optionally, the first sub-layer 105A, the second sub-layer 105B, and the third sub-layer 105C has a similar thickness.

In one embodiment, which can be combined with other embodiments described herein, the metal layers 104 are pre-patterned on the substrate 102, e.g., the substrate 102 is a pre-patterned indium tin oxide (ITO) glass substrate. In one embodiment, which can be combined with other embodiments described herein, the metal layers 104 are pre-patterned on the substrate 102, e.g., the metal layers 104 include a first sub-layer 105A of indium tin oxide, a second sub-layer 105B of silver, and a third sub-layer 105C of indium tin oxide.

The pixels are defined by adjacent pixel-defining layer (PDL) structures disposed on the substrate 102. The PDL structures 126 can be disposed on the substrate 102. The PDL structures 126 include one of an organic material, an organic material with an inorganic coating disposed thereover, or an inorganic material. The organic material of the PDL structures 126 includes, but is not limited to, polyimides. The inorganic material of the PDL structures 126 includes, but is not limited to, silicon oxide (SiO₂), silicon nitride (Si₃N₄), silicon oxynitride (Si₂N₂O), magnesium fluoride (MgF₂), or combinations thereof. Adjacent PDL structures define a respective sub-pixel and expose the anode (i.e., metal layer 104) of the respective sub-pixel of the sub-pixel circuit 1200.

The sub-pixel circuit 1200 has a plurality of sub-pixels 106 including at least a first sub-pixel 108A, a second sub-pixel 108B, and a third sub-pixel 108C. While the Figures depict the first sub-pixel 108A, the second sub-pixel 108B, and the third sub-pixel 108C, the sub-pixel circuit 1200 of the embodiments described herein may include three or more sub-pixels 106, such as a fourth and a fifth sub-pixel. Each sub-pixel 106 has an OLED material, e.g., first OLED material 112A, second OLED material 112B, and third OLED material 112C, configured to emit a white, red, green, blue or other color light when energized, e.g., the first OLED material 112A of the first sub-pixel 108A emits a yellow light when energized, the second OLED material 112B of the second sub-pixel 108B emits a yellow light when energized, the third OLED material 112C of the third sub-pixel 108C emits a blue light when energized, and the OLED material of a fourth sub-pixel emits a different color light when energized.

Inorganic overhang structures 110 are disposed over the substrate 102, thereby defining each sub-pixel of the plurality of sub-pixels. In some embodiments, as shown in FIG. 12A, the inorganic overhang structures 110 are disposed over each of the PDL structures 126. The inorganic overhang structures 110 are permanent to the sub-pixel circuit. The inorganic overhang structures 110 further define each sub-pixel 106 of the sub-pixel circuit 900. The inorganic overhang structures 110 include at least an upper portion 110B disposed on a lower portion 110A. A first configuration of the inorganic overhang structures 110 includes the upper portion 110B of a non-conductive inorganic material and the lower portion 110A of a conductive inorganic material. A second configuration of the inorganic overhang structures 110 includes the upper portion 110B of a conductive inorganic material and the lower portion 110A of a conductive inorganic material. A third configuration of the inorganic overhang structures 110 includes the upper portion 110B of a non-conductive inorganic material, the lower portion 110A of a non-conductive inorganic material, and an optional assistant cathode (not shown) disposed under the lower portion 110A. A fourth configuration of the inorganic overhang structures 110 includes the upper portion 110B of a conductive inorganic material, the lower portion 110A of a non-conductive inorganic material, and an optional assistant cathode (not shown) disposed under the lower portion 110A. The first, second, third, and fourth embodiments of the sub-pixel circuit 1200 include inorganic overhang structures 110 of at least one of the first, second, third, or fourth configurations. The inorganic overhang structures 110 are able to remain in place, e.g., are permanent.

The non-conductive inorganic material includes, but is not limited to, an inorganic silicon-containing material, e.g., the silicon-containing material includes oxides or nitrides of silicon, or combinations thereof. The conductive inorganic material includes, but is not limited to, a metal-containing material, e.g., the metal-containing material includes copper, titanium, aluminum, molybdenum, silver, indium tin oxide, indium zinc oxide, or combinations thereof.

At least a bottom surface 107 of the upper portion 110B is wider than a top surface 105 of the lower portion 110A to form an overhang 109. The bottom surface 107 larger than the top surface 105 forming the overhang 109 allows for the upper portion 110B to shadow the lower portion 110A. The shadowing of the overhang 109 provides for evaporation deposition each of the OLED material 112 and a cathode 114.

The OLED material, e.g., e.g., first OLED material 112A, second OLED material 112B, and third OLED material 112C, may include one or more of a HIL, a HTL, an EML, and an ETL. The OLED material, e.g., first OLED material 112A, second OLED material 112B, and third OLED material 112C, is disposed on the metal layer 104. In some embodiments, which can be combined with other embodiments described herein, the OLED material, e.g., first OLED material 112A, second OLED material 112B, and third OLED material 112C, is disposed on the metal layer 104 and over a portion of the PDL structures 126. A first cathode 114A, a second cathode 114B, and a third cathode 114C is disposed over the first OLED material 112A, second OLED material 112B, and third OLED material 112C, respectively, of the PDL structures 126 in each sub-pixel 106. The first cathode 114A, the second cathode 114B, and the third cathode 114C may be disposed on a portion of a sidewall 111 of the lower portion 110A. The first cathode 114A, the second cathode 114B, and the third cathode 114C includes a conductive material, such as a metal, e.g., chromium, titanium, aluminum, ITO, or a combination thereof. In other embodiments, which can be combined with other embodiments described herein, the first OLED material 112A, second OLED material 112B, and third OLED material 112C and the first cathode 114A, the second cathode 114B, and the third cathode 114C are disposed over a top surface 115 of the upper portion 110B of the inorganic overhang structures 110, respectively.

Each sub-pixel 106 includes include an encapsulation layer 116. The encapsulation layer 116 may be or may correspond to a local passivation layer. The encapsulation layer 116 of a respective sub-pixel, e.g., first encapsulation layer 116A, second encapsulation layer 116B, and third encapsulation layer 116C, is disposed over the first cathode 114A, the second cathode 114B, and the third cathode 114C, respectively, with the encapsulation layer 116 extending under at least a portion of each of the inorganic overhang structures 110 and along a sidewall of each of the inorganic overhang structures 110. The encapsulation layer 116 is disposed over the cathode and over at least the sidewall 111 of the lower portion 110A. In some embodiments, which can be combined with other embodiments described herein, the encapsulation layer 116 is disposed over the sidewall 113 of the upper portion 110B. In some embodiments, which can be combined with other embodiments described herein, the encapsulation layer 116 is disposed over the top surface 115 of the upper portion 110B of the inorganic overhang structures 110. The encapsulation layer 116 can include a non-conductive inorganic material, such as the silicon-containing material. The silicon-containing material may include Si₃N₄ containing materials.

An intermediate layer 118 may be deposited over the encapsulation layer 116, as shown in FIG. 12A. The intermediate layer 118 can include a monomer and/or a polymer, e.g., an inorganic polymer or an organic polymer. In some embodiments, the intermediate layer 118 can include a thickness of about 1 μm to about 10 μm, e.g., about 1 μm to about 5 μm, about 2 μm to about 8 μm, or about 4 μm to about 6 μm. Optionally, a second encapsulation layer 120 may be deposited over the intermediate layer 118. The second encapsulation layer 120 can include any of the encapsulation layer 116. The second encapsulation layer 120 can include a thickness of about 1 μm to about 10 μm, e.g., about 1 μm to about 5 μm, about 2 μm to about 8 μm, or about 4 μm to about 6 μm.

A plurality of mask structures 122 may be disposed over the second encapsulation layer 120. The plurality of mask structures 122 can be a material suitable to absorb external and/or internal light, e.g., a black material such as a black absorbing material. The plurality of mask structures 122 are disposed according to the first sub-pixel 108A, a second sub-pixel 108B, and a third sub-pixel 108C. For example, the plurality of mask structures 122 are disposed to such that the plurality of mask structures are aligned with the PDL structures 126 and/or the inorganic overhang structures 110, thereby allowing light emission from the OLED materials through an opening between the plurality of mask structures 122.

A color filter is disposed in the opening between the plurality of mask structures 122. A first color filter 124A may be aligned with the first sub-pixel 108A, a second color filter 124B may be aligned with the second sub-pixel 108B, and a third color filter 124C may be aligned with the third sub-pixel 108C. Each of the first color filter 124A, the second color filter 124B, or the third color filter 124C may be configured to restrict light transparency from a bottom surface of the color filter to a top surface of the color filter to a specific color and/or wavelength, e.g., red, green, and/or blue. For example, the first color filter 124A may receive a yellow, white, and/or red light and restrict light transparency to the color red, thereby only emitting red emission from the first sub-pixel 108A. As a further example, the second color filter 124B may receive a yellow, white, and/or red light and may restrict light transparency to the color green, thereby only emitting green emission from the second sub-pixel 108B. As a further example, the third color filter 124C may receive a blue, white, and/or yellow light and may restrict light transparency to the color blue, thereby only emitting blue emission from the third sub-pixel 108C.

Optionally, the plurality of mask structures 122 and the color filters, e.g., the first color filter 124A, the second color filter 124B, or the third color filter 124C may be disposed on a backing material 130, as shown in FIG. 12B. The backing material 130 can include a transparent material suitable for supporting the plurality of mask structures 122 and the color filters, e.g., the first color filter 124A, the second color filter 124B, or the third color filter 124C. The plurality of mask structures 122 and the color filters, e.g., the first color filter 124A, the second color filter 124B, or the third color filter 124C may be disposed on the backing material 130, inverted, and placed on the intermediate layer 118, as shown in FIG. 12B, thereby allowing for manufacturing of the color filters to occur in parallel with the manufacturing of the sub-pixels, and reducing the time for manufacturing.

FIG. 12C is a schematic, cross-sectional view of a sub-pixel circuit 1200, in which the sub-pixel circuit 1200 has the OLED material 112 and the cathode 114 shared across the first sub-pixel 108A, the second sub-pixel 108B, and the third sub-pixel 108C. The OLED material 112 can includes a white emitting OLED material, as described herein. The OLED material 112 and the cathode 114 may be shared due to a removal of an inorganic overhangs structure 110 between the first sub-pixel 108A and the second sub-pixel 108B, and the second sub-pixel 108B and the third sub-pixel 108C.

The third sub-layer 105C of the first sub-pixel 108A, the second sub-pixel 108B, and the third sub-pixel 108C is similar. Without being bound by theory, a reduction of manufacturing costs occurs due to the reduced materials required to produce the sub-pixel circuit 1200, e.g., reduction of overhang structures, and reduction of individualized OLED materials.

Optionally, the plurality of mask structures 122 and the color filters, e.g., the first color filter 124A, the second color filter 124B, or the third color filter 124C may be disposed on a backing material 130, as shown in FIG. 12D. The backing material 130 can include a transparent material suitable for supporting the plurality of mask structures 122 and the color filters, e.g., the first color filter 124A, the second color filter 124B, or the third color filter 124C. The plurality of mask structures 122 and the color filters, e.g., the first color filter 124A, the second color filter 124B, or the third color filter 124C may be disposed on the backing material 130, inverted, and placed on the intermediate layer 118, as shown in FIG. 12D, thereby allowing for manufacturing of the color filters to occur in parallel with the manufacturing of the sub-pixels, and reducing the time for manufacturing.

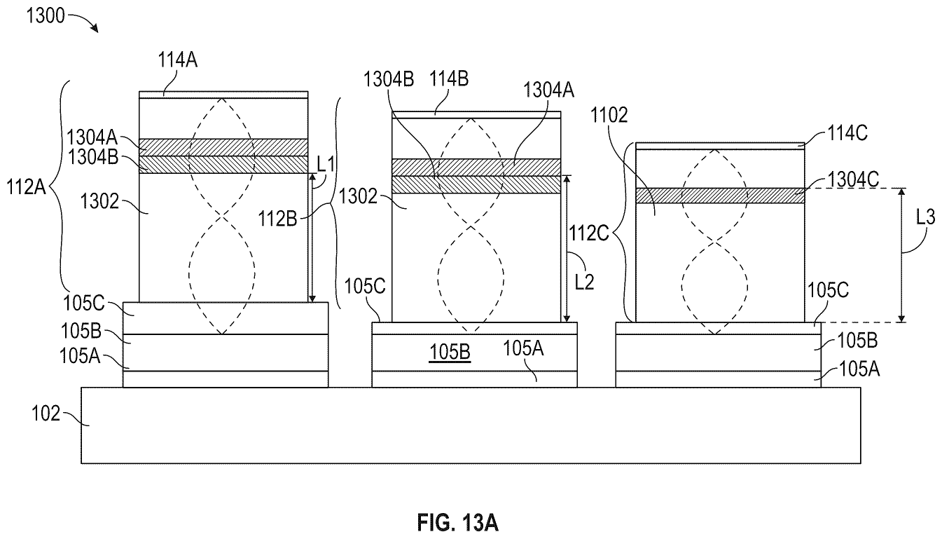

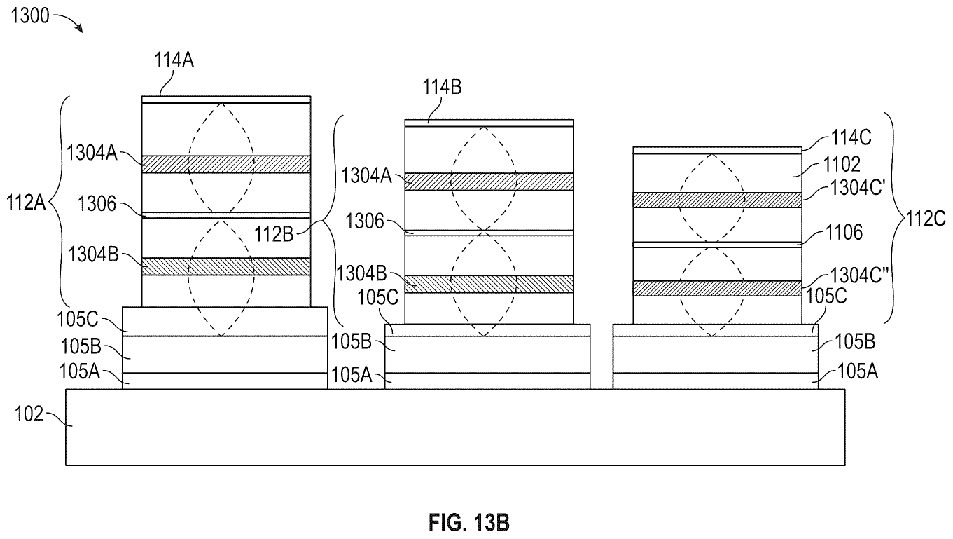

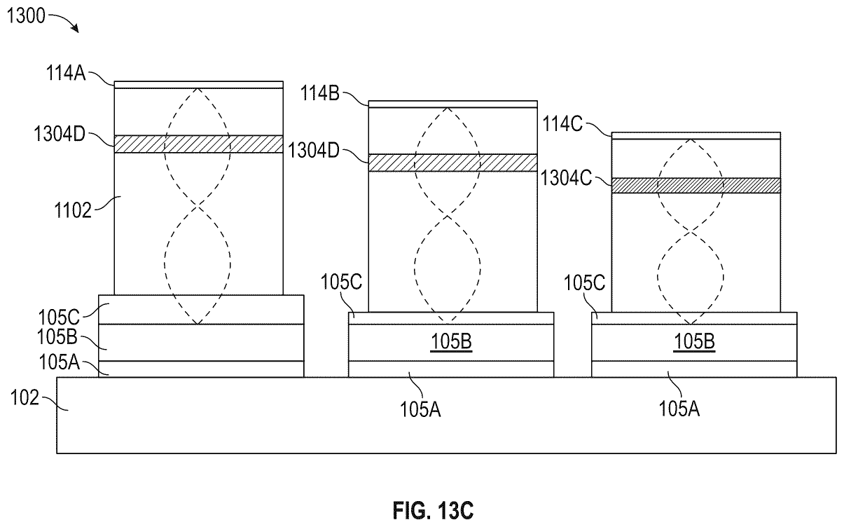

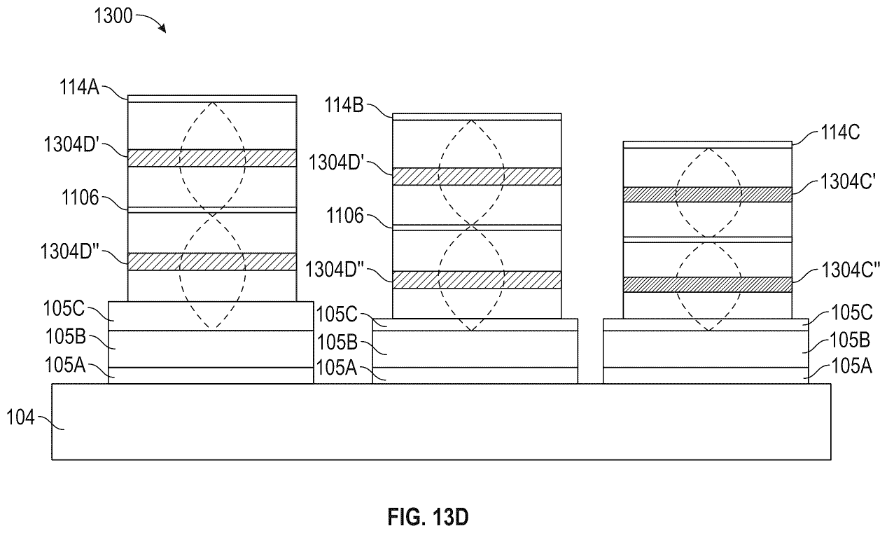

FIG. 13A shows a schematic, cross-sectional views of a substrate 1300. The substrate 1300 includes a plurality of metal layers, each metal layer 104 including a first sub-layer 105A, a second sub-layer 105B, and a third sub-layer 105C. The plurality of metal layers includes a first metal layer 104A, a second metal layer 104B, and a third metal layer 104C. The first metal layer 104A includes a third sub-layer 105C that is thicker than a third sub-layer 105C of the second metal layer 104B, and/or the third metal layer 104C.

The substrate 1300 includes a first OLED material 112A. The first OLED material 112A including a bulk OLED material 1302. The bulk OLED material 1302 includes a non-emission material of the first OLED material 112A. The first OLED material 112A includes a first emission material 1304A. The first emission material 1304A can include a material configured to emit a red, green, blue, or yellow wavelength of light upon receiving a current. For example, the first emission material 1304A can include a material configured to emit a red wavelength of light. The first OLED material 112A includes a second emission material 1304B. The second emission material 1304B can include a material configured to emit a red, green, blue, or yellow wavelength of light upon receiving a current. For example, the second emission material 1304B can include a material configured to emit a green wavelength of light.

The first emission material 1304A is separated by a distance “L1” from the second sub-layer 105B. The second sub-layer 105B is configured to emit a standing wave, the standing wave including nodes, e.g., locations where the waves intersect at the mean position of the wave, and anti-nodes, e.g., locations where the waves include a displacement of greater than 90% from a mean position. The distance “L1” is a distance where the first emission material 1304A intersects an anti-node location in the first OLED material 112A. Without being bound by theory, the thickness of the third sub-layer 105C adjusts the location of the anti-node in the first OLED material 112A, such that the first emission material 1304A may emit a red light from the first OLED material 112A.

The substrate 1300 includes a second OLED material 112B. The second OLED material 112B including a bulk OLED material 1302. The first OLED material 112A includes the first emission material 1304A and the second emission material 1304B. The second emission material 1304B is separated by a distance “L2” from the second sub-layer 105B. The distance “L2” is shorter than the distance “L1”. The distance “L2” is a distance where the second emission material 1304B intersects an anti-node location in the second OLED material 112B. Without being bound by theory, the thickness of the third sub-layer 105C adjusts the location of the anti-node in the second OLED material 112B, such that the second emission material 1304B may emit a green light from the second OLED material 112B.

The substrate 1300 includes a third OLED material 112C. The third OLED material 112C including a bulk OLED material 1302. The third OLED material 112C includes a third emission material 1304C. The third emission material 1304C can include a material configured to emit a red, green, blue, or yellow wavelength of light upon receiving a current. For example, the third emission material 1304C can include a material configured to emit a blue wavelength of light. The third emission material 1304C is separated by a distance “L3” from the second sub-layer 105B. The distance “L3” is shorter than the distance “L1” and/or “L2”. The distance “L3” is a distance where the third emission material 1304C intersects an anti-node location in the third OLED material 112C. Without being bound by theory, the thickness of the third sub-layer 105C adjusts the location of the anti-node in the third OLED material 112C, such that the third emission material 1304C may emit a blue light from the third OLED material 112C.

Optionally, a charge generation layer 1306 may be disposed between the first emission material 1304A and the second emission material 1304B, as shown in FIG. 13B. Optionally, the charge generation layer 1306 may be disposed between an upper third emission layer 1304C′ and a lower third emission layer 1304C″. 1304C′ and 1304C″ may be different materials but both emit blue light. For example, 1304C′ may be a fluorescent blue material and 1304C″ may be a phosphorescent blue material or vice versa. A charge generation layer 1306 includes a donor and an acceptor material. Without being bound by theory, the charge generation layer 1306 can act as an artificial metal anode and/or cathode, thereby providing a source for electrons to flow to and/or from in the OLED material 112. Without being bound by theory, the charge generation layer 1306 can provide an enhanced standing wave current, thereby increasing intensity and/or brightness of the emission of the wavelength from the OLED material 112.

Optionally, a fourth emission material 1304D may be disposed between the in the bulk OLED material 1302, as shown in FIG. 13C. The fourth emission material 1304D can include a material configured to emit a red, green, blue, or yellow wavelength of light upon receiving a current. For example, the fourth emission material 1304D can include a material configured to emit a yellow wavelength of light. Without being bound by theory, the thickness of the third sub-layer 105C adjusts the location of the anti-node in the first OLED material 112A and the second OLED material 112B, such that wavelength of light may be adjusted. Optionally, a charge generation layer 1306 may be disposed between an upper fourth emission layer 1304D′ and a lower fourth emission layer 1304D″, as shown in FIG. 13D. Optionally, the charge generation layer 1306 may be disposed between an upper third emission layer 1304C′ and a lower third emission layer 1304C″. 1304D′ and 1304D″ may be different materials but both emit yellow light. For example, 1304D′ may be a fluorescent yellow material and 1304D″ may be a phosphorescent yellow material or vice versa.

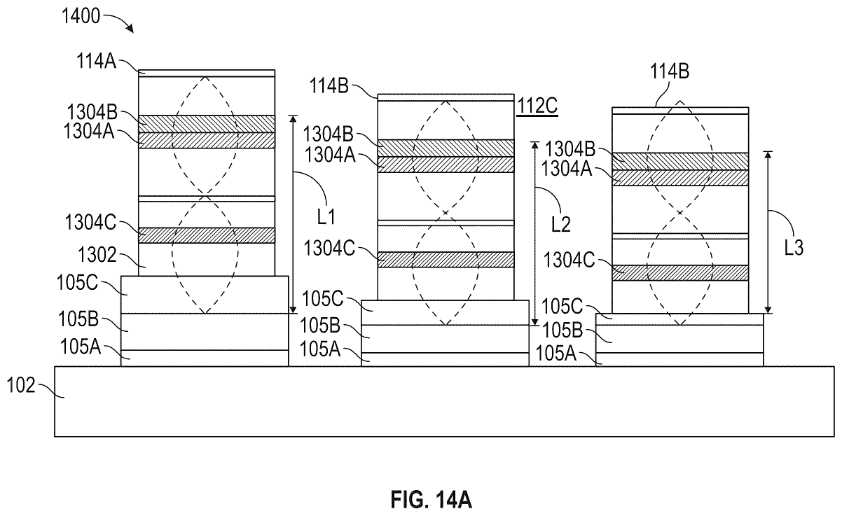

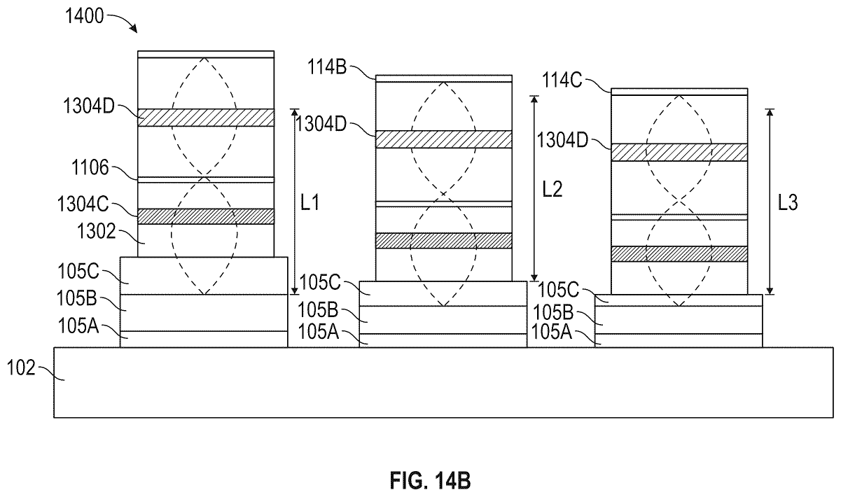

FIG. 14A shows a schematic, cross-sectional views of a substrate 1400. The substrate 1400 includes a plurality of metal layers, each metal layer 104 including a first sub-layer 105A, a second sub-layer 105B, and a third sub-layer 105C. The plurality of metal layers includes a first metal layer 104A, a second metal layer 104B, and a third metal layer 104C. The first metal layer 104A includes a third sub-layer 105C that is thicker than a third sub-layer 105C of the second metal layer 104B, and/or the third metal layer 104C.

The substrate 1400 includes a first OLED material 112A. The first OLED material 112A including a bulk OLED material 1302. The first OLED material 112A includes a first emission material 1304A, a second emission material 1304B and a third emission material 1304C. The first emission material 1304A and the second emission material 1304B are separated from the third emission material 1304C by a charge generation layer 1306. The first emission material 1304A is separated by the distance “L1” from the second sub-layer 105B. Without being bound by theory, the first OLED material 112A can emit a white light due to the thickness of the third sub-layer 105C and the distance “L1” of the first emission material 1304A to the second sub-layer 105B. The substrate 1400 includes a second OLED material 112B. The second OLED material 112B includes a first emission material 1304A, a second emission material 1304B, and a third emission material 1304C. The first emission material 1304A and the second emission material 1304B are separated from the third emission material 1304C by a charge generation layer 1306. The second emission material 1304B is separated by the distance “L2” from the second sub-layer 105B. Without being bound by theory, the second OLED material 112B can emit a white light due to the thickness of the third sub-layer 105C and the distance “L2” of the second emission material 1304B to the second sub-layer 105B. The substrate 1400 includes a third OLED material 112C. The third OLED material 112C includes a first emission material 1304A, a second emission material 1304B, and a third emission material 1304C. The first emission material 1304A and the second emission material 1304B are separated from the third emission material 1304C by a charge generation layer 1306. The second emission material 1304B is separated by the distance “L3” from the second sub-layer 105B. Without being bound by theory, the third OLED material 112C can emit a white light due to the thickness of the third sub-layer 105C and the distance “L3” of the second emission material 1304B to the second sub-layer 105B.

Optionally, a fourth emission material 1304D may be disposed above the charge generation layer 1306, thereby replacing the first emission material 1304A and/or the second emission material 1304B, as shown in FIG. 14B. The fourth emission material 1304D can include a material configured to emit a red, green, blue, or yellow wavelength of light upon receiving a current. For example, the fourth emission material 1304D can include a material configured to emit a yellow wavelength of light.

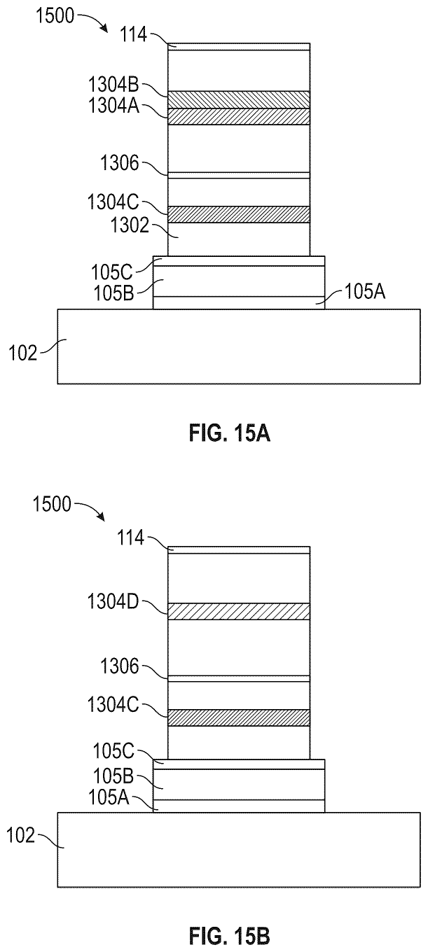

FIG. 15A shows a schematic, cross-sectional views of a substrate 1500. The substrate 1500 includes a metal layer 104 including a first sub-layer 105A, a second sub-layer 105B, and a third sub-layer 105C. The first sub-layer 105A, the second sub-layer 105B, and the third sub-layer 105C include a similar thickness. The substrate 1500 includes an OLED material 112. The OLED material 112 includes a bulk OLED material 1302. The OLED material 112 includes a first emission material 1304A, a second emission material 1304B and a third emission material 1304C. The first emission material 1304A and the second emission material 1304B are separated from the third emission material 1304C by a charge generation layer 1306. Optionally, a fourth emission material 1304D may be disposed above the charge generation layer 1306, thereby replacing the first emission material 1304A and/or the second emission material 1304B, as shown in FIG. 15B. The fourth emission material 1304D can include a material configured to emit a red, green, blue, or yellow wavelength of light upon receiving a current. For example, the fourth emission material 1304D can include a material configured to emit a yellow wavelength of light.

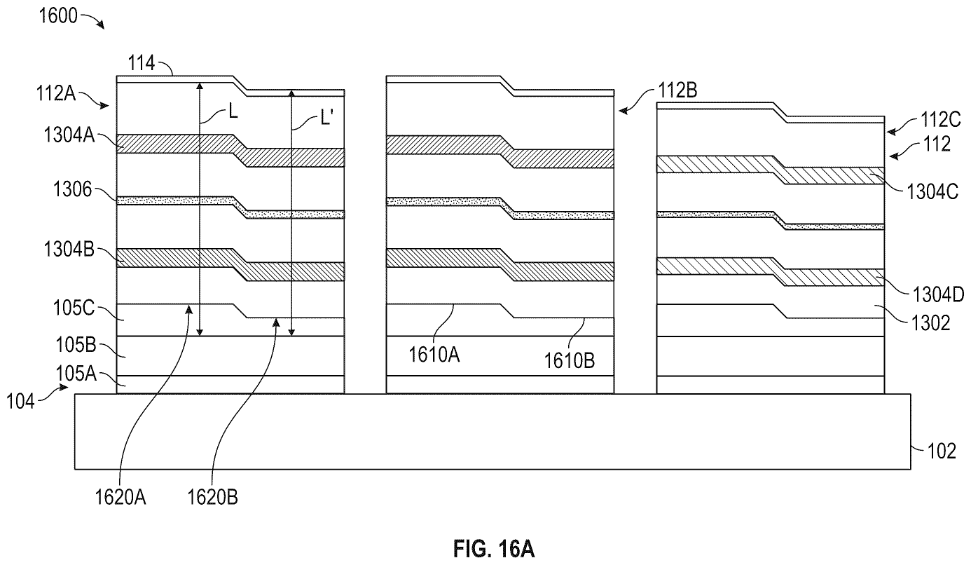

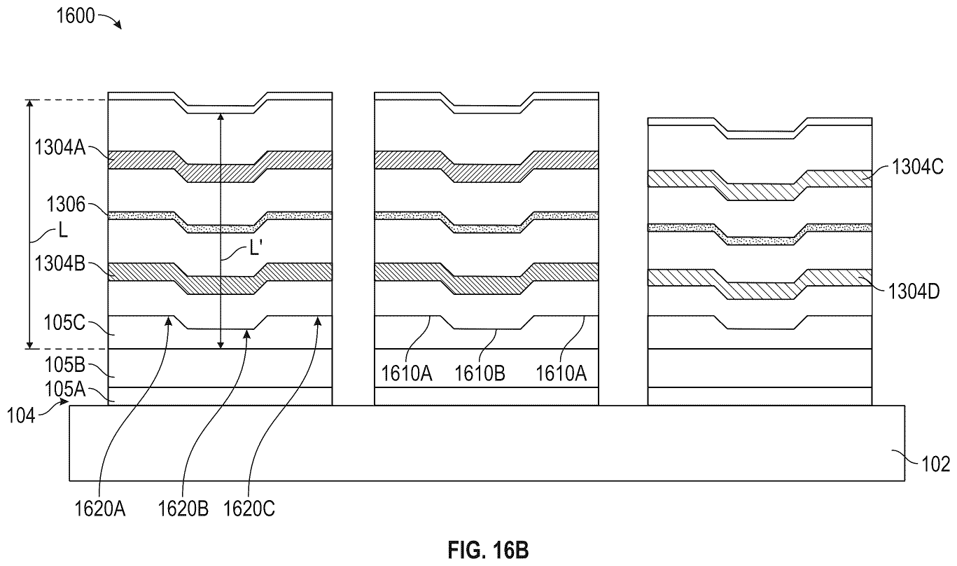

FIG. 16A shows a schematic, cross-sectional views of a substrate 1600, according to one or more embodiments. The substrate 1600 includes a plurality of metal layers, each metal layer 104 including a first sub-layer 105A, a second sub-layer 105B, and a third sub-layer 105C. The third sub-layer 105C of one or more of the metal layers includes a first upper surface 1610A and a second upper surface 1610B. The first upper surface 1610A and the second upper surface 1610B are offset from one another because a first portion 1620A of the third sub-layer 105C having the first upper surface 1610A has a different thickness of a second portion 1620B of the third sub-layer 105C having the second upper surface 1610B.

The substrate 1600 includes a first OLED material 112A a second OLED material 112B, and a third OLED material 112C. The first OLED material 112A and the second OLED material 112B include a bulk OLED material 1302. The first OLED material 112A and the second OLED material 112B each include a first emission material 1304A and a second emission material 1304B. The first emission material 1304A and the second emission material 1304B are separated by a charge generation layer 1306. The first OLED material 112A and the second OLED material 112B are configured to each emit a white and/or yellow light. The third OLED material 112C includes a bulk OLED material 1302. The third OLED material 112C includes a third emission material 1304C and a fourth emission material 1304D. The third emission material 1304C and the fourth emission material 1304D are separated by a charge generation layer 1306. The third OLED material 112C is configured to each emit a blue light.

In one or more embodiments, the a first upper surface 1610A and a second upper surface 1610B cause the of the OLED materials 112 to have a varying depth because the first portion 1620A of the third sub-layer 105C having the first upper surface 1610A has a different thickness of the second portion 1620B of the third sub-layer 105C having the second upper surface 1610B. For example, a first distance L is defined by the distance from the second sub-layer 105B to the cathode 114 for the OLED material 112 aligned with the first upper surface 1610A. A second distance L′ is defined by the distance from the second sub-layer 105B to the cathode 114 for the OLED material 112A, 112B aligned with the second upper surface 1610B. In one or more embodiments, the first distance L is greater than the second distance L′. In one or more embodiments, a first portion 1902 of the OLED materials 112 is disposed over the first upper surface 1610A of the third sub-layer 105C. A second portion 1904 of the OLED materials 112 is disposed over the second upper surface 1610B of the third sub-layer 105C.

The varying distances L, L′ of the OLED material 112 of each sub-pixel causes the intensity of the light emitted by the OLED material 112 to change depending on the position of the eye of someone viewing the sub-pixel. For example, if the eye of a user viewing a sub-pixel having varying distances L, L′ is directly aligned with the OLED material 112 of the sub-pixel, then the light emitted by the area of the OLED material 112 disposed over the first upper surface 1610A may appear brighter than the light emitted by the area of the OLED material 112 disposed over the second upper surface 1610B. If the eye of a user viewing a sub-pixel having varying distances L, L′ is offset from the OLED material 112 of the sub-pixel by an angle, such as 45 degrees, then the light emitted by the area of the OLED material 112 disposed over the second upper surface 1610B may appear brighter than the light emitted by the area of the OLED material 112 disposed over the first upper surface 1610A. Therefore, by varying the distances L, L′ of the OLED material 112 the image quality of the light emitted by the substrate 1600 is improved at various viewing angles.

FIG. 16B shows a schematic, cross-sectional views of a substrate 1600, according to one or more embodiments because a first portion 1620A and a third portion 1620C of the third sub-layer 105C having the first upper surface 1610A has a different thickness of the second portion 1620B of the third sub-layer 105C having the second upper surface 1610B. The substrate 1600 shown in FIG. 16B is similar to the substrate 1600 shown in FIG. 16A, and include one or more of the aspects, features, components, properties, and/or operations thereof. The substrate 1600 includes a plurality of metal layers, each metal layer 104 including a first sub-layer 105A, a second sub-layer 105B, and a third sub-layer 105C. The third sub-layer 105C of one or more of the metal layers includes a first upper surface 1610A and a second upper surface 1610B. The first upper surface 1610A and the second upper surface 1610B are offset from one another. In one or more embodiments, the second upper surface 1610B is a recessed surface in the middle of each metal layer 104. The first upper surface 1610A surrounds the second upper surface 1610B. In one or more embodiments, the first upper surface 1610A is higher than the second upper surface 1610B. In one or more embodiments, a first portion 1902 of the OLED materials 112 is disposed over the first upper surface 1610A of the third sub-layer 105C. A second portion 1904 of the OLED materials 112 is disposed over the second upper surface 1610B of the third sub-layer 105C.

The sub-pixel circuits 100 of FIG. 1D-1F may include metal layers 104 with the third metal layer 104C as described in FIGS. 16A and 16B such that the sub-pixels 108A, 108B, 108C include the OLED material 112A, 112B, 112C with the varying distances L, L′.

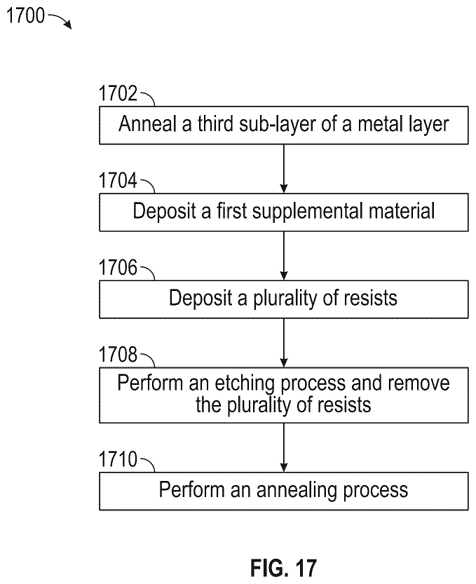

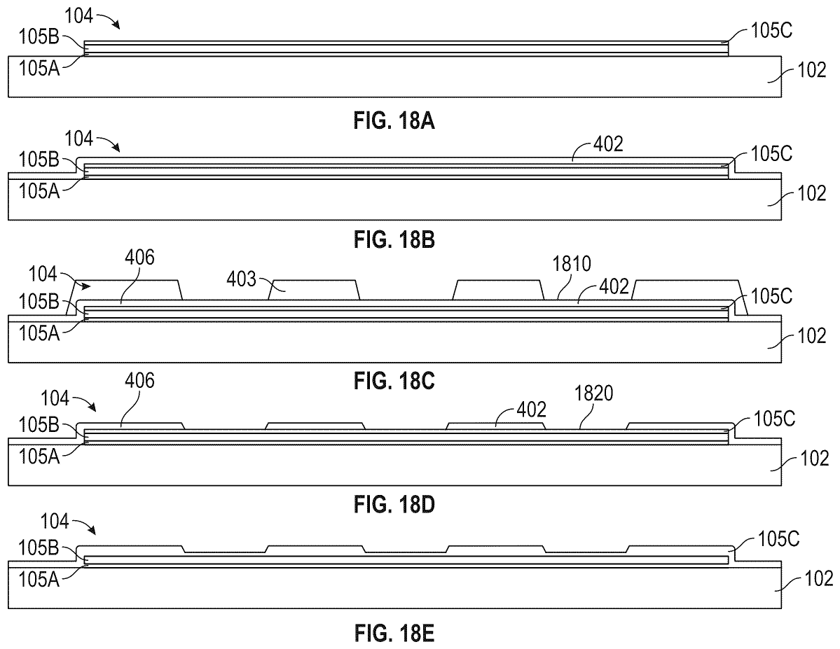

FIG. 17 is a flow a flow diagram of a method 1700 for forming a sub-pixel circuit 100, according to one or more embodiments. FIGS. 18A-18E are schematic, cross-sectional views of a substrate 1600 during the method 1700 for forming a metal layer 104, according embodiments described herein.

Prior to performing the method 1700, a metal layer 104 is formed by performing operations 302-308 of the method 300, operations 702-708 of the method 700, operations 1002-1008 of the method 1000, or a combination thereof. At operation 1702, as shown in FIG. 18A the first sub-layer 105A and the third sub-layer 105C are annealed according to an annealing process. The first sub-layer 105A and the third sub-layer 105C are annealed to produce a poly-crystallized transparent conductive oxide from the amorphous transparent conductive oxide. For example, the first sub-layer 105A and the third sub-layer 105C may be annealed to form a poly-crystallized indium tin oxide.

At operation 1704, as shown in FIG. 18B, a first supplemental material 402 is deposited over the third sub-layer 105C. The first supplemental material 402 includes an amorphous transparent conductive oxide. The amorphous transparent conductive oxide is amorphous indium tin oxide, amorphous indium zinc oxide, or a combination thereof. The first supplemental material 402 can be deposited to provide a thickness of about 50 nm to about 200 nm. The first supplemental material 402 can include a first oxide layer disposed over the third sub-layer 105C and/or the substrate 102 and a second oxide layer disposed over the first oxide layer. The second oxide layer can include a first amorphous transparent conductive oxide such as amorphous indium zinc oxide. The second oxide layer can include a second amorphous transparent conductive oxide such as amorphous indium tin oxide.

The first oxide layer can include a thickness of about 45 nm to about 160 nm. The second oxide layer can include a thickness of about less than 40 nm, e.g., about 5 nm to about 40 nm. Without being bound by theory, by reducing the thickness of the second oxide layer to be less than 40 nm, a reduction of partial crystallization of the second oxide layer may occur, thereby improving an etch selectivity and/or efficiency during subsequent processing steps. For example, a thickness of about 40 nm or less of indium tin oxide may have greater etch selectivity and/or efficiency compared to a thickness of about 50 nm or greater of indium tin oxide. Additionally, and without being bound by theory, a first supplemental material 402 including a first oxide layer comprising indium zinc oxide having a thickness of about 45 nm to about 160 nm, and a second oxide layer comprising indium tin oxide having a thickness of less than 40 nm may provide enhanced etch selectivity and/or efficiency during subsequent processing steps, e.g., etching such as etching with oxalic acid.

At operation 1706, as shown in FIG. 18C, a plurality of second resists 403 is deposited over the first supplemental material 402. The plurality of second resists 403 is deposited over the first supplemental material 402 such that a metal layer 104 is covered by the plurality of second resists 403. Optionally, the plurality of second resists 403 may be deposited over a lateral edge 406 of a second metal layer 104B and a third metal layer 104C. Without being bound by theory, the plurality of second resists 403 may be deposited over the lateral edge of the second metal layer 104B and the third metal layer 104C such that the third sub-layer 105C does not get etched over the lateral edge, thereby providing enhanced protection of the edge of the second sub-layer 105B. The plurality of second resists 403 is patterned over the third metal layer 104C as desired. One or more upper surfaces 1810 of the first supplemental material 402 are exposed in between the portions of the plurality of second resists 403. The plurality of second resists 403 defines one or more openings. The one or more upper surfaces 1810 of the first supplemental material 402 are exposed by the openings.

The pattern of the plurality of second resists 403 can be used to form the first portion 1620A and the second portion 1620B of the third sub-layer 105C of each metal layer 104 in FIG. 16A. For example, the plurality of second resists 403 can be deposited only over the left half of each metal layer 104. During an etching operation, the resist prevents the left half of each metal layer from being etched. After the etching process is performed, the resist is removed, and the area protected by the resist defines the first portion 1620A of the third sub-layer 105C having the first upper surface 1610A. The area of the third sub-layer 105C that was etched during the etching process defines the second portion 1620B of the third sub-layer 105C having the second upper surface 1610B.

The pattern of the plurality of second resists 403 can be used to form the first portion 1620A, the second portion 1620B, and the third portion 1620C of the third sub-layer 105C of each metal layer 104 in FIG. 16B. For example, the plurality of second resists 403 can be deposited only a left portion and a right portion of each metal layer 104 leaving the center of each metal layer 104 exposed. During an etching operation, the resist prevents the left portion and the right portion of each metal layer from being etched. After the etching process is performed, the resist is removed, and the area protected by the resist defines the first portion 1620A and the third portion 1620C of the third sub-layer 105C having the first upper surface 1610A. The area of the third sub-layer 105C that was etched during the etching process defines the second portion 1620B of the third sub-layer 105C having the second upper surface 1610B.

The plurality of second resists 403 is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the plurality of second resists 403 determines whether the resist is a positive resist or a negative resist.

At step 1708, as shown in FIG. 18D, the one or more exposed upper surfaces 1810 are etched using an etching process and the plurality of second resists 403 are removed. The etching process may be a wet etching process and/or a dry etching process.

At step 1710, as shown in FIG. 18E, the second oxide layer of the first supplemental material 402 is annealed. The first oxide layer remains an amorphous transparent conductive oxide, e.g., amorphous indium zinc oxide. The second oxide layer of the first supplemental material 402 is annealed to produce a poly-crystallized transparent conductive oxide from the amorphous transparent conductive oxide. For example, the second oxide layer of the first supplemental material 402 may be annealed to form a poly-crystallized indium tin oxide. In some embodiments, which may be combined with other embodiments, by annealing the second oxide layer of the first supplemental material 402 to produce a poly-crystallized transparent conductive oxide, the second oxide layer of the first supplemental material 402 may be similar to the third sub-layer 105C. For example, the second oxide layer of the first supplemental material 402, when annealed, may become the third sub-layer 105C. The third sub-layer includes one or more first upper surfaces 1610A and one or more second upper surfaces 1610B. The first upper surfaces 1610A and the second upper surfaces 1610B are offset from one another. In one or more embodiments, the thickness of the third sub-layer 105C is greater between the second sub-layer 105B and the first upper surface 1610A than the thickness between the second sub-layer 105B and the second upper surface 1610B.

The sub-pixel circuits 100 of FIG. 1D-1F may include metal layers 104 formed via the method 1700. The sub-pixel circuits 100 of FIGS. 2D-2F may include metal layers 104 formed via the method 1700. Thus the sub-pixel circuits 100 of FIG. 1D-1F include may include the first OLED material 112A, the second OLED material 112B, and the third OLED material 112C having the varying distances L, L′.

Subsequent to performing the method 1700, a sub-pixel circuit is formed over the metal layers 104 is formed by performing operations 320-340 of the method 300, operations 720-742 of the method 700, operations 1020-1048 of the method 1000, or a combination thereof.

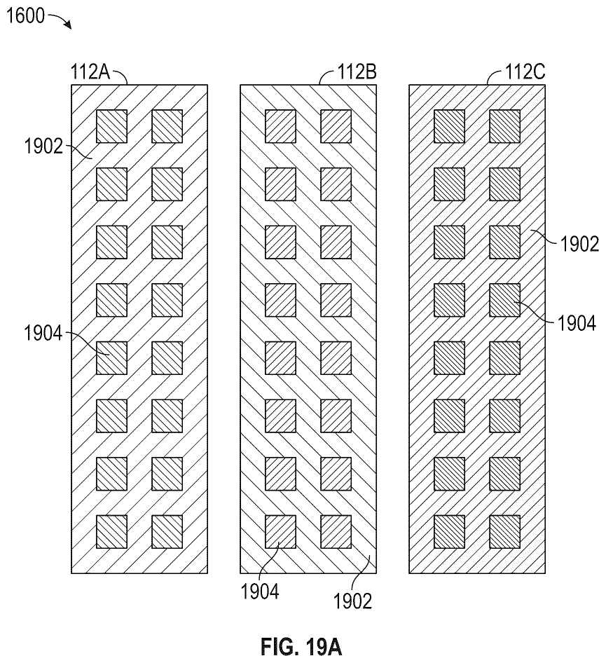

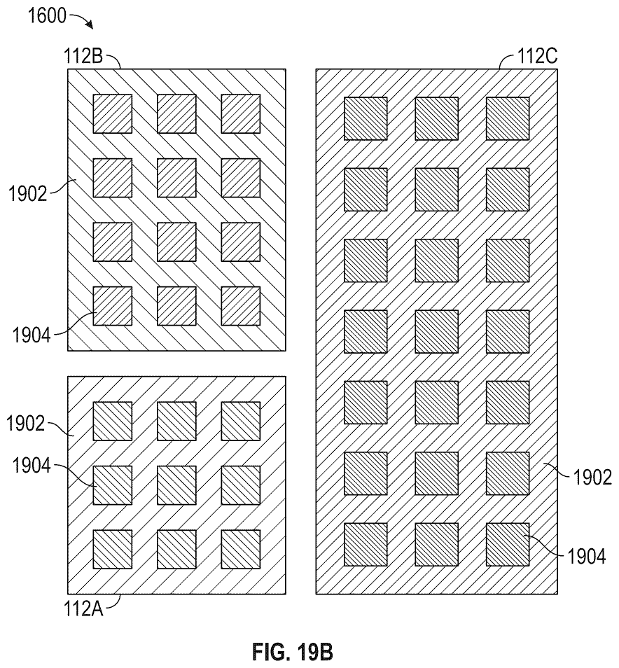

FIGS. 19A and 19B are schematic top views of the substrate 1600, according to one or more embodiments. The substrate 1600 includes the first OLED material 112A, the second OLED material 112B, and the third OLED material 112C. The first OLED material 112A includes the first emission material 1304A. The second OLED material 112B includes the third emission material 1304C. It should be understood that the FIGS. 19A and 19B do not include the cathode 114 and the bulk OLED material 1302 for illustrative purposes. The third OLED material 112C includes the second emission material 1304B. Each OLED material 112A, 112B, 112C. Each OLED material includes a first portion 1902 and a second portion 1904. The first portion is disposed over the first upper surface 1610A of the third sub-layer 105C (FIGS. 16A, 16B) and the second portion 1904 second upper surface 1610B of the third sub-layer 105C (FIGS. 16A, 16B). In one or more embodiments, the first upper surface 1610A and the second upper surface 1610B are offset from one another causing the a first portion 1902 and a second portion 1904 of the OLED materials 112A, 112B, 112C to be offset from one another. In one or more embodiments, the second portion 1904 is recessed within the first portion 1902. In one or more embodiments, as shown in FIG. 19A the first OLED material 112A, the second OLED material 112B, and the third OLED material 112C are the same size as one another. In one or more embodiments, as shown in FIG. 19B the third OLED material 112C is larger than the first OLED material 112A, the second OLED material 112B.

Overall, a sub-pixel circuit for an OLED device and methods of forming a sub-pixel circuit are described herein. The sub-pixel circuits include varying thicknesses of a third sub-layer of a metal layer, thereby allowing for control of an emission wavelength of the OLED material. By controlling the emission of the wavelength, one or more overhang structures may be eliminated and/or removed, while maintaining color intensity and contrast, thereby reducing manufacturing costs. Moreover, by controlling the emission of the wavelength by varying the thickness of the third sub-layer of a metal layer, a plurality of OLED material configurations may be implemented, thereby allowing for various wavelength emissions to be utilized while still maintaining color intensity and contrast.

While the foregoing is directed to embodiments of the present disclosure, other and further embodiments of the disclosure may be devised without departing from the basic scope thereof, and the scope thereof is determined by the claims that follow.

What is claimed is:

1. A method, the method comprising:
disposing a plurality of metal layers over a substrate, the plurality of metal layers comprising a plurality of first sub-layers, a plurality of second sub-layers, and a plurality of third sub-layers, wherein disposing the plurality of metal layers comprises:
disposing the plurality of first sub-layers over the substrate, the second plurality of sub-layers over the plurality of first sub-layers, and the plurality of third sub-layers over the plurality of second sub-layers, wherein the plurality of first sub-layers comprise a first thickness, the plurality of second sub-layers comprise a second thickness, and the plurality of third sub-layers comprise a third thickness;
disposing a supplemental material over the plurality of third sub-layers;
patterning a resist over the supplemental material, the resist defining one or more openings, one or more upper surfaces of the supplemental material are exposed by the one or more openings;
etching the one or more upper surfaces of the supplemental material exposed by the one or more openings; and
annealing the supplemental material to form one or more first upper surfaces and one or more second upper surfaces of the third sub-layer.

2. The method of claim 1, wherein a thickness of the third sub-layer is greater from the second sub-layer to the first upper surface than the thickness from the second sub-layer to the second upper surface.

3. The method of claim 1, wherein the second upper surface is a recessed surface in the middle of each metal layer.

4. The method of claim 1, wherein the first upper surface surrounds the second upper surface.

5. The method of claim 1, wherein the first upper surface is higher than the second upper surface.

6. The method of claim 1, further comprising:
disposing a plurality of pixel defining layer (PDL) structures between the plurality of metal layers;
disposing a lower portion layer and an upper portion layer over a plurality of sub-pixels;
disposing a second resist over the lower portion layer and the upper portion layer;
patterning the second resist to form a first opening in a first sub-pixel of the plurality of sub-pixels, the first opening defining a plurality of overhang structures;
disposing a first organic light-emitting device (OLED) material, on a metal layer of the first opening and the plurality of overhang structures;
disposing a cathode layer on the first OLED material and the plurality of overhang structures;
disposing a first encapsulation layer over the cathode layer and the plurality of overhang structures;
forming a third resist over the first encapsulation layer and the plurality of overhang structures;
removing a portion of the third resist over the plurality of overhang structures; and
etching the first encapsulation layer, the cathode layer, the first OLED material, and a residual portion of the third resist to expose the plurality of overhang structures.

7. The method of claim 6, further comprising:
disposing a plurality of mask structures over the first encapsulation layer wherein the plurality of mask structures are aligned with the PDL structures; and
depositing a color filter between adjacent mask structures of the plurality of mask structures.

8. The method of claim 6, further comprising:
disposing an intermediate layer over the first encapsulation layer; and
disposing a second encapsulation layer over the intermediate layer.

9. The method of claim 6, wherein a first distance is defined by the distance from the second sub-layer to the cathode for the OLED material aligned with the one or more first upper surfaces and second distance is defined by the distance from the second sub-layer to the cathode for the OLED material aligned with the one or more second upper surfaces, the first distance is greater than the second distance.

10. A sub-pixel circuit, comprising:
a plurality of anodes deposited over a substrate, each anode comprising:
a first sub-layer;
a second sub-layer;
a third sub-layer, the third sub-layer comprising a first upper surface and a second upper surface offset from one another;
an organic light emitting diode (OLED) material disposed over the anode; and
a cathode disposed over the OLED material, wherein a first distance is defined by the distance from the second sub-layer to the cathode for the OLED material aligned with the first upper surface and second distance defined by the distance from the second sub-layer to the cathode for the OLED material aligned with the second upper surface, the first distance is greater than the second distance.

11. The sub-pixel circuit of 10, wherein a thickness of the third sub-layer is greater between the second sub-layer and the first upper surface than the thickness between the second sub-layer and the second upper surface.

12. The sub-pixel circuit of 10, wherein the second upper surface is a recessed surface in the middle of each metal layer.

13. The sub-pixel circuit of 10, wherein the first upper surface surrounds the second upper surface.

14. The sub-pixel circuit of 10, wherein the first upper surface is higher than the second upper surface.

15. The sub-pixel circuit of claim 10, further comprising an inorganic layer disposed on the substrate, the inorganic layer defining sub-pixels of the device, wherein the inorganic layer comprises a plurality of overhang structures.

16. The sub-pixel circuit of claim 15, further comprising a pixel defining layer (PDL) disposed on the substrate and below the inorganic layer.

17. The sub-pixel circuit of claim 15, further comprising an encapsulation layer contacting a sidewall of the overhang structures under an overhang and an underside surface of the overhang structures.

18. The sub-pixel circuit of claim 17, further comprising a global passivation layer disposed over the encapsulation layer and the overhang structures.

19. A device, comprising:
a substrate;
an inorganic layer disposed on the substrate, the inorganic layer defining sub-pixels of the device, wherein the inorganic layer comprises a plurality of overhang structures;
a pixel defining layer (PDL) disposed on the substrate and below the inorganic layer;
a first sub-pixel comprising:
a first anode having a first thickness disposed over the substrate; and
a first organic light-emitting diode (OLED) material disposed over and in contact with the first anode;
a first color filter disposed over the first OLED material;
a second sub-pixel comprising:
a second anode having a second thickness disposed over the substrate; and
a second OLED material disposed over and in contact with the second anode, wherein the first OLED material and the second OLED material are configured to emit the same color light;
a second color filter disposed over the second OLED material; and
a third sub-pixel comprising:
a third anode having a third thickness disposed over the substrate; and
a third organic light-emitting diode (OLED) material disposed over and in contact with the third anode, wherein the first thickness the second thickness, and the third thickness are the same; and
a third color filter disposed over the third OLED material.

20. The device of claim 19, wherein the first OLED material, the second OLED material, and the third OLED material are the same.
